(19) United States
(12) Patent Application Publication
(10) Pub. No.: US 2023/0337457 A1
(43) Pub. Date: Oct. 19, 2023

(54) METHOD FOR MANUFACTURING TRANSPARENT ELECTRODE, LIGHT EMITTING ELEMENT, AND METHOD FOR MANUFACTURING LIGHT EMITTING ELEMENT

(71) Applicants: Samsung Display Co., Ltd., Yongin-si (KR); KOREA UNIVERSITY Research and Business Foundation, Seoul (KR)

(72) Inventors: YOUNGTAK LEE, Yongin-si (KR); Byeong-Kwon JU, Seoul (KR); Minjeong CHOI, Seoul (KR); Jaewon PARK, Seoul (KR); Jun-Young PARK, Seoul (KR); JAE YOUNG LEE, Yongin-si (KR); Seungwon LEE, Seoul (KR)

(73) Assignees: Samsung Display Co., Ltd., Yongin-si (KR); KOREA UNIVERSITY Research and Business Foundation, Seoul (KR)

(21) Appl. No.: 18/102,989

(22) Filed: Jan. 30, 2023

(30) Foreign Application Priority Data
Apr. 15, 2022 (KR) 10-2022-0047113

(51) Int. Cl. H10K 50/828; H10K 50/15; H10K 50/16; H10K 71/00

(52) U.S. Cl. CPC H10K 50/828; H10K 50/15; H10K 50/16; H10K 71/00; H10K 2102/103

(57) ABSTRACT

Embodiments provide a light emitting element that includes a first electrode, a second electrode facing the first electrode, and a plurality of functional layers disposed between the first electrode and the second electrode. At least one of the first electrode and the second electrode includes a plurality of fibrous electrodes, which are randomly disposed. The plurality of fibrous electrodes includes a first fibrous electrode having a first width in a plan view, and a second fibrous electrode having a second width different from the first width in a plan view.

### CROSS-REFERENCE TO RELATED APPLICATION(S)

This application claims priority to and benefits of Korean Patent Application No. 10-2022-0047113 under 35 U.S.C. § 119, filed on Apr. 15, 2022, in the Korean Intellectual Property Office (KIPO), the entire contents of which are incorporated herein by reference.

### BACKGROUND

### 1. Technical Field

The disclosure herein relates to a method for manufacturing a transparent electrode that may be used as a stretchable electrode, a light emitting element, and a method for manufacturing the light emitting element.

### 2. Description of the Related Art

There has been a continuous demand for flexible, readily deformable, and stretchable electronic element technologies lately, and the stretchable electronic element technologies are expected to be widely applicable to the technical fields such as wearable elements and robot sensor skin.

The stretchable electronic element technologies go beyond simply having excellent bendable or flexible properties, and require electrodes that exhibit high transmittance and have useful electrical and mechanical properties even when stretched or compressed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a method for manufacturing a transparent electrode having excellent optical properties and low sheet resistance.

The disclosure also provides a light emitting element including a transparent electrode with low resistance and high transmittance.

The disclosure also provides a method for manufacturing a light emitting element including a transparent electrode with low resistance and high transmittance.

An embodiment of the disclosure provides a light emitting element that may include a first electrode, a second electrode facing the first electrode, and a plurality of functional layers disposed between the first electrode and the second electrode. At least one of the first electrode and the second electrode may include a plurality of fibrous electrodes, which are randomly disposed. The plurality of fibrous electrodes may include a first fibrous electrode having a first width in a plan view, and a second fibrous electrode having a second width different from the first width in a plan view.

In an embodiment, the first fibrous electrode and the second fibrous electrode may be integral with each other.

In an embodiment, the first width of the first fibrous electrode may be in a range of about 300 nm to about 500 nm, and the second width of the second fibrous electrode may be in a range of about 2 μm to about 3 μm.

In an embodiment, each of the first fibrous electrode and the second fibrous electrode may have a thickness in a thickness direction of the first electrode or the second electrode, and the thickness of the first fibrous electrode may be substantially equal to the thickness of the second fibrous electrode in the thickness direction.

In an embodiment, the first fibrous electrode and the second fibrous electrode may each independently include silver (Ag), gold (Au), platinum (Pt), aluminum (Al), copper (Cu), tin (Sn), gallium (Ga), indium (In), nickel (Ni), or any combination thereof.

In an embodiment, at least one of the first electrode and the second electrode may further include a buffer layer disposed on the plurality of fibrous electrodes and including a transparent conductive oxide.

In an embodiment, the buffer layer may cover the plurality of fibrous electrodes.

In an embodiment, the buffer layer may have an upper surface parallel to an upper surface of the first electrode or the second electrode.

In an embodiment, the buffer layer may include indium zinc oxide.

In an embodiment, the buffer layer may include a first buffer layer disposed on the plurality of fibrous electrodes and including the transparent conductive oxide, and a second buffer layer disposed on the first buffer layer and including a conductive polymer.

In an embodiment, the plurality of functional layers may include a hole transport region disposed on the first electrode, an emission layer disposed on the hole transport region, and an electron transport region disposed on the emission layer.

In an embodiment of the disclosure, a method for manufacturing a transparent electrode may include forming an electrode layer on a substrate, disposing a first polymer fiber having a first diameter and a second polymer fiber having a second diameter different from the first diameter on the electrode layer, etching the electrode layer, using the first polymer fiber and the second polymer fiber as masks, and removing the first polymer fiber and the second polymer fiber.

In an embodiment, the first polymer fiber and the second polymer fiber may be randomly disposed on the electrode layer.

In an embodiment, the first diameter may be in a range of about 300 nm to about 500 nm, and the second diameter may be in a range of about 2 μm to about 3 μm.

In an embodiment, the disposing of the first polymer fiber and the second polymer fiber may include disposing the first polymer fiber on the electrode layer, and disposing the second polymer fiber on the electrode layer and the first polymer.

In an embodiment, the method may further include forming a buffer layer including a transparent conductive oxide on the substrate, after the removing of the first polymer fiber and the second polymer fiber.

In an embodiment, the forming of the buffer layer may include forming a first buffer layer including the transparent conductive oxide on the substrate, and forming a second buffer layer including a conductive polymer on the first buffer layer.

In an embodiment, the method may further include heat-treating the first polymer fiber and the second polymer fiber, after the disposing of the first polymer fiber and the second polymer fiber.

In an embodiment, the disposing of the first polymer fiber and the second polymer fiber may be performed by at least one of electro-spinning, melt-blowing, and flash-spinning.

In an embodiment of the disclosure, a method for manufacturing a light emitting element may include forming a first electrode, forming a plurality of functional layers on the first electrode, and forming a second electrode on the plurality of functional layers. The forming of the first electrode may include forming an electrode layer on a substrate, disposing a first polymer fiber having a first diameter and a second polymer fiber having a second diameter different from the first diameter on the electrode layer, etching the electrode layer, using the first polymer fiber and the second polymer fiber as masks, and removing the first polymer fiber and the second polymer fiber.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles therefore. The above and other aspects and features of the disclosure will become more apparent by describing in detail embodiments thereof with reference to the accompanying drawings, in which:

FIG. 1 is a plan view showing an embodiment of a display device;

FIG. 2 is a schematic cross-sectional view of a display device according to an embodiment;

FIG. 3A is a schematic cross-sectional view of a light emitting element according to an embodiment;

FIG. 3B is a perspective view showing a portion of a light emitting element according to an embodiment;

FIG. 3C is a plan view showing a portion of a light emitting element according to an embodiment;

FIG. 4 is a schematic cross-sectional view of a light emitting element according to an embodiment;

FIG. 5A is a flowchart showing a method for manufacturing a transparent electrode according to an embodiment;

FIG. 5B is a flowchart showing disposing a first polymer fiber and a second polymer fiber on an electrode layer in a method for manufacturing a transparent electrode according to an embodiment;

FIGS. 6A to 6H are each a perspective view showing processes in a method for manufacturing a transparent electrode according to an embodiment of the disclosure;

FIGS. 7A to 7G are each a schematic cross-sectional view showing processes of manufacturing a light emitting element according to an embodiment;

FIGS. 8A to 8C are each a view of scanning transfer micrographs of transparent electrodes of Example and Comparative Examples;

FIG. 9A is a graph showing sheet resistance of transparent electrodes of Example and Comparative Examples;

FIG. 9B is a graph showing changes in light transmittance versus wavelengths of Example and Comparative Examples;

FIG. 9C is a graph showing haze of Example and Comparative Examples;

FIG. 9D is a graph showing changes in sheet resistance of transparent electrodes versus spinning time of the first polymer fiber and the second polymer fiber;

FIG. 10A is a graph showing changes in electrical resistance value versus a radius of transparent electrodes of Example and Comparative Examples; and

FIG. 10B is a graph showing changes in electrical resistance value from a test of repeated bending of transparent electrodes of Example and Comparative Examples.

### DETAILED DESCRIPTION OF THE EMBODIMENTS

Hereinafter, embodiments of the disclosure will be described with reference to the drawings.

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

Like numbers refer to like elements throughout. In the drawings, the thickness, the ratio, and the dimensions of elements may be exaggerated for an effective description of technical contents.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

As used herein, the expressions used in the singular such as “a,” “an,” and “the,” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms (including technical and scientific terms) used herein have the same meaning as commonly understood by one of ordinary skill in the art to which the disclosure belongs. Terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the disclosure will be described with reference to the accompanying drawings.

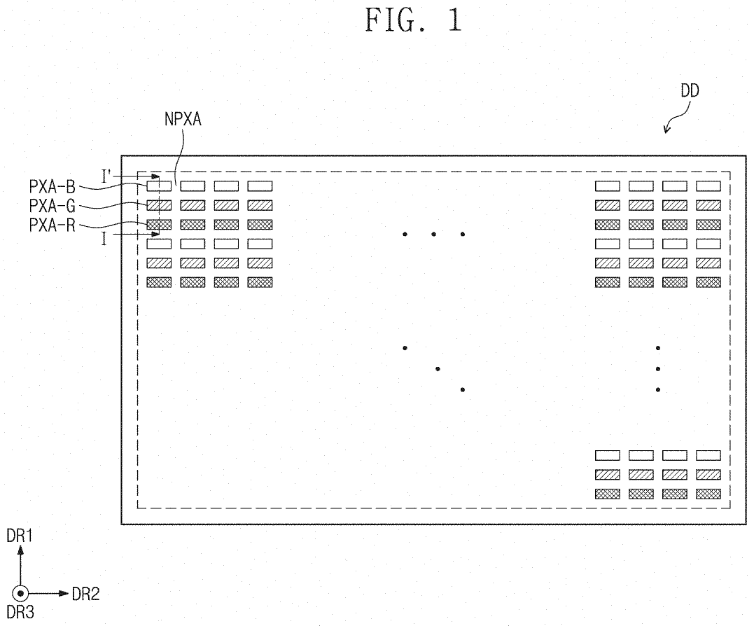

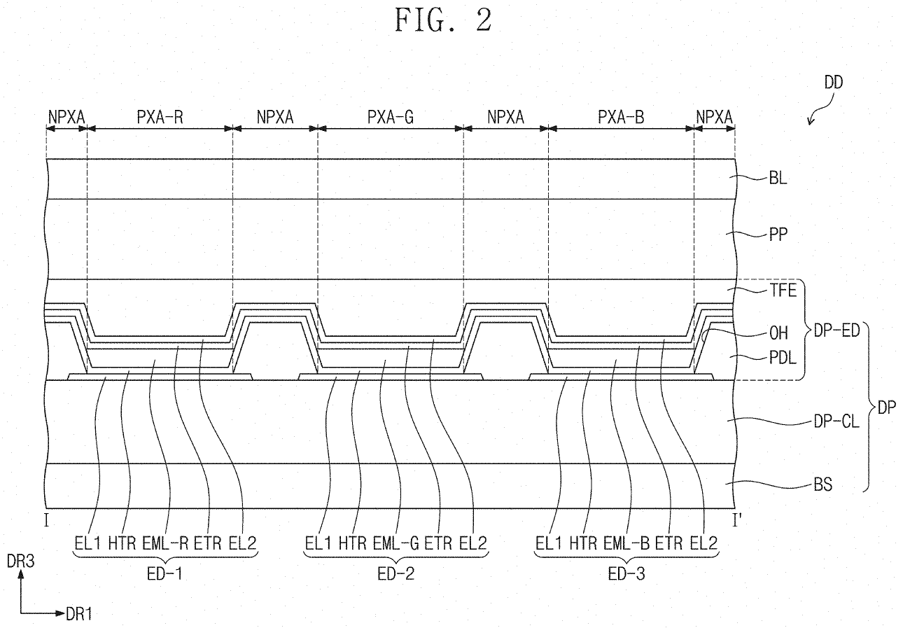

FIG. 1 is a plan view showing an embodiment of a display device DD. FIG. 2 is a schematic cross-sectional view of a display device DD according to an embodiment. FIG. 2 is a schematic cross-sectional view showing a display device DD along line I-I′ of FIG. 1.

The display device DD may include a display panel DP and an optical layer PP disposed on the display panel DP. The display panel DP may include light emitting elements ED-1, ED-2, and ED-3. The display device DD may include multiple light emitting elements ED-1, ED-2, and ED-3. The optical layer PP may be disposed on the display panel DP to control reflected light of external light in the display panel DP. The optical layer PP may include, for example, a polarizing layer or a color filter layer. Unlike what is shown in the drawings, the optical layer PP may be omitted in the display device DD of an embodiment.

A base substrate BL may be disposed on the optical layer PP. The base substrate BL may be a member providing a base surface on which the optical layer PP is disposed. The base substrate BL may be a glass substrate, a metal substrate, a plastic substrate, etc. However, the embodiment of the disclosure is not limited thereto, and the base substrate BL may be an inorganic layer, an organic layer, or a composite material layer. Unlike what is shown, the base substrate BL may be omitted in an embodiment.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, multiple light emitting elements ED-1, ED-2, and ED-3 disposed between the pixel defining films PDL, and an encapsulation layer TFE disposed on the light emitting elements ED-1, ED-2, and ED-3.

The base layer BS may be a member providing a base surface in which the display element layer DP-ED is disposed. The base layer BS may be a glass substrate, a metal substrate, a plastic substrate, etc. However, the embodiment of the disclosure is not limited thereto, and the base layer BS may be an inorganic layer, an organic layer, or a composite material layer.

In an embodiment, the circuit layer DP-CL may be disposed on the base layer BS, and the circuit layer DP-CL may include multiple transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

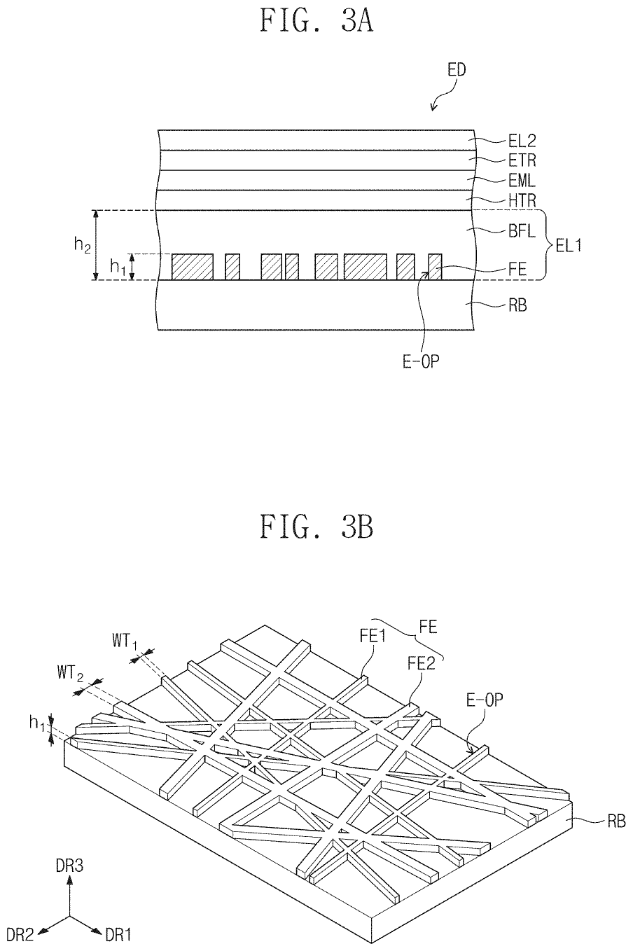

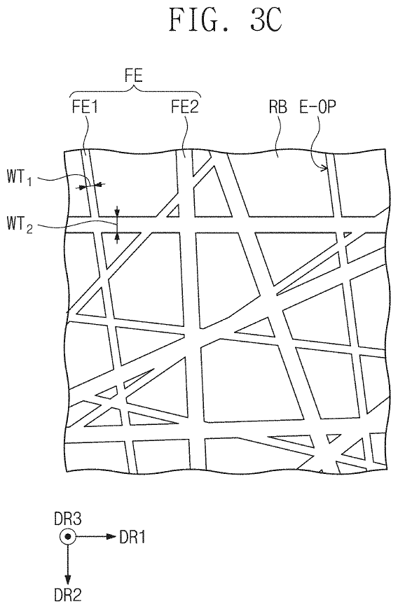

The light emitting elements ED-1, ED-2, and ED-3 may each have a structure of a light emitting element ED according to an embodiment of FIGS. 3A and 3B, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided in common throughout the light emitting elements ED-1, ED-2, and ED-3. However, the embodiment of the disclosure is not limited thereto, and in another embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, the electron transport region ETR, etc., of the light emitting elements ED-1, ED-2, and ED-3 may be patterned and provided through an inkjet printing method.

An encapsulation layer TFE may cover the light emitting elements ED-1, ED-2, and ED-3. The encapsulation layer TFE may seal the light emitting elements ED-1, ED-2, and ED-3. The encapsulation layer TFE may be a thin film encapsulation layer. The encapsulation layer TFE may be a single layer or a stack of multiple layers. The encapsulation layer TFE may include at least one insulating layer. The encapsulation layer TFE according to an embodiment may include at least one inorganic film (hereinafter, an encapsulation inorganic film). The encapsulation layer TFE according to an embodiment may include at least one organic film (hereinafter, an encapsulation organic film) and at least one encapsulation inorganic film.

The encapsulation inorganic film may protect the display element layer DP-ED from moisture/oxygen, and the encapsulation organic film may protect the display element layer DP-ED from foreign substances such as dust particles. The encapsulation inorganic film may include silicon nitride, silicon oxynitride, silicon oxide, titanium oxide, aluminum oxide, etc., but is not particularly limited thereto. The encapsulation organic layer may include an acrylic compound, an epoxy-based compound, etc. The encapsulation organic layer may include a photopolymerizable organic material, and is not particularly limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In the description, the light emitting regions PXA-R, PXA-G, and PXA-B may each correspond to a pixel. The pixel defining films PDL may separate the light emitting elements ED-1, ED-2, and ED-3. The emission layers EML-R, EML-G, and EML-B of the light emitting elements ED-1, ED-2 and ED-3 may be disposed and separated in openings OH defined by the pixel defining films PDL.

The light emitting regions PXA-R, PXA-G, and PXA-B may be divided into multiple groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are illustrated as an example. For example, the display device DD of an embodiment may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the disclosure is not limited thereto, and the first to third light emitting elements ED-1, ED-2 and ED-3 may emit light in the same wavelength range or emit light in at least one different wavelength range. For example, the first to third light emitting elements ED-1, ED-2, and ED-3 all may emit blue light.

The light emitting regions PXA-R, PXA-G, and PXA-B in the display device DD according to an embodiment may be arranged in the form of a stripe. Referring to FIG. 1, multiple red light emitting regions PXA-R, multiple green light emitting regions PXA-G, and multiple blue light emitting regions PXA-B may each be arranged in a second direction DR2. In another embodiment, the red light emitting region PXA-R, the green light emitting region PXA-G, and the blue light emitting region PXA-B may be alternately arranged in a first direction DR1.

FIGS. 1 and 2 illustrate that the light emitting regions PXA-R, PXA-G, and PXA-B are all similar in size, but the embodiment of the disclosure is not limited thereto, and the light emitting regions PXA-R, PXA-G and PXA-B may be different in size from each other according to wavelength range of emitted light. The areas of the light emitting regions PXA-R, PXA-G, and PXA-B may be areas in a plan view.

The arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may vary according to display quality characteristics required for the display device DD. For example, the light emitting regions PXA-R, PXA-G, and PXA-B may be arranged in the form of a PENTILE™ configuration or a Diamond Pixel™ configuration.

The areas of each of the light emitting regions PXA-R, PXA-G, and PXA-B may be different in size from one another. For example, in an embodiment, the green light emitting region PXA-G may be smaller than the blue light emitting region PXA-B in size, but the embodiment of the disclosure is not limited thereto.

FIG. 3A is a schematic cross-sectional view of a light emitting element according to an embodiment. FIG. 3B is a perspective view showing a portion of a light emitting element according to an embodiment. FIG. 3C is a plan view showing a portion of a light emitting element according to an embodiment. FIGS. 3B and 3C show a substrate RB presented in FIG. 3A and multiple fibrous electrodes FE disposed on the substrate RB.

Referring to FIG. 3A, the light emitting element ED according to an embodiment may include a first electrode EL1, a hole transport region HTR, an emission layer EML, an electron transport region ETR, and a second electrode EL2. In an embodiment, at least one of the first electrode EL1 and the second electrode EL2 of the light emitting element ED may include multiple fibrous electrodes FE, which will be described later. Hereinafter, an embodiment in which the first electrode EL1 in the light emitting element ED includes multiple fibrous electrodes FE is shown in FIGS. 3A to 3C, but the embodiment is not limited thereto. For example, in the light emitting element ED, the second electrode EL2 may include multiple fibrous electrodes FE, and in the embodiment, as for the fibrous electrodes included in the second electrode EL2, descriptions of the fibrous electrodes FE of the first electrode EL1, which will be described may be equally applied.

The first electrode EL1 may include multiple fibrous electrodes FE and a buffer layer BFL. The first electrode EL1 may include multiple fibrous electrodes FE disposed on the substrate RB and a buffer layer BFL disposed on the fibrous electrodes FE. The substrate RB may provide a reference surface on which the fibrous electrodes FE are formed. For example, the substrate RB may be a base layer BS or a circuit layer DP-CL, which is described in FIG. 2. For example, the substrate RB may be an insulating layer disposed on top of the circuit layer DP-CL.

Referring to FIGS. 3A to 3C, the fibrous electrodes FE may be disposed on the substrate RB. The fibrous electrodes FE may be randomly disposed on the substrate RB. On the substrate RB, each of the fibrous electrodes FE may extend in an arbitrary direction. The direction in which the fibrous electrodes FE extend may be random. The distance between adjacent fibrous electrodes FE among the fibrous electrodes FE may be different. As used herein, “randomly disposed” may indicate that electrodes or the like are not in the form of an arrangement having a certain regularity, but are irregularly disposed in regard to an extension direction or a distance.

At least two or more of the fibrous electrodes FE on the substrate RB may be arranged to intersect each other. A portion in which at least two fibrous electrodes FE intersect each other in the fibrous electrodes FE herein may be referred to as an intersect portion. In the fibrous electrodes FE, an intersect portion where adjacent fibrous electrodes FE intersect each other and a portion where fibrous electrodes FE do not intersect may be substantially the same in a thickness direction or the third direction DR3.

The fibrous electrodes FE may have a straight line, a curved line, or a mixed form of a straight line and a curved line. FIGS. 3B and 3C show that the fibrous electrodes FE have a straight line, but this is presented for convenience of description, and the embodiment is not limited thereto.

The fibrous electrodes FE may include a first fibrous electrode FE1 and a second fibrous electrode FE2. Each of the first fibrous electrode FE1 and the second fibrous electrode FE2 may be disposed on the substrate RB. The first fibrous electrode FE1 and the second fibrous electrode FE2 may be randomly disposed on the substrate RB. A direction in which the first fibrous electrode FE1 and the second fibrous electrode FE2 extend may be random. In an embodiment, the first fibrous electrode FE1 and the second fibrous electrode FE2 may be integral with each other. For example, the first fibrous electrode FE1 and the second fibrous electrode FE2 may be provided as a single body. The first fibrous electrode FE1 and the second fibrous electrode FE2 may be disposed on the substrate RB and may be integral with each other.

The first fibrous electrode FE1 and the second fibrous electrode FE2 may have different widths in a plan view. The first fibrous electrode FE1 may have a first width WT₁ in a plan view. The second fibrous electrode FE2 may have a second width WT₂ in a plan view.

The first width WT₁ and the second width WT₂ may be different from each other. The second width WT₂ of the second fibrous electrode FE2 may be greater than the first width WT₁ of the first fibrous electrode FE1.

The first width WT₁ of the first fibrous electrode FE1 may have a nano-scale width. In an embodiment, the first width WT₁ of the first fibrous electrode FE1 may be in a range of about 300 nm to about 500 nm. In case that the first width WT₁ of the first fibrous electrode FE1 is less than about 300 nm, the first electrode EL1 may have deterioration in mechanical durability due to a small width, resulting in damage such as cracks. In case that the first width WT₁ of the first fibrous electrode FE1 is greater than about 500 nm, an electrode satisfying a desired resistance value and light transmittance may be not achieved.

The second width WT₂ of the second fibrous electrode FE2 may have a micro-scale width. In an embodiment, the second width WT₂ of the second fibrous electrode FE2 may be in a range of about 2 μm to about 3 μm. In case that the second width WT₂ of the second fibrous electrode FE2 is less than about 2 μm, the fibrous electrode FE may have a reduced area ratio, and the light emitting element ED may thus have deterioration in luminous efficiency. In case that the second width WT₂ of the second fibrous electrode FE2 is greater than about 3 μm, a space through which light passes may be reduced due to a large width to cause a reduction in light transmittance. As used herein, “nano-scale” may be a value in the nanometer range of less than about 1 μm, and “micro-scale” may be a value in the micrometer range of about 1 μm to about 1 mm.

The first fibrous electrode FE1 and the second fibrous electrode FE2 may include a same material. The first fibrous electrode and the second fibrous electrode may each independently include silver (Ag), gold (Au), platinum (Pt), aluminum (Al), copper (Cu), tin (Sn), gallium (Ga), indium (In), nickel (Ni), or any combination thereof. The first fibrous electrode FE1 and the second fibrous electrode FE2 may each independently include silver (Ag), gold (Au), platinum (Pt), aluminum (Al), copper (Cu), tin (Sn), gallium (Ga), indium (In), or nickel (Ni), or the first fibrous electrode FE1 and the second fibrous electrode FE2 may each independently include a mixture of two or more materials selected from the group consisting of silver (Ag), gold (Au), platinum (Pt), aluminum (Al), copper (Cu), tin (Sn), gallium (Ga), indium (In), and nickel (Ni).

An electrode opening E-OP may be defined in the fibrous electrodes FE. The fibrous electrodes FE may include a lower surface adjacent to the substrate RB and an upper surface facing the lower surface. The fibrous electrodes FE may have openings defined from the upper surface of the fibrous electrodes FE to the lower surface of the fibrous electrodes FE as shown in FIG. 3A. An upper surface of the substrate RB may be exposed through the electrode opening E-OP, and the buffer layer BFL described above may contact the exposed upper surface of the substrate RB. As used herein, the “upper surface” may be a surface placed on an upper portion with respect to the third direction DR3, and the “lower surface” may be a surface placed on a lower portion with respect to the third direction DR3.

The electrode opening E-OP may have various shapes. As the fibrous electrodes FE are randomly disposed on the substrate RB, the electrode opening E-OP defined in the fibrous electrodes FE may have various shapes. For example, the electrode opening E-OP may have a polygonal shape or an irregular shape, but is not limited thereto.

The fibrous electrodes FE may have a first thickness h₁. The first thickness h₁ of the fibrous electrodes FE may be measured in the third direction DR3 which is a thickness direction. In an embodiment, the first thickness h₁ may be in a range of about 20 nm to about 160 nm. For example, the first thickness h₁ may be about 50 nm, but is not limited thereto. In case that the first thickness h₁ of the fibrous electrodes FE satisfies the above-described range, the first electrode EL1 applied to the light emitting element ED may have a reduced sheet resistance and a greater transmittance, and may thus increase luminous efficiency. In case that the first thickness h₁ of the fibrous electrodes FE is less than about 20 nm, the first electrode EL1 applied to the light emitting element ED may have a greater sheet resistance and a reduced transmittance, and may thus deteriorate luminous efficiency. In case that the first thickness h₁ of the of fibrous electrodes FE is greater than about 160 nm, the fibrous electrodes FE may have a greater peak to valley, and may accordingly cause an electrical shortage and a current leakage. As used herein, “peak to valley” may be a maximum height from the lower surface to the upper surface of the fibrous electrodes FE.

Each of the first fibrous electrode FE1 and the second fibrous electrode FE2 may have a predetermined (or selectable) thickness in the third direction DR3. Each of the first fibrous electrode FE1 and the second fibrous electrode FE2 may have a first thickness h₁. For example, the first fibrous electrode FE1 may have a thickness in the third direction DR3 which is substantially the same as a thickness of the second fibrous electrode FE2 in the third direction DR3. As used herein, it should be understood that “substantially the same” may indicate that numerical ranges such as width and thickness are the same, including not only a case in which numerical ranges such as width and thickness are physically the same, but also errors upon processes, that may generally occur.

The first electrode EL1 may include a buffer layer BFL. The buffer layer BFL may be disposed on the fibrous electrodes FE. The buffer layer BFL may be disposed on the first fibrous electrode FE1 and the second fibrous electrode FE2. The buffer layer BFL may cover the first fibrous electrode FE1 and the second fibrous electrode FE2. The buffer layer BFL may fill the electrode opening E-OP formed in the fibrous electrodes FE and may cover the entirety of the first fibrous electrode FE1 and the second fibrous electrode FE2. The buffer layer BFL may be disposed on the fibrous electrodes FE to form parallel resistance with the fibrous electrodes FE. The buffer layer BFL may serve to provide a uniform current supply to the light emitting element ED through the forming of parallel resistance with the fibrous electrodes FE. The buffer layer BFL may serve to protect the fibrous electrodes FE from an external environment. For example, the buffer layer BFL may prevent damage to the fibrous electrodes FE by external heat and protect the fibrous electrodes FE against strong acid/strong base and plasma environments.

An upper surface of the buffer layer BFL may be flat. The upper surface of the buffer layer BFL may be parallel to a plane defined by the first direction DR1 and the second direction DR2. A step may be formed between the upper surface of the substrate RB and the upper surface of the fibrous electrodes FE. For example, a step may be formed on the upper surface of the substrate RB by the first thickness h₁ of the fibrous electrodes FE. The buffer layer BFL may remove steps formed by the fibrous electrodes FE and provide a flat reference surface to a member disposed on an upper side.

The buffer layer BFL may have a second thickness h₂ in the third direction DR3. The second thickness h₂ may be measured from the upper surface of the substrate RB to the upper surface of the buffer layer BFL in the third direction DR3. The second thickness h₂ of the buffer layer BFL may be greater than the first thickness h₁ of the fibrous electrodes FE.

In an embodiment, the second thickness h₂ of the buffer layer BFL may be in a range of about 40 nm to about 240 nm. However, the embodiment of the disclosure is not limited thereto. In case that the second thickness h₂ of the buffer layer BFL is less than about 40 nm, a difference in sheet resistance between the buffer layer BFL and the fibrous electrodes FE may increase, and the light emitting element ED may thus have deteriorated electrical properties. In case that the second thickness h₂ of the buffer layer BFL is greater than about 240 nm, the light emitting element ED may have deteriorated durability and reduced light transmittance due to a large thickness, and may thus have a decrease in luminous efficiency. As the second thickness h₂ of the buffer layer BFL satisfies the above-described range, the first electrode EL1 exhibiting both low sheet resistance and high light transmittance may be obtained, and in case that the first electrode EL1 is applied to the light emitting element ED, the light emitting element ED may have increased luminous efficiency.

The buffer layer BFL may include a transparent conductive oxide (TCO) and/or a conductive polymer. In an embodiment, the buffer layer BFL may include a transparent conductive oxide (TCO). The buffer layer BFL may include a transparent conductive oxide such as indium tin oxide (ITO), indium zinc oxide (IZO), zinc oxide (ZnO), or indium tin zinc oxide (ITZO). In an embodiment, the buffer layer BFL may include indium zinc oxide (IZO). In another embodiment, the buffer layer BFL may include a conductive polymer such as a polythiophene-based compound, a polypyrrole-based compound, a polyaniline-based compound, a polyacetylene-based compound, a polyphenylene-based compound, and a mixture thereof. For example, the buffer layer BFL may include a PEDOT:PSS (Poly(3,4-ethylene dioxythiophene):poly(styrenesulfonate) compound.

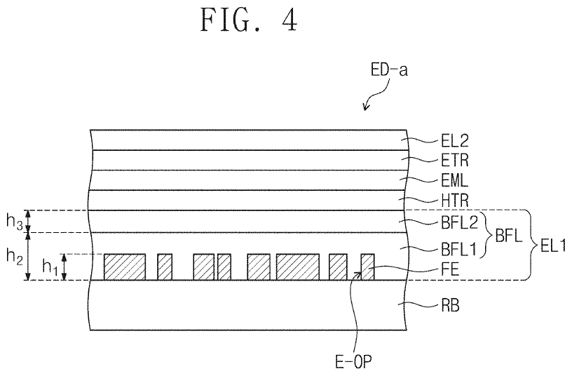

FIG. 4 is a schematic cross-sectional view of a light emitting element according to an embodiment of the disclosure. Hereinafter, in describing a light emitting element according to an embodiment of the disclosure with reference to FIG. 4, the same reference numerals are given to components that are the same as the components described above with reference to FIGS. 1 to 3C, and detailed descriptions thereof will be omitted.

Referring to FIG. 4, in a light emitting element ED-a according to an embodiment, the first electrode EL1 may have a structure different from that of the light emitting element ED shown in FIG. 3A. In the light emitting element ED-a shown in FIG. 4, the buffer layer BFL may have a multi-layered structure, unlike the light emitting element ED shown in FIG. 3A. The buffer layer BFL may include a first buffer layer BFL1 and a second buffer layer BFL2. The first buffer layer BFL1 may be disposed on the substrate RB, and the second buffer layer BFL2 may be disposed on the first buffer layer BFL1.

The first buffer layer BFL1 may be disposed on the fibrous electrodes FE. The first buffer layer BFL1 may cover the fibrous electrodes FE. The second buffer layer BFL2 may be disposed on the first buffer layer BFL1. The second buffer layer BFL2 may be directly disposed on the first buffer layer BFL1 to cover an upper surface of the first buffer layer BFL1. The first buffer layer BFL1 may fill the electrode opening E-OP formed in the fibrous electrodes FE and may cover the entirety of the fibrous electrodes FE.

In an embodiment, the second thickness h₂ of the first buffer layer BFL1 may be in a range of about 40 nm to about 240 nm. In case that the second thickness h₂ of the first buffer layer BFL1 is less than about 40 nm, a difference in sheet resistance between the first buffer layer BFL1 and the fibrous electrodes FE may increase, and the light emitting element ED-a may thus have deteriorated electrical properties. In case that the second thickness h₂ of the first buffer layer BFL1 is greater than about 240 nm, the light emitting element ED-a may have deteriorated durability and reduced light transmittance due to a thick thickness, may thus have a decrease in luminous efficiency. As the second thickness h₂ of the first buffer layer BFL1 satisfies the aforementioned range, the first electrode EL1 exhibiting both low sheet resistance and high light transmittance may be realized.

The first buffer layer BFL1 may include a transparent conductive oxide (TCO). The first buffer layer BFL1 may include a transparent conductive oxide such as indium tin oxide (ITO), indium zinc oxide (IZO), zinc oxide (ZnO), or indium tin zinc oxide (ITZO). In an embodiment, the first buffer layer BFL1 may include indium zinc oxide (IZO).

The second buffer layer BFL2 may be disposed on the first buffer layer BFL1. The second buffer layer BFL2 may be directly disposed on the upper surface of the first buffer layer BFL1. The second buffer layer BFL2 may be spaced apart from the fibrous electrodes FE in the third direction DR3. The second buffer layer BFL2 may be disposed to be spaced apart from the fibrous electrodes FE with the first buffer layer BFL1 therebetween. An upper surface of the second buffer layer BFL2 may be flat. The upper surface of the second buffer layer BFL2 may be parallel to a plane defined by the first direction DR1 and the second direction DR2. As the second buffer layer BFL2 is disposed on the first buffer layer BFL1, the first electrode EL1 may have a reduction in overall surface roughness, and the light emitting element ED-a may thus have an increased durability. As used herein, the surface roughness may be an arithmetic mean roughness (Ra).

The second buffer layer BFL2 may have a third thickness h₃ in the third direction DR3. In an embodiment, the third thickness h₃ of the second buffer layer BFL2 may be in a range of about 100 nm to about 300 nm. In case that the third thickness h₃ of the second buffer layer BFL2 is less than about 100 nm, the thin film may be too thin to serve as a flat film. In case that the third thickness h₃ of the second buffer layer BFL2 is greater than about 300 nm, mechanical properties may be deteriorated, and light transmittance may be reduced due to the thick thin film.

The second buffer layer BFL2 may include a conductive polymer. Examples of the conductive polymer may include a polythiophene-based compound, a polypyrrole-based compound, a polyaniline-based compound, a polyacetylene-based compound, a polyphenylene-based compound, and a mixture thereof, and for example, polythiophene-based compounds or PEDOT:PSS(Poly(3,4-ethylene dioxythiophene):poly(styrenesulfonate) may be used for the second buffer layer BFL2.

The hole transport region HTR may be provided on the first electrode EL1. The hole transport region HTR may include at least one of a hole injection layer, a hole transport layer, a buffer layer or a light emitting auxiliary layer, and an electron blocking layer. The hole transport region HTR may have, for example, a thickness in a range of about 50 Å to about 15,000 Å.

The hole transport region HTR may be a layer formed of a single material, a layer formed of different materials, or a structure having multiple layers formed of different materials.

For example, the hole transport region HTR may have a single-layer structure formed of a hole injection layer or a hole transport layer, or a single-layer structure formed of a hole injection material or a hole transport material. The hole transport region HTR may have a single-layer structure formed of different materials, or a structure in which a hole injection layer/hole transport layer, a hole injection layer/hole transport layer/buffer layer, a hole injection layer/buffer layer, a hole transport layer/buffer layer, or a hole injection layer/hole transport layer/electron blocking layer are stacked in order from the first electrode EL1, but the embodiment of the disclosure is not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-2 below.

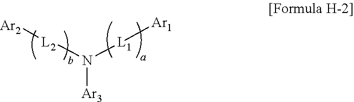

In Formula H-2 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In case that a or b is an integer of 2 or greater, multiple L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-2, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-2, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, the compound represented by Formula H-2 above may be a monoamine compound. In another embodiment, the compound represented by Formula H-2 may be a diamine compound in which at least one of Ar₋₁ to Ar₃ includes an amine group as a substituent. In still another embodiment, the compound represented by Formula H-2 may be a carbazole-based compound wherein at least of Ar₁ and Ar₂ may include a substituted or unsubstituted carbazole group or a substituted or unsubstituted fluorene-based group.

The compound represented by Formula H-2 may be a compound selected from Compound Group H. However, the compounds listed in Compound Group H below are presented as an example, and the compound represented by Formula H-2 is not limited to the those listed in Compound Group H below.

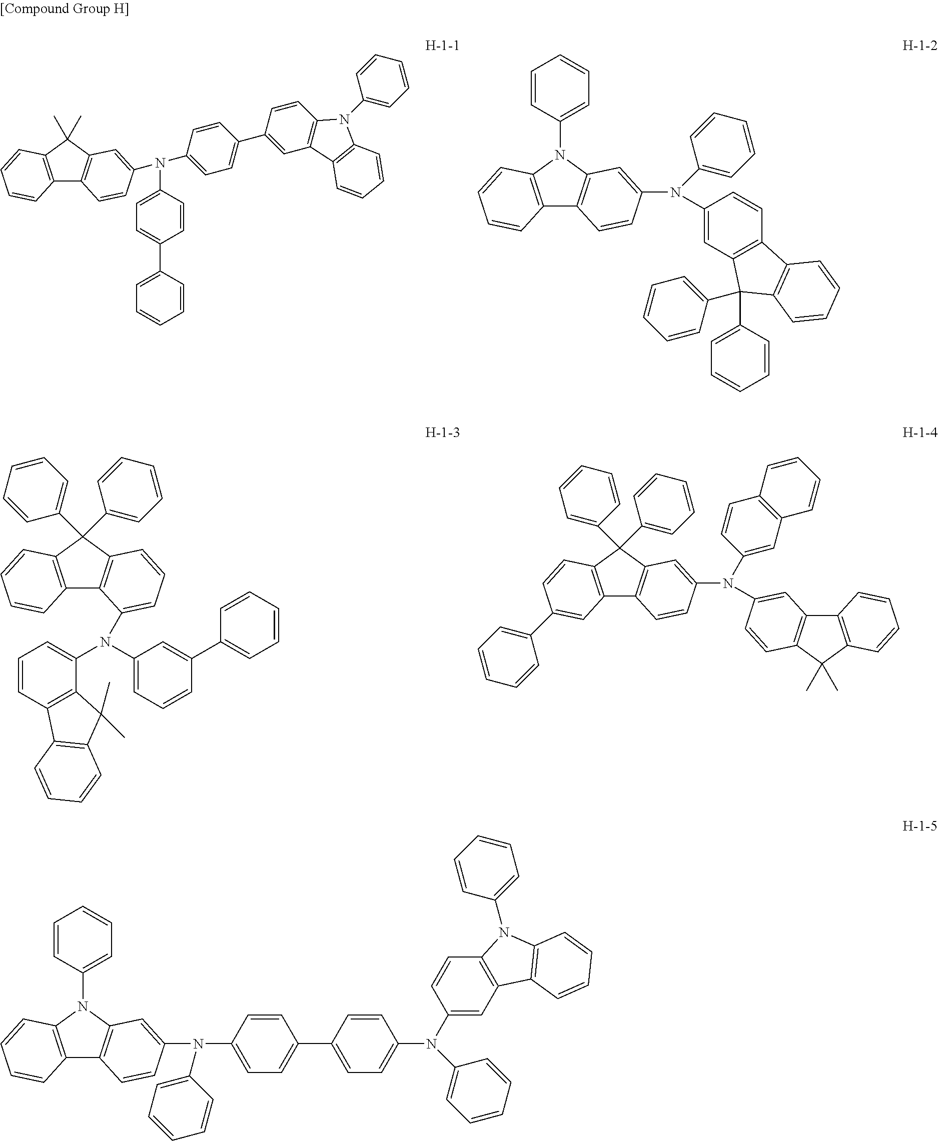 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

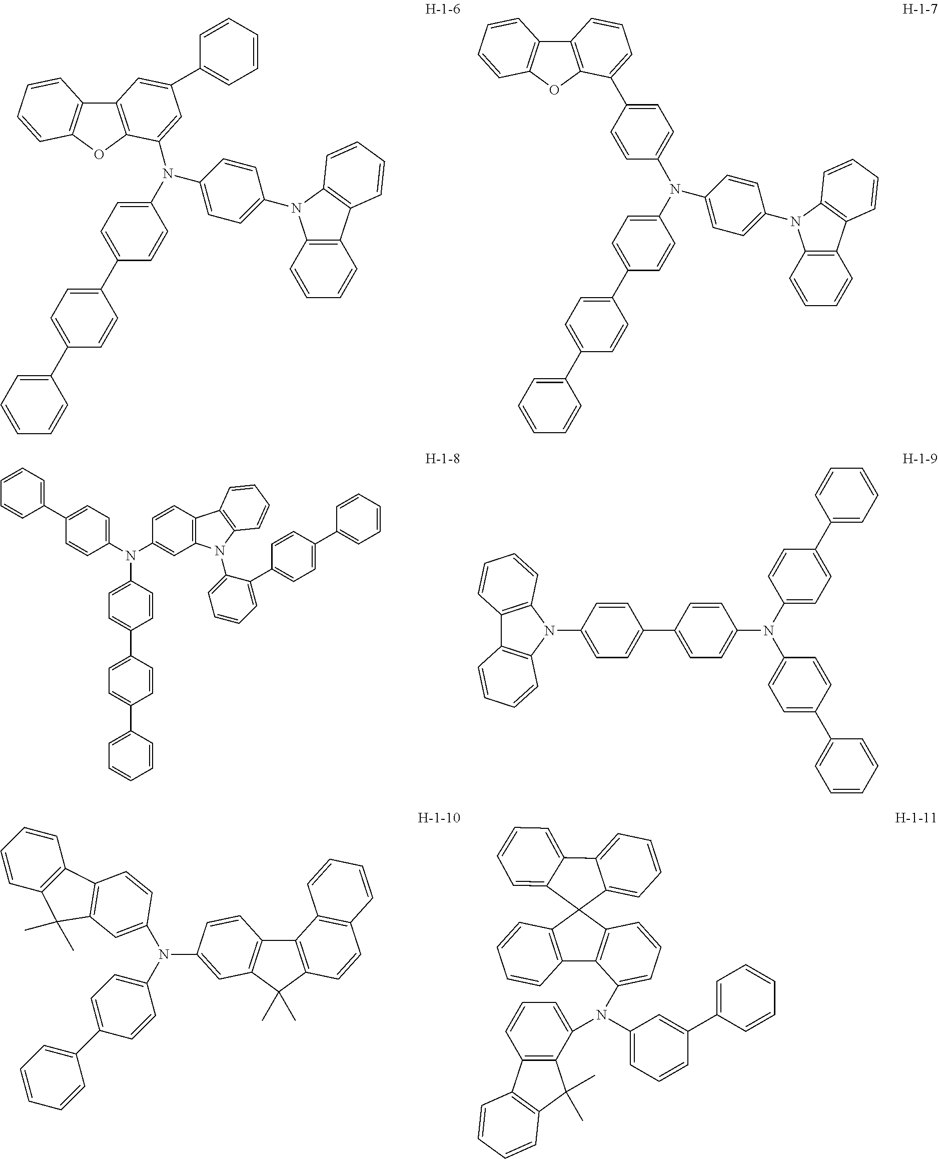

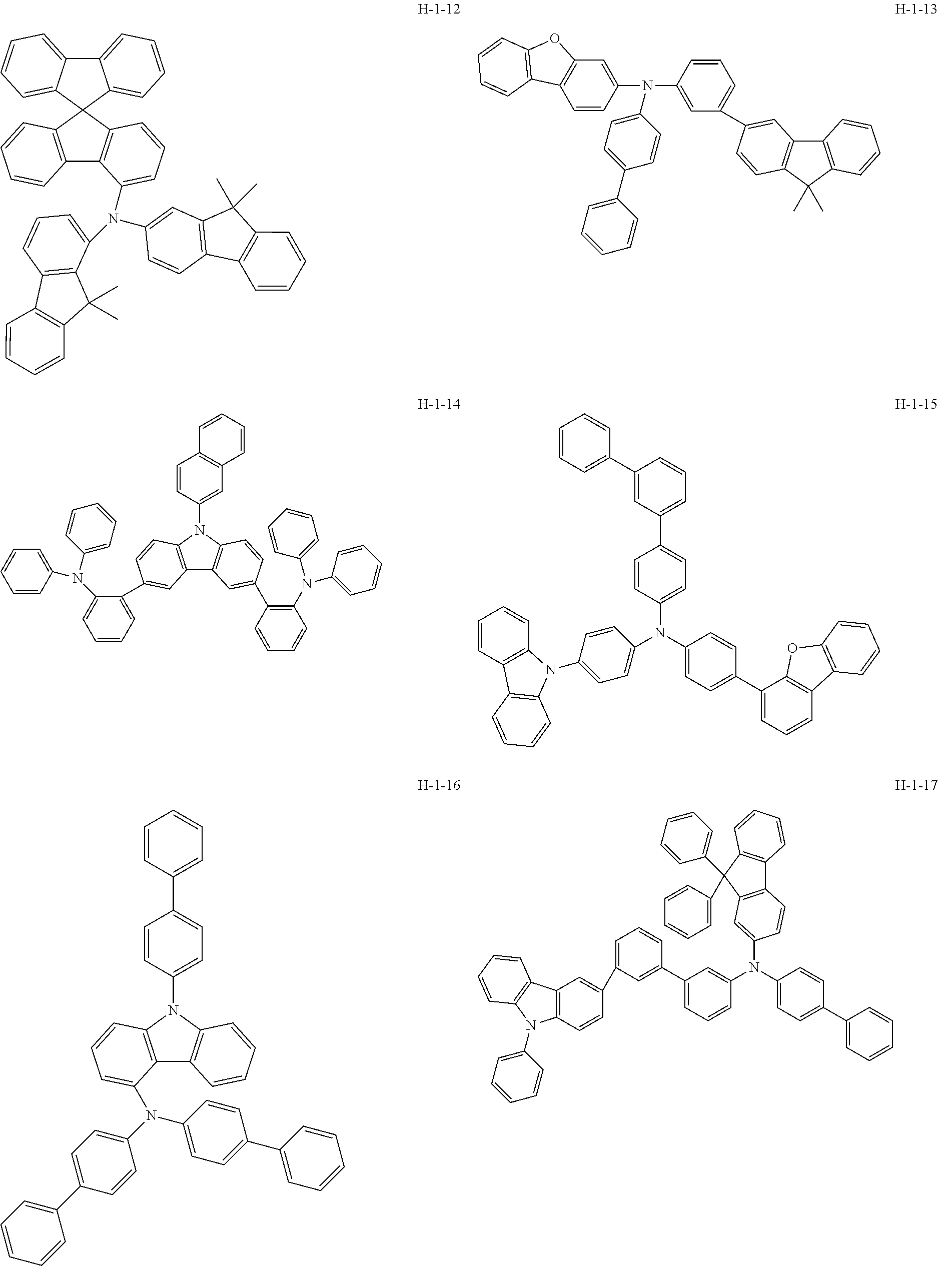

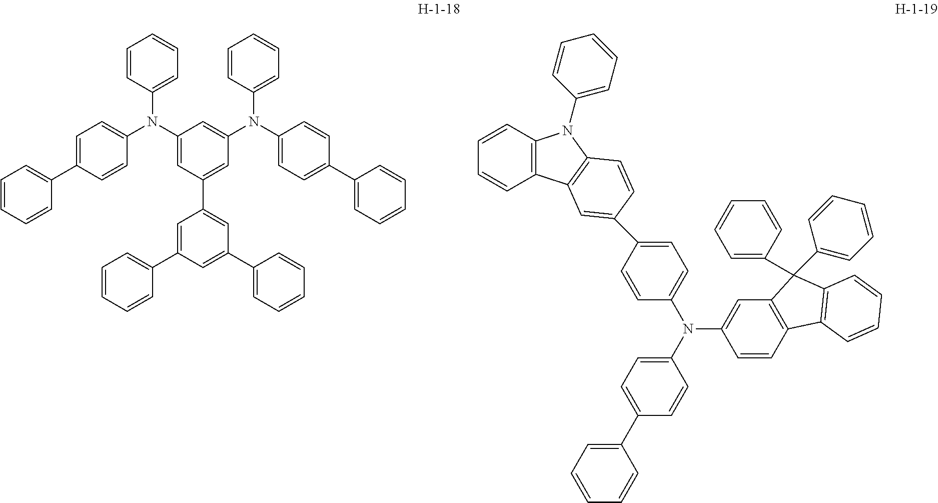 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenyl amino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HAT-CN), etc.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphtalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

At least one of the hole injection layer, the hole transport layer, and the electron blocking layer (not shown) in the hole transport region HTR may include the compounds that may be included in the hole transport region described above.

The hole transport region HTR may have a thickness in a range of about 100 Å to about 10,000 Å. For example, the hole transport region HTR may have a thickness in a range of about 100 Å to about 5,000 Å. In case that the hole transport region HTR includes a hole injection layer, the hole injection layer may have a thickness in a range of, for example, about 30 Å to about 1,000 Å. In case that the hole transport region HTR includes a hole transport layer, the hole transport layer may have a thickness in a range of about 30 Å to about 1,000 Å. In case that the hole transport region HTR includes an electron blocking layer, the electron blocking layer may have a thickness in a range of, for example, about 10 Å to about 1,000 Å. In case that the thicknesses of the hole transport region HTR, the hole injection layer, the hole transport layer, and the electron blocking layer satisfy the above-described ranges, satisfactory hole transport properties may be obtained without a substantial increase in driving voltage.

The hole transport region HTR may further include a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, and cyano group-containing compounds, but is not limited thereto. For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f. 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but is not limited thereto.

As described above, the hole transport region HTR may further include at least one of a buffer layer or an electron blocking layer in addition to the hole injection layer and the hole transport layer. The buffer layer may compensate a resonance distance according to the wavelength of light emitted from an emission layer EML, and may thus increase luminous efficiency. Materials which may be included in the hole transport region HTR may be used as materials included in the buffer layer. The electron blocking layer may be a layer that serves to prevent electrons from being injected from the electron transport region ETR to the hole transport region HTR.

The emission layer EML may be provided on the hole transport region HTR. The emission layer EML may have, for example, a thickness in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

In the light emitting elements ED and ED-a according to an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting elements ED and ED-a according to the embodiment shown in FIGS. 3A and 4, the emission layer EML may include a host and a dopant, and the emission layer EML may include a compound represented by Formula E-1 below. The compound represented by Formula E-1 below may be used as a fluorescent host.

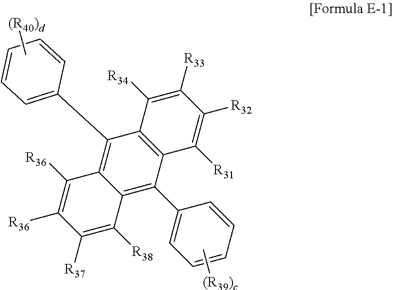

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 1 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one of Compounds E1 to E19 below.

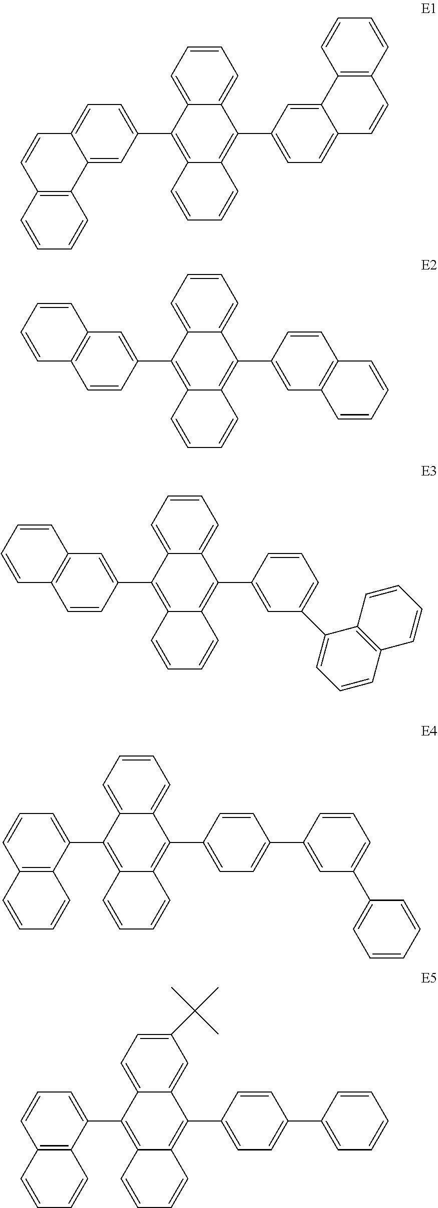

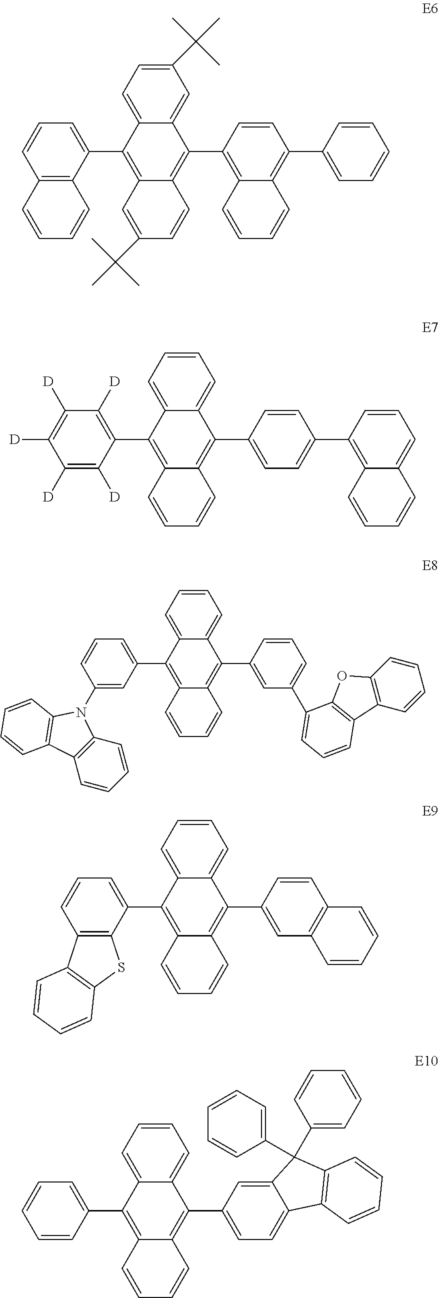

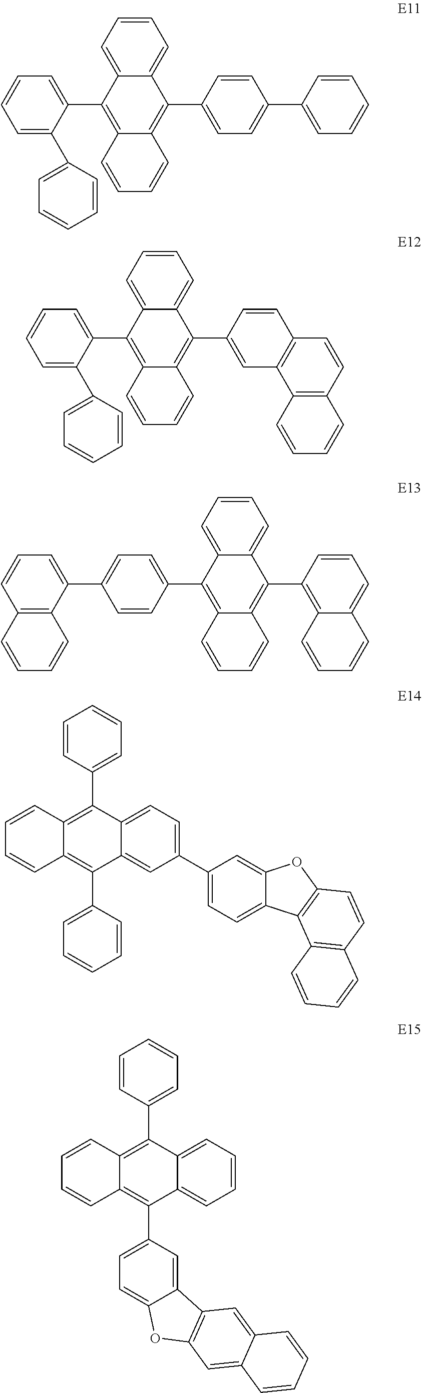

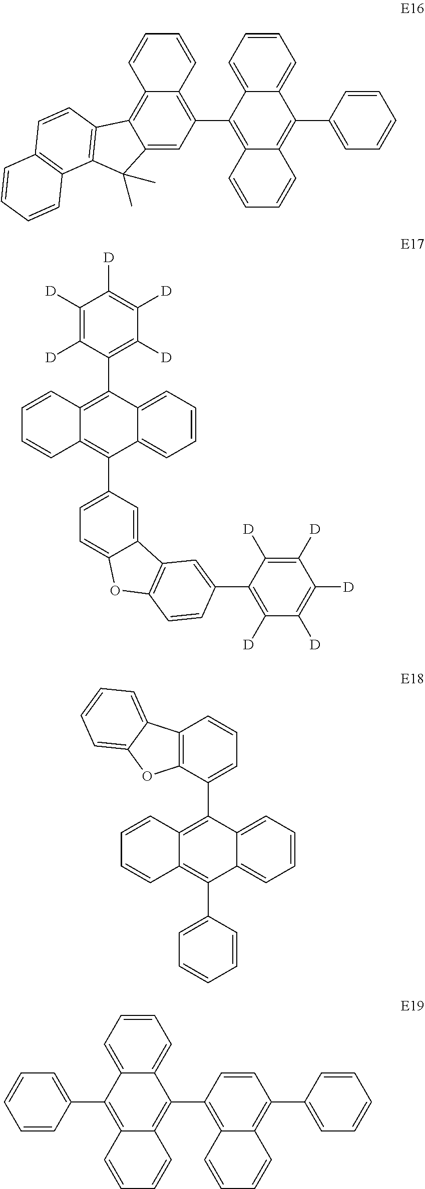

In an embodiment, the emission layer EML may include a first compound represented by Formula E-1, and at least one of a second compound represented by Formula HT-1 below, a third compound represented by Formula ET-1 below, and a fourth compound represented by Formula M-b below.

In an embodiment, the second compound may be used as a hole transporting host of the emission layer EML.

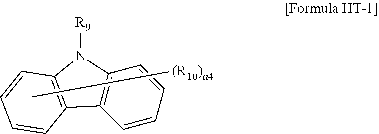

In Formula HT-1, a4 may be an integer of 0 to 8. In case that a4 is an integer of 2 or greater, multiple R₁₀'s may all be the same or at least one R₁₀ may be different from the others. R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₉ may be a substituted phenyl group, an unsubstituted dibenzofuran group, or a substituted fluorenyl group. R₁₀ may be a substituted or unsubstituted carbazole group.

The second compound may be represented by one of Compound Group 2 below. In Compound Group 2 below, D represents a deuterium atom.

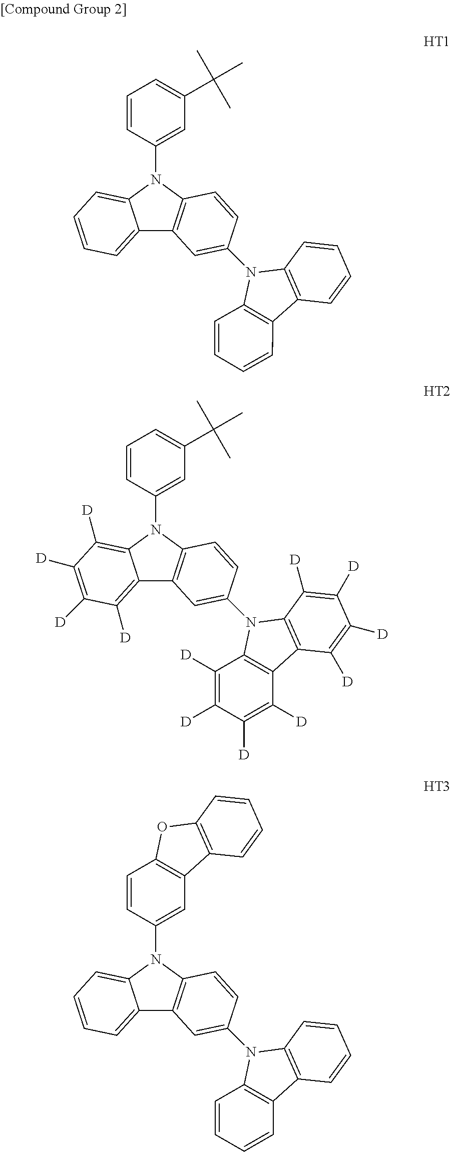

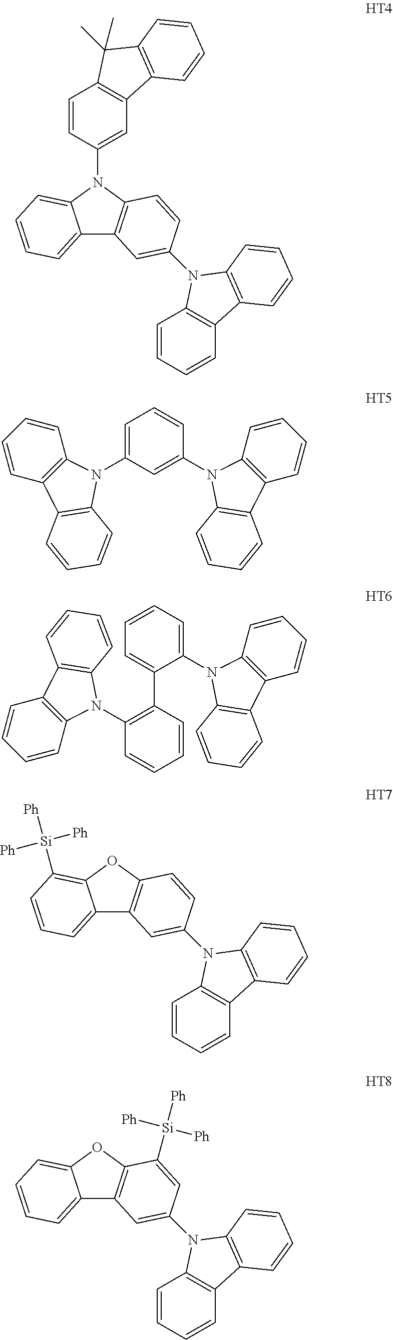

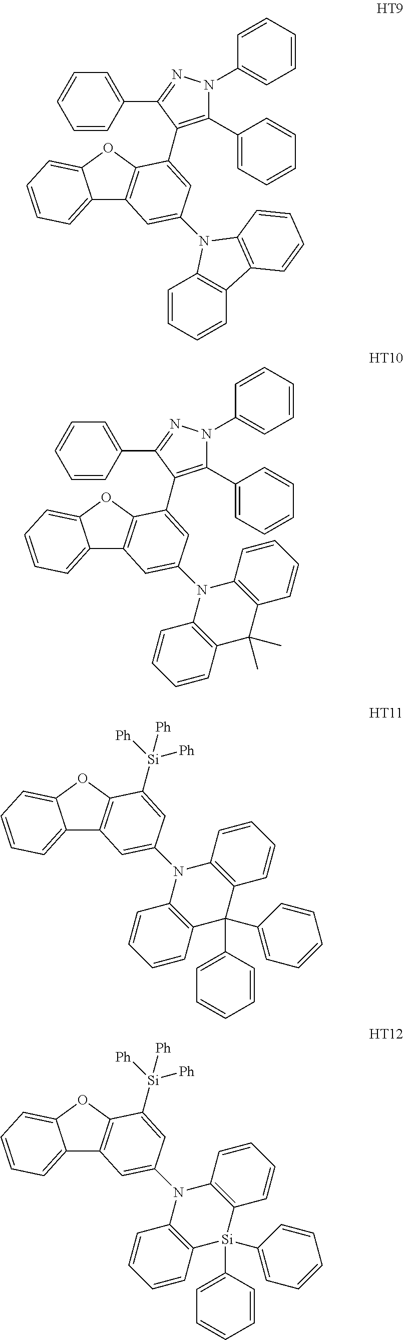

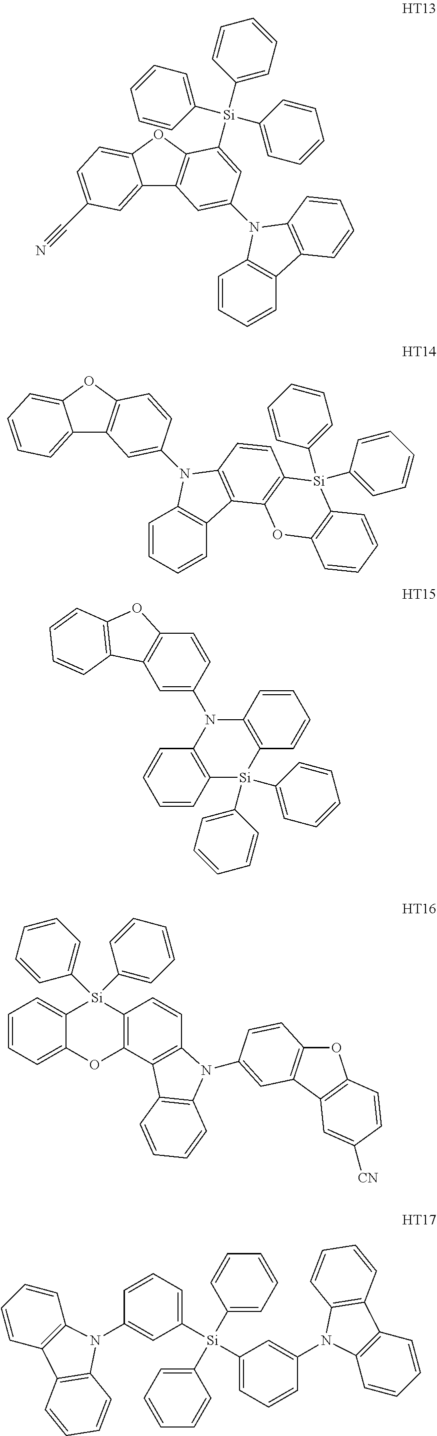 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

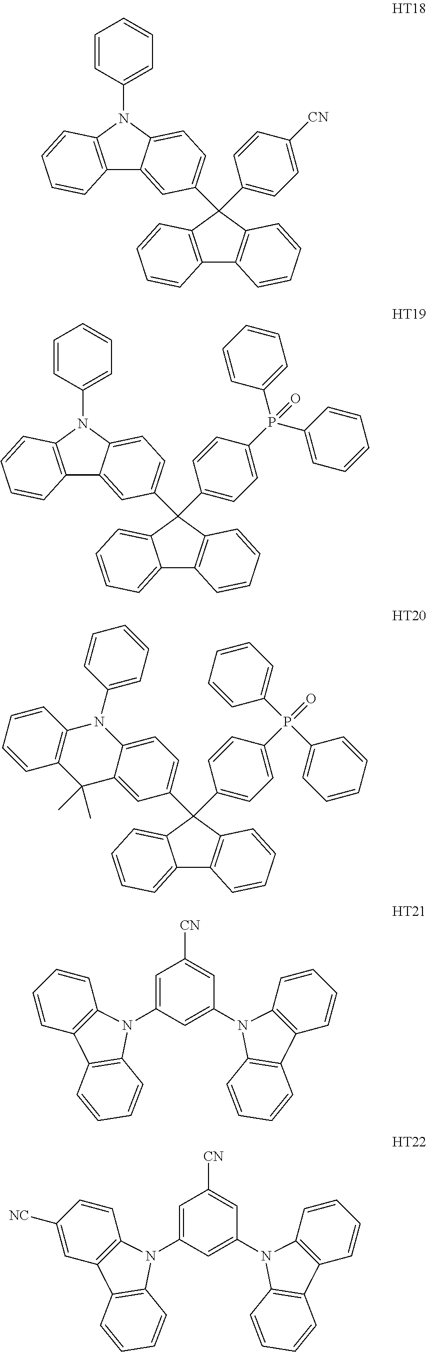

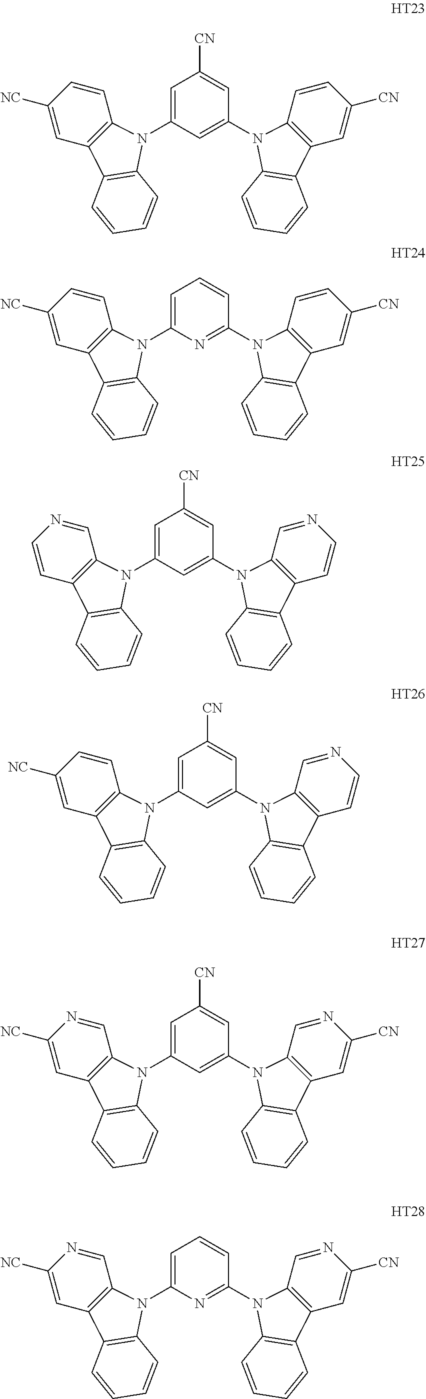 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

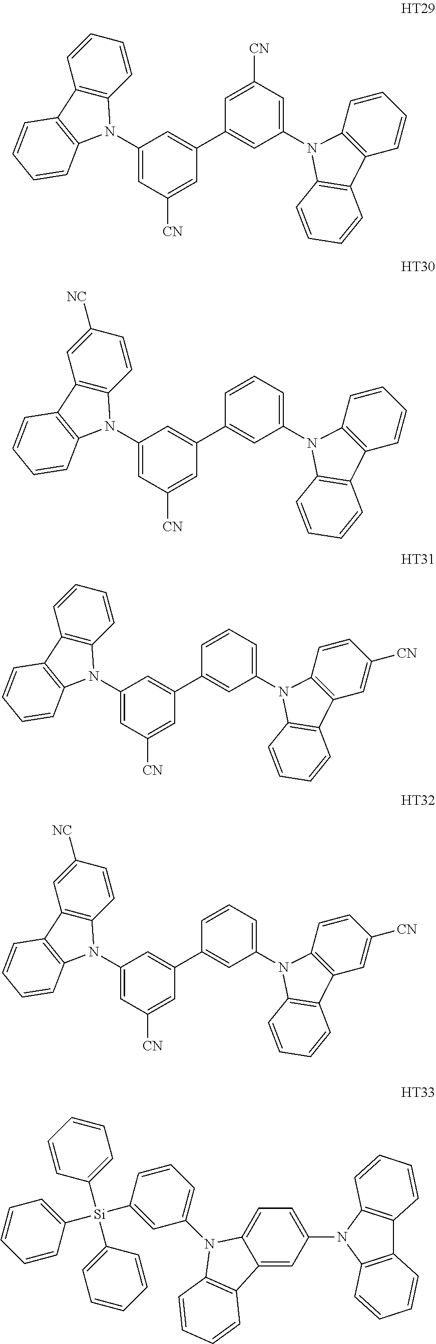 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

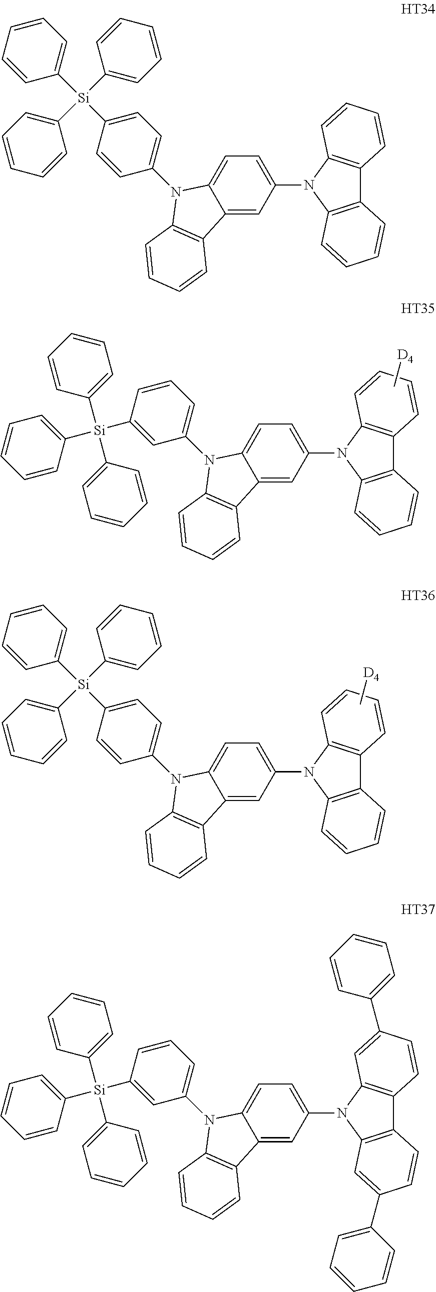

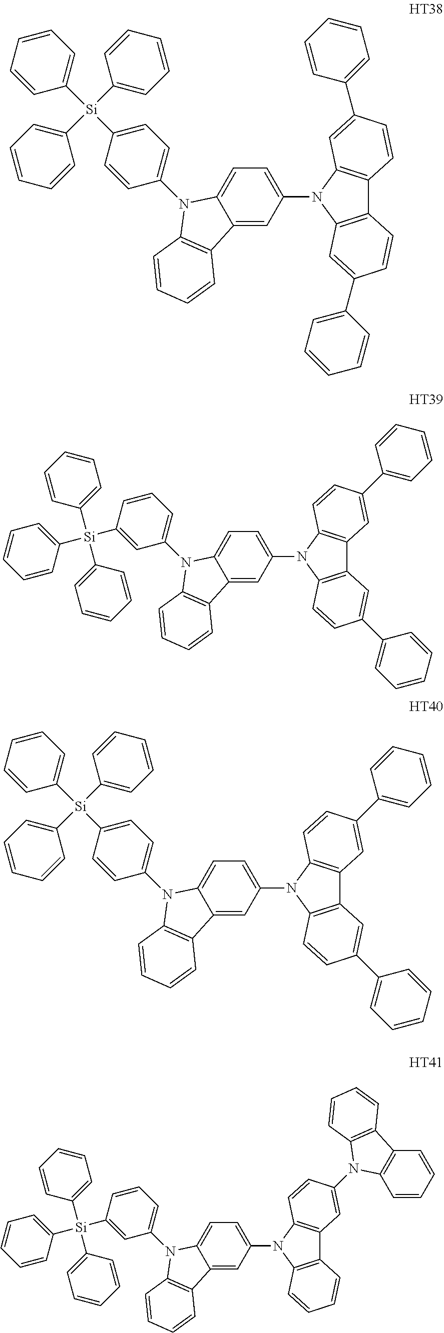 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

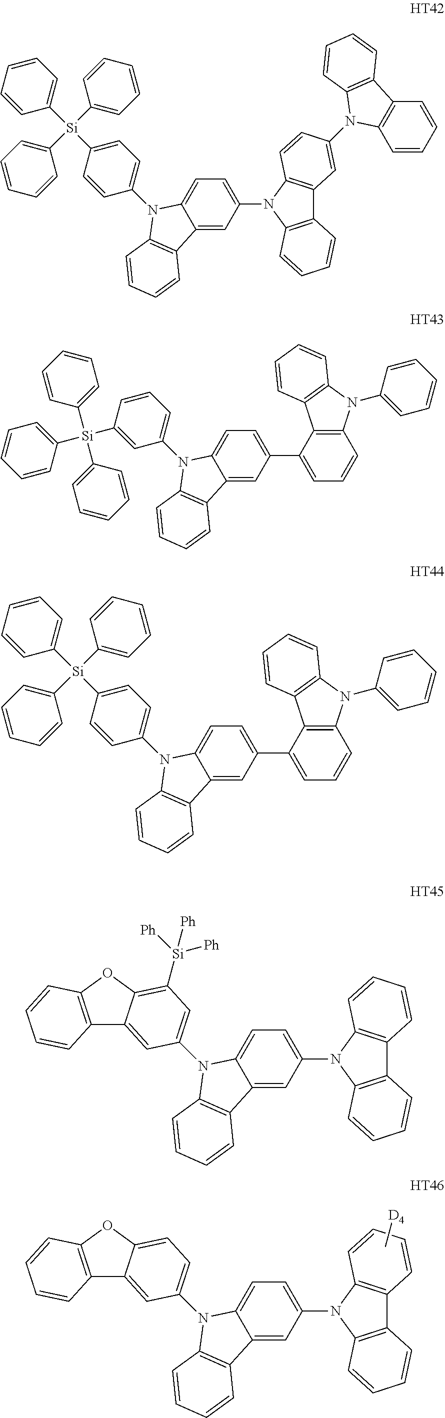

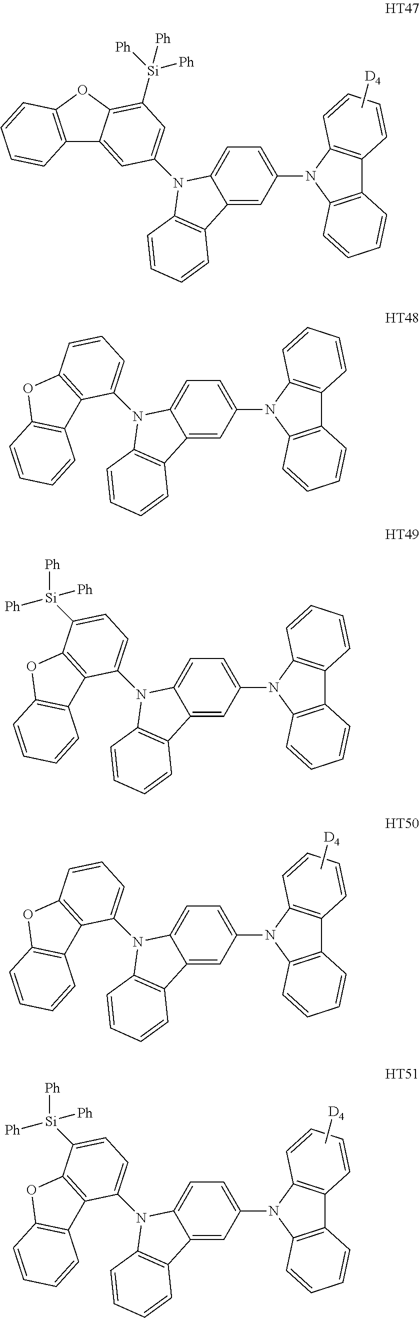

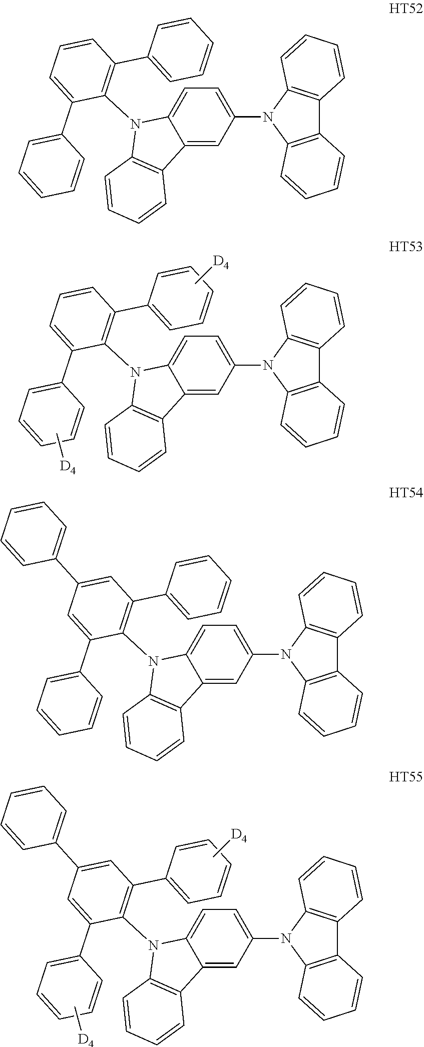

In an embodiment, the emission layer EML may include a third compound represented by Formula ET-1 below. For example, the third compound may be used as an electron transporting host of the emission layer EML.

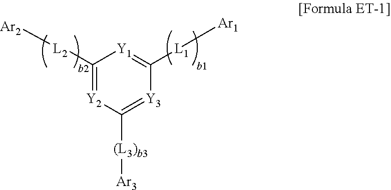

In Formula ET-1, at least one of Y₁ to Y₃ may be N, and another may be C(Rₐ), and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer of 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may a substituted or unsubstituted phenyl group or a substituted or unsubstituted carbazole group.

The third compound may be represented by one of Compound Group 3 below. The light emitting elements ED and ED-a according to an embodiment may include one of Compound Group 3 below. In Compound Group 3 below, D may be a deuterium atom.

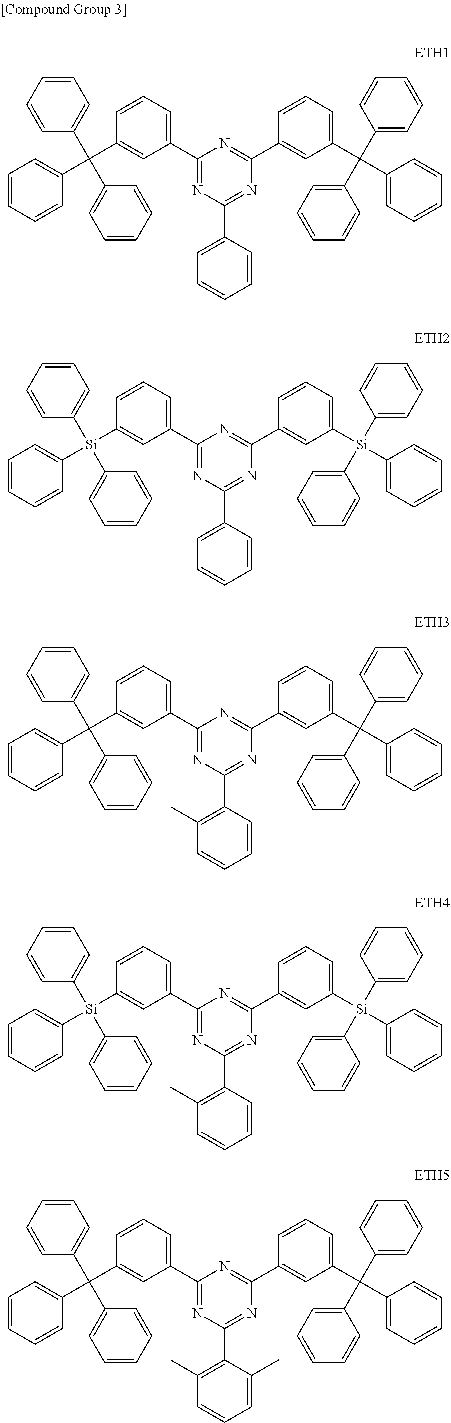

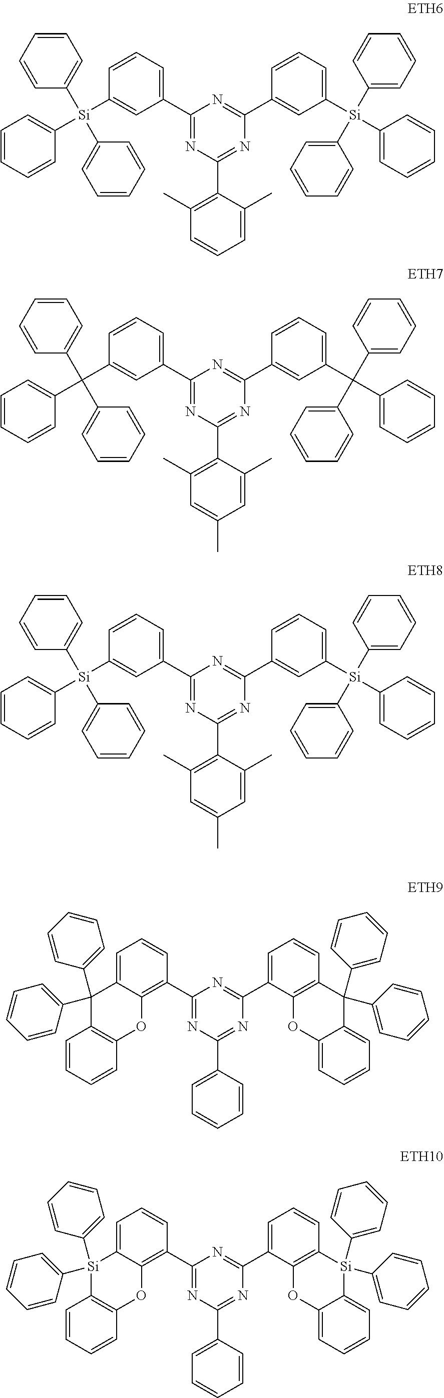

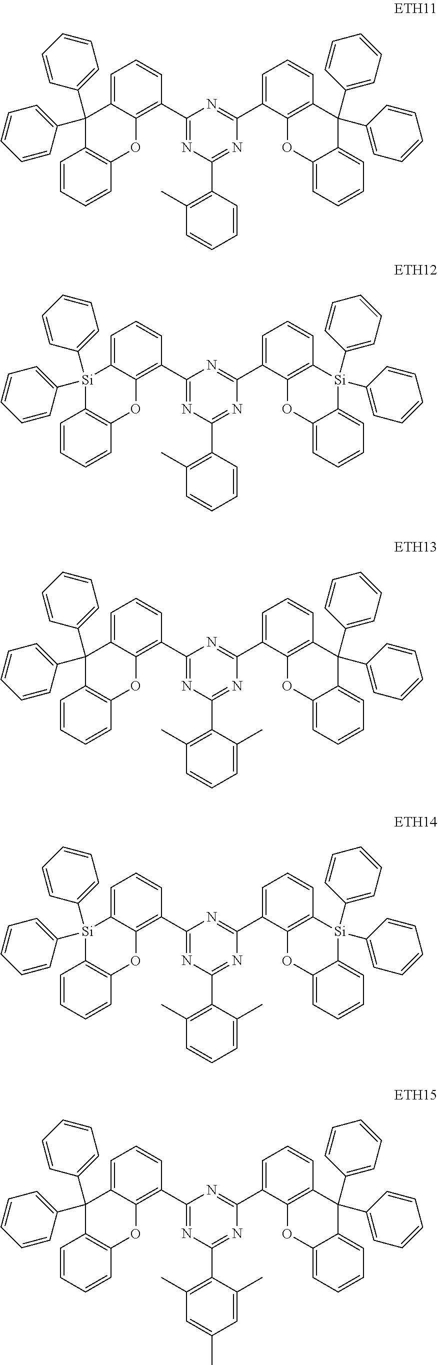

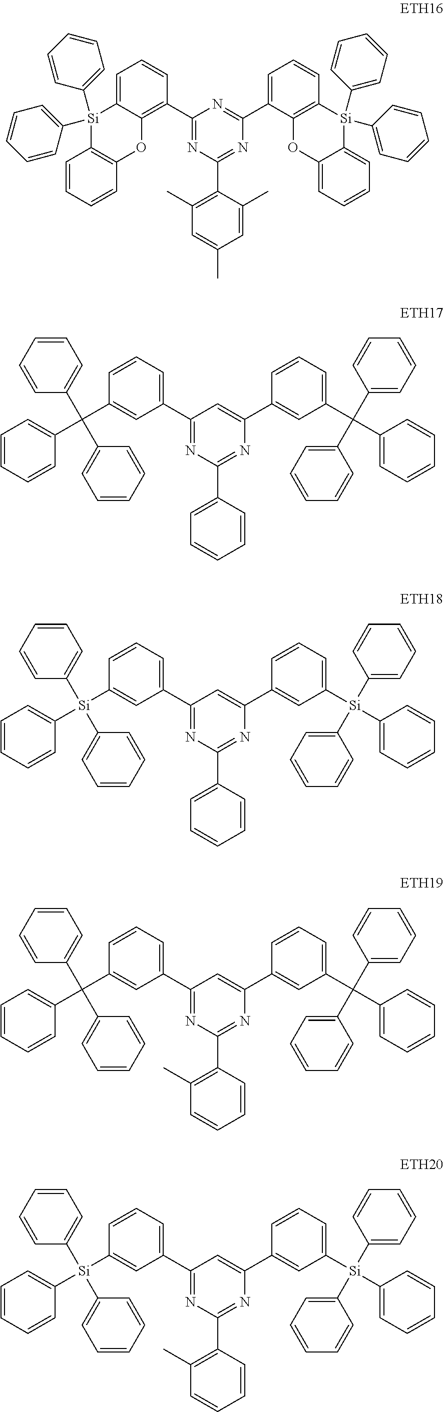

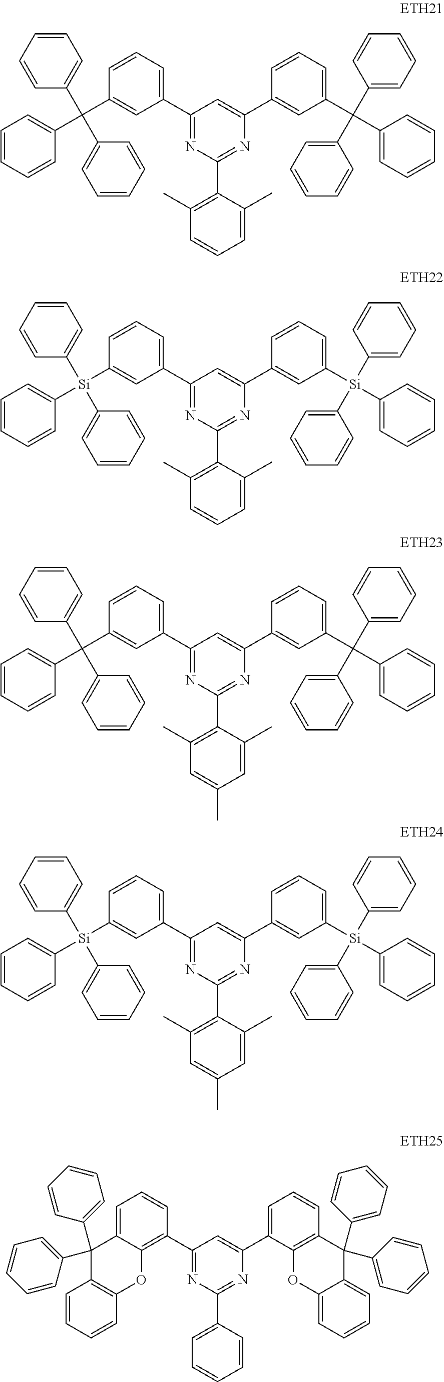

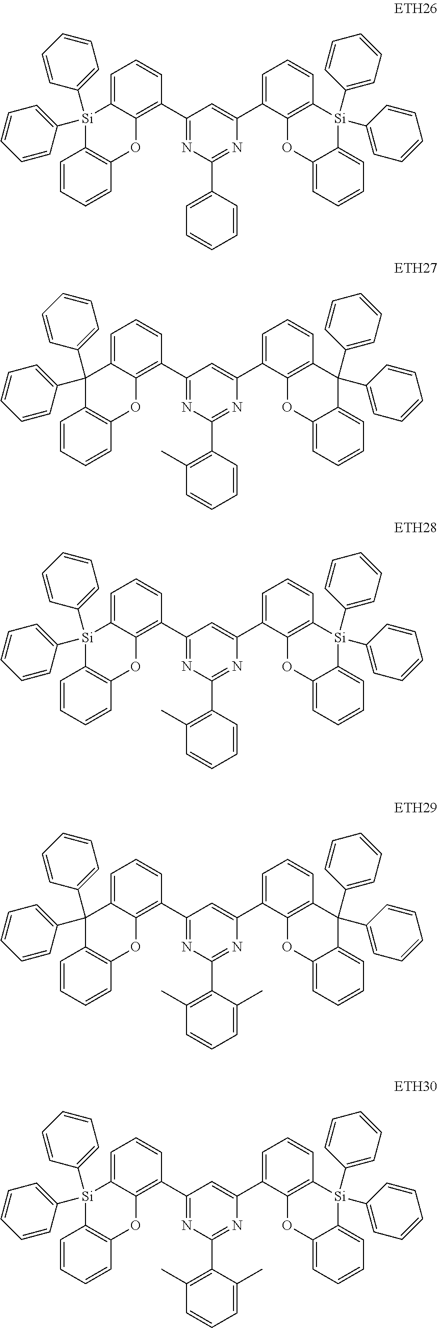

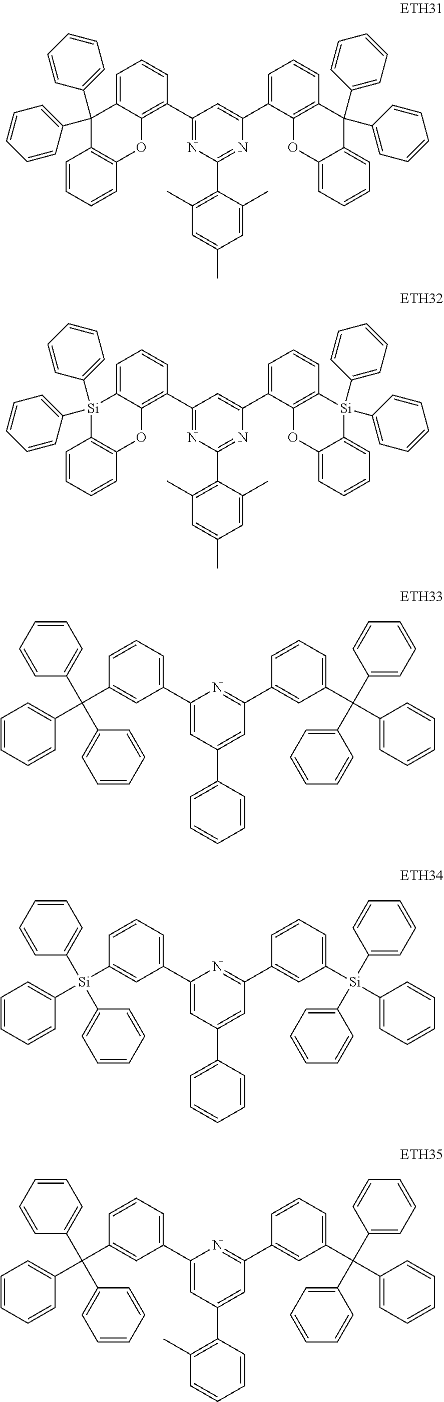

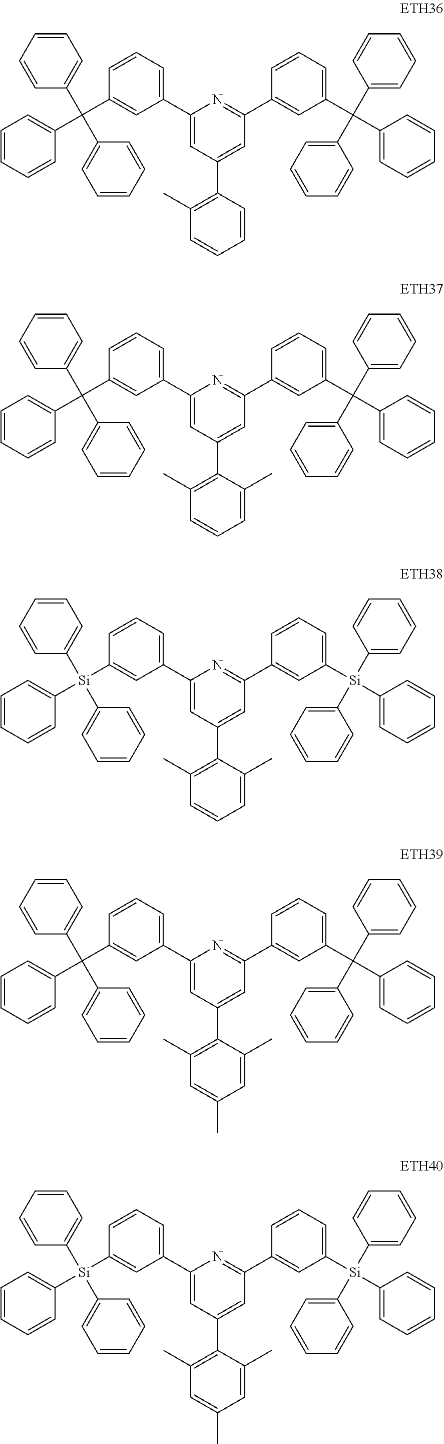

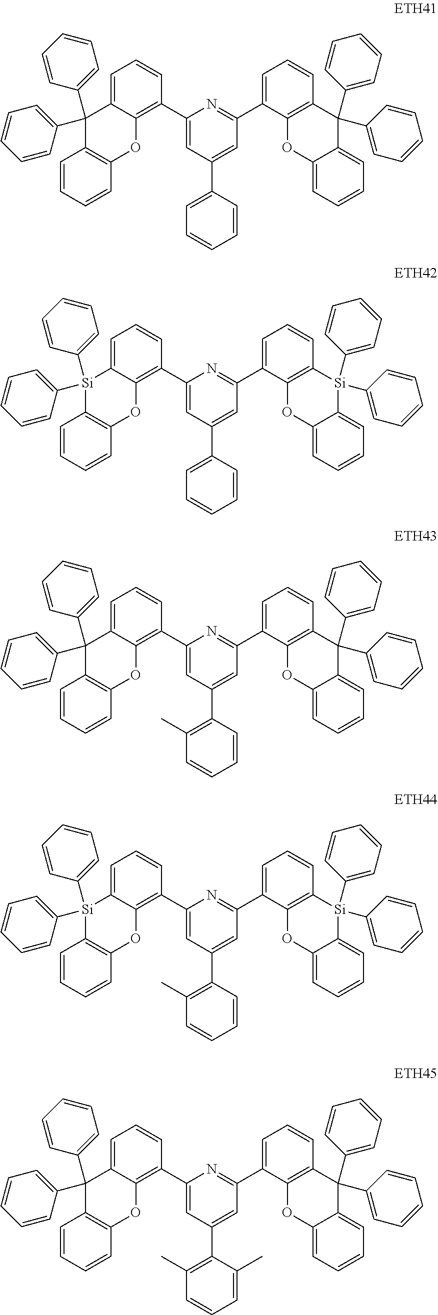

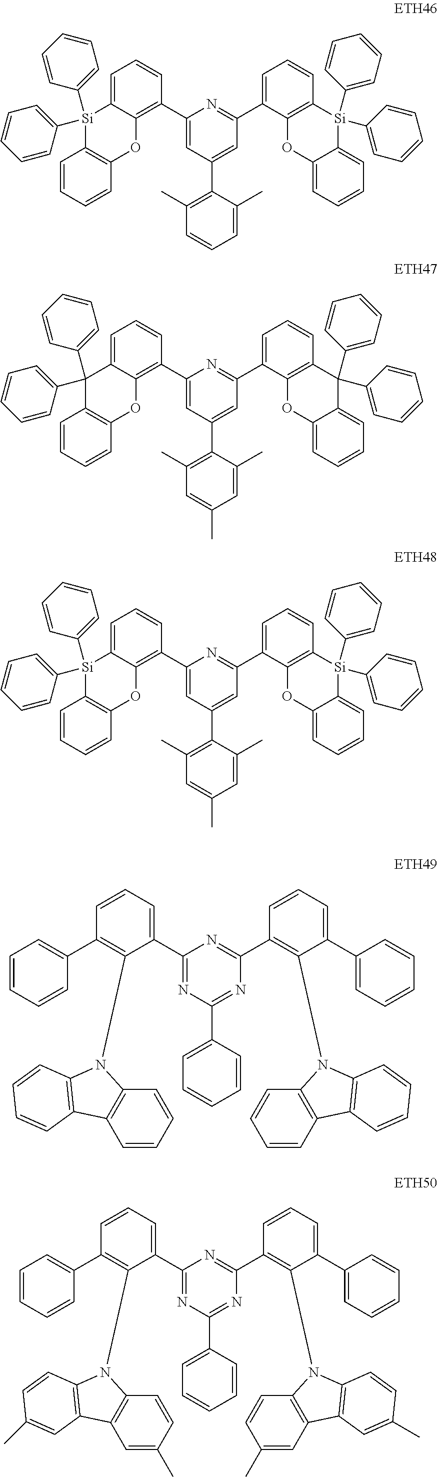

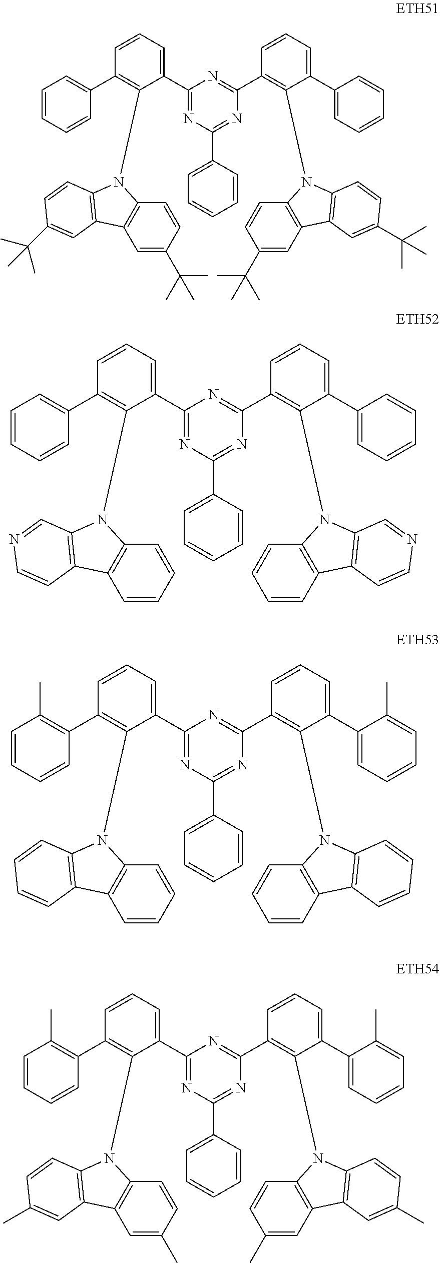

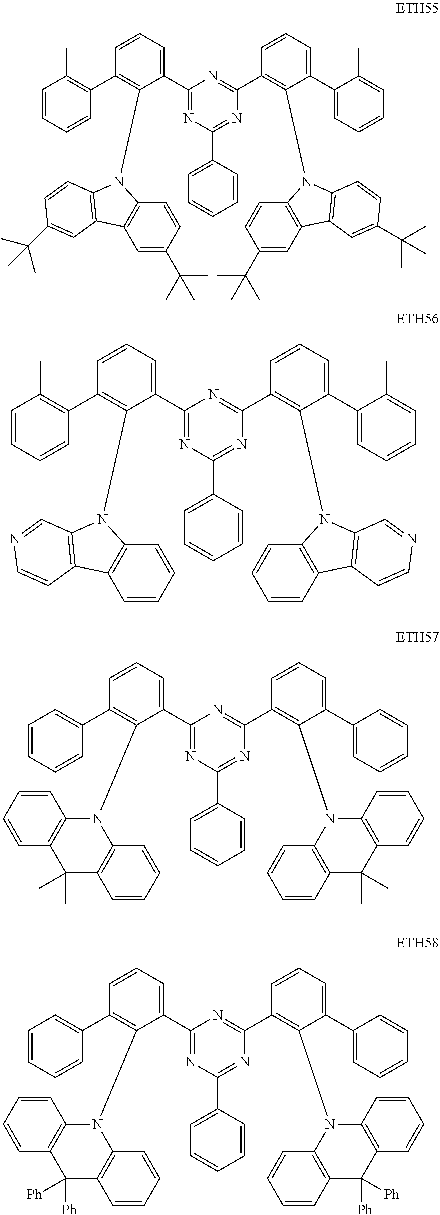

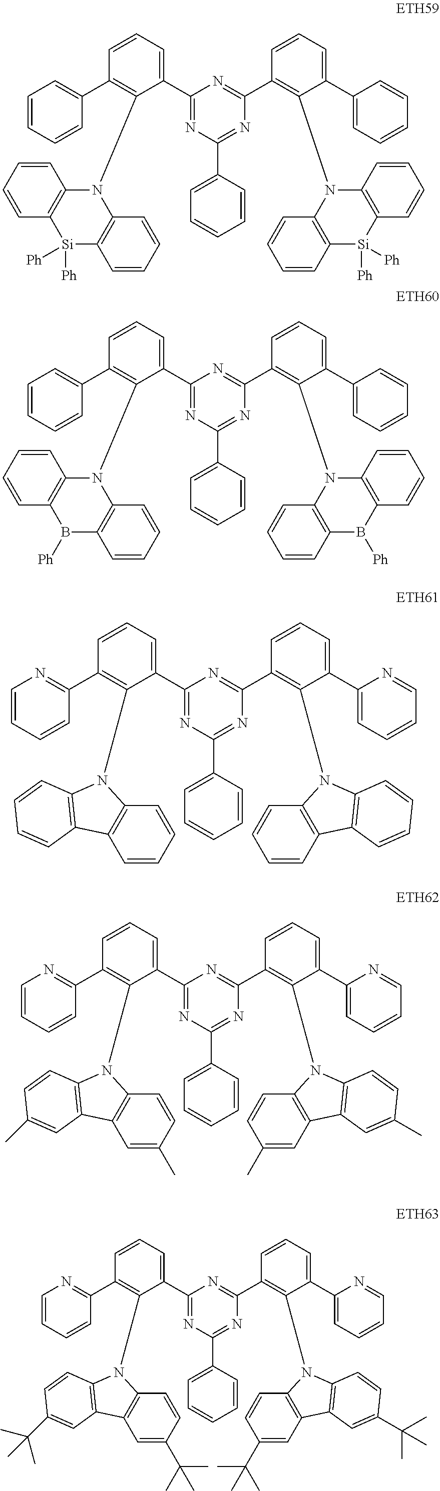

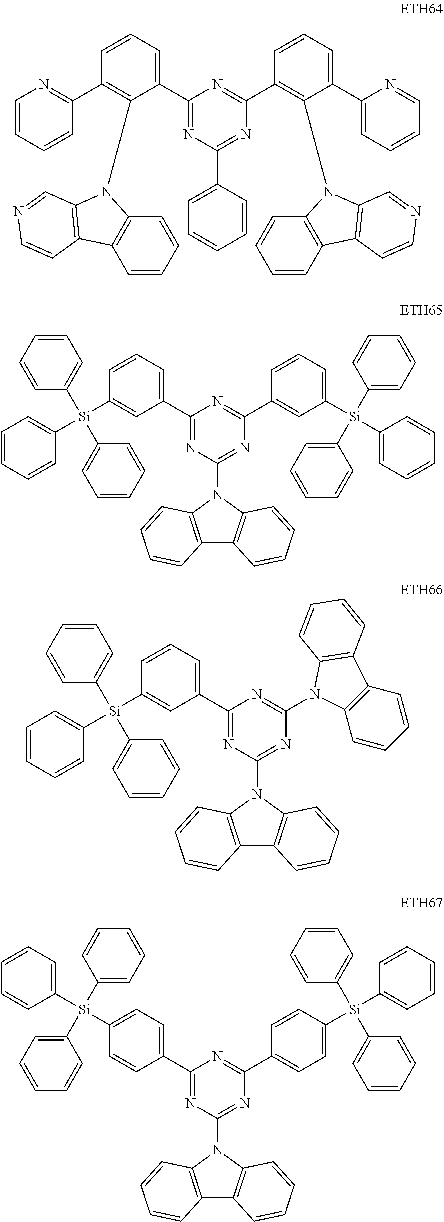 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

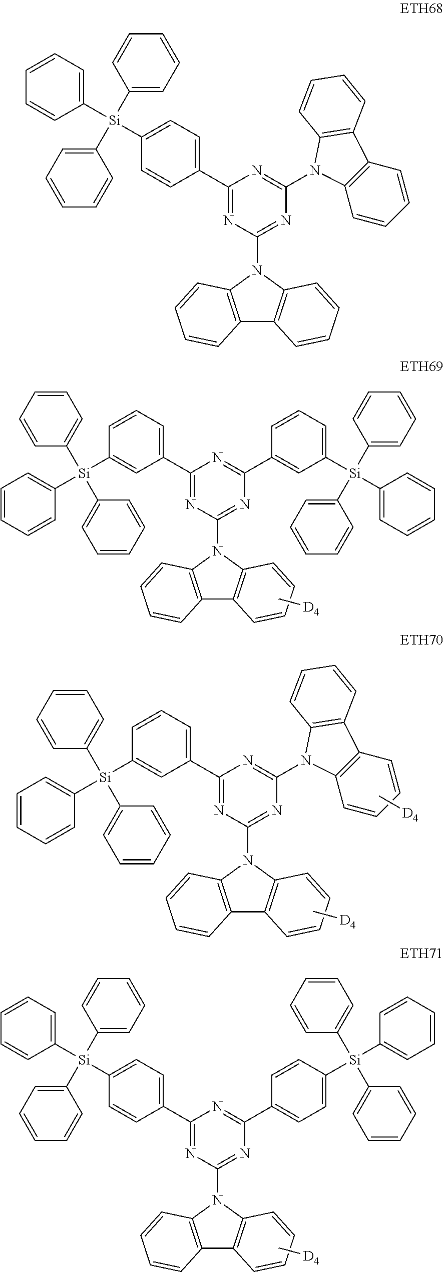

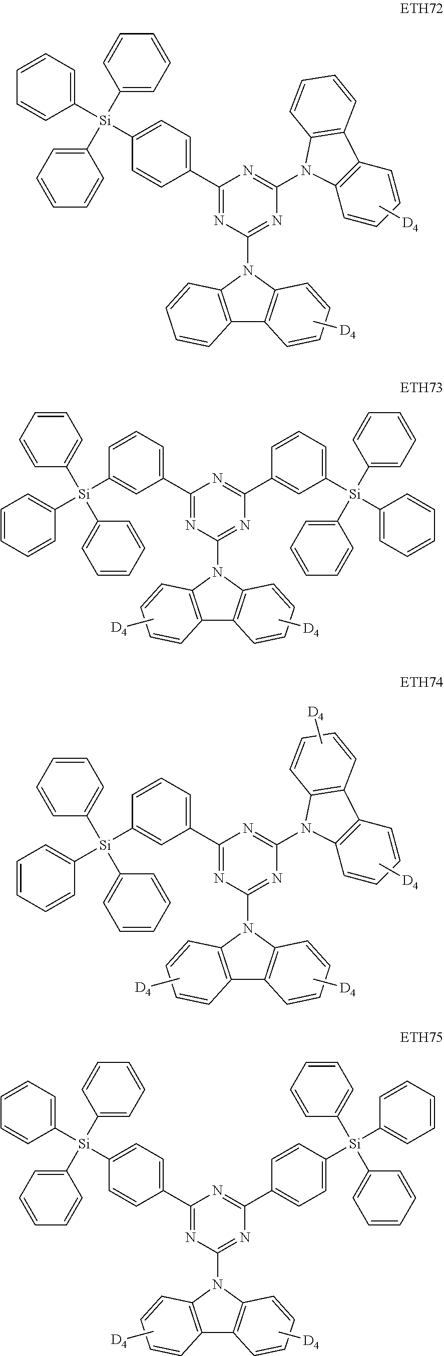

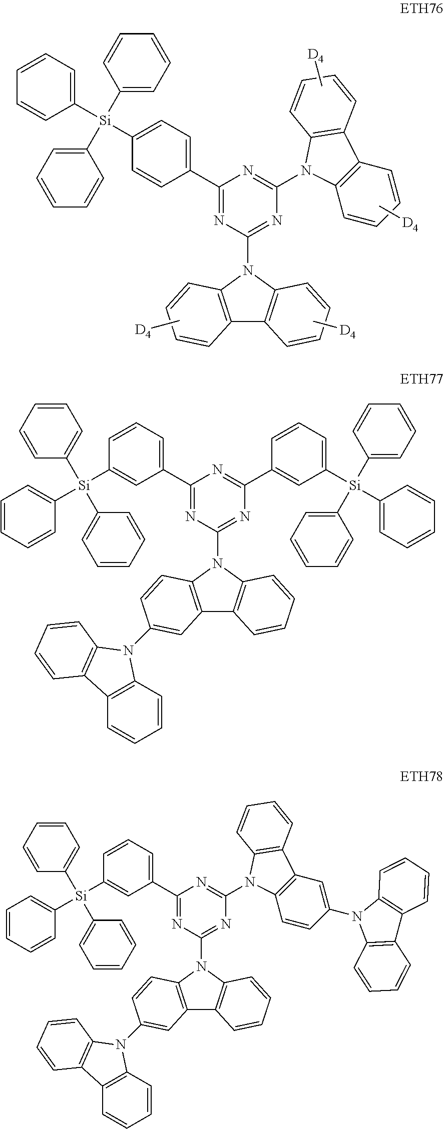

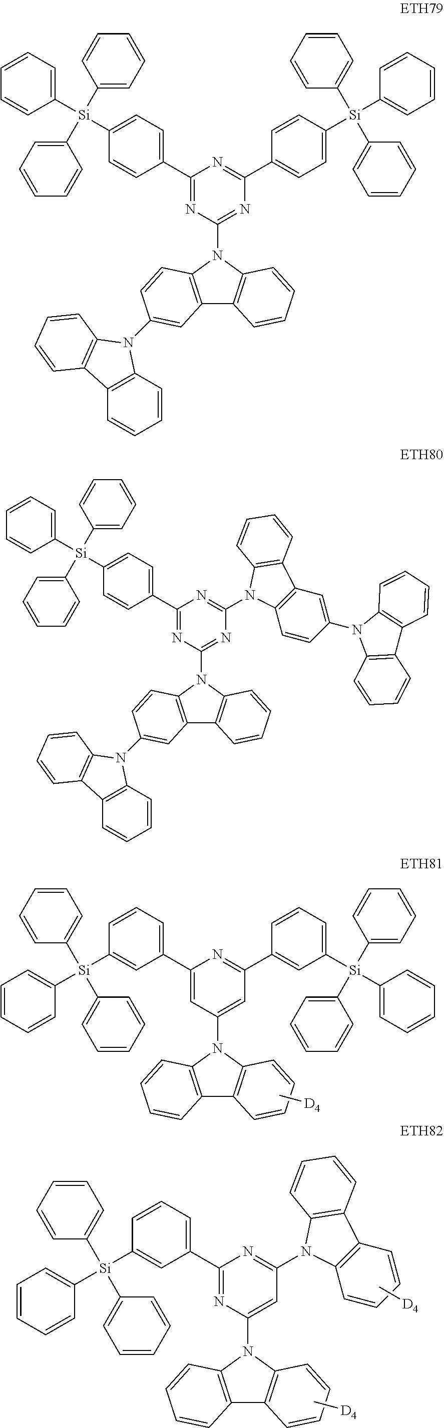

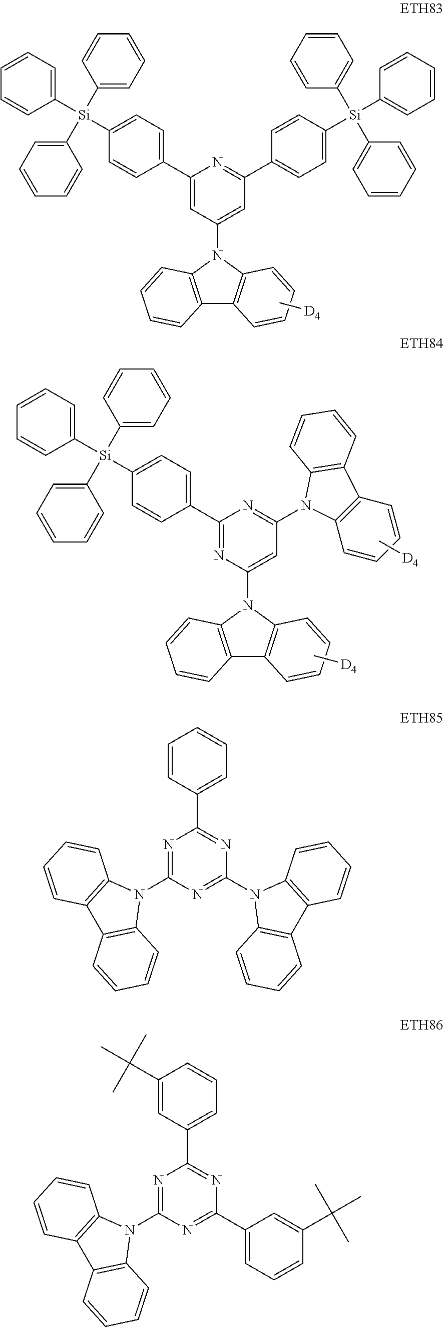

In an embodiment, the emission layer EML may include a compound represented by Formula E-2a or Formula E-2b below. The compound represented by Formula E-2a or Formula E-2b may be used as a phosphorescent host.

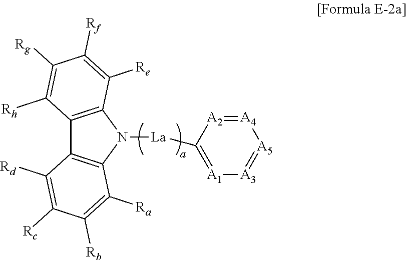

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In case that a is an integer of 2 or greater, multiple Lₐ's may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or one linked to an adjacent group to form a ring. Rₐ to Rᵢ may be linked to an adjacent group to form a hydrocarbon ring or a heterocycle containing N, O, S, etc. as a ring-forming atom.

In Formula E-2a, two or three of A₁ to A₅ may be N, and the others may be Cri.

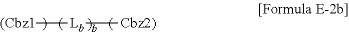

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, and b may be an integer of 0 to 10, and in case that b is an integer of 2 or greater, multiple L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be represented by one of Compound Group E-2 below. However, the compounds listed in Compound Group E-2 below are presented as an example, and the compound represented by Formula E-2a or Formula E-2b is not limited to those listed in Compound Group E-2 below.

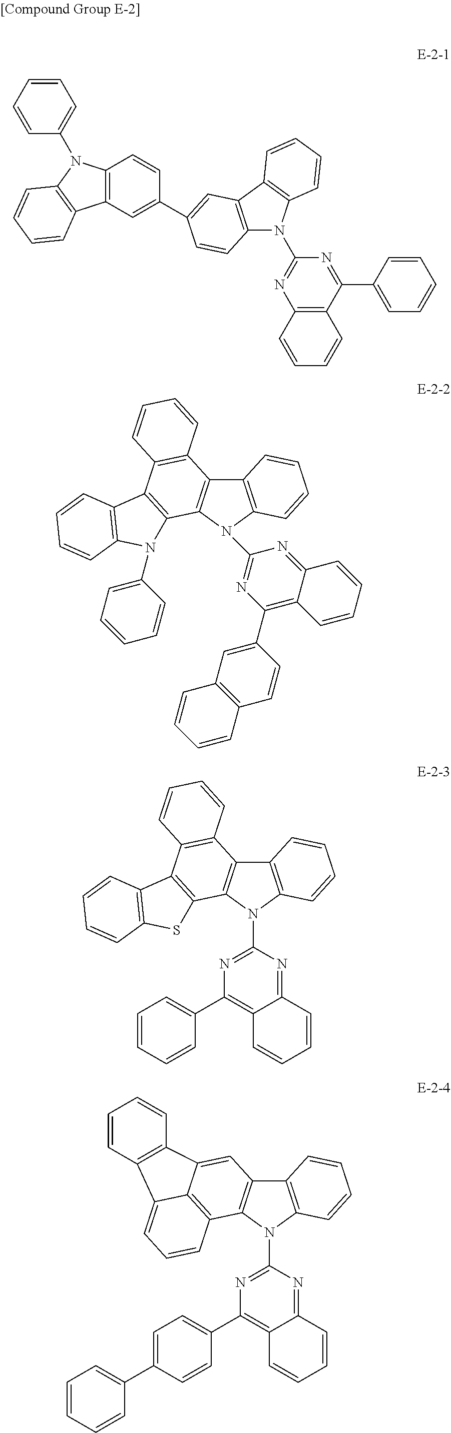

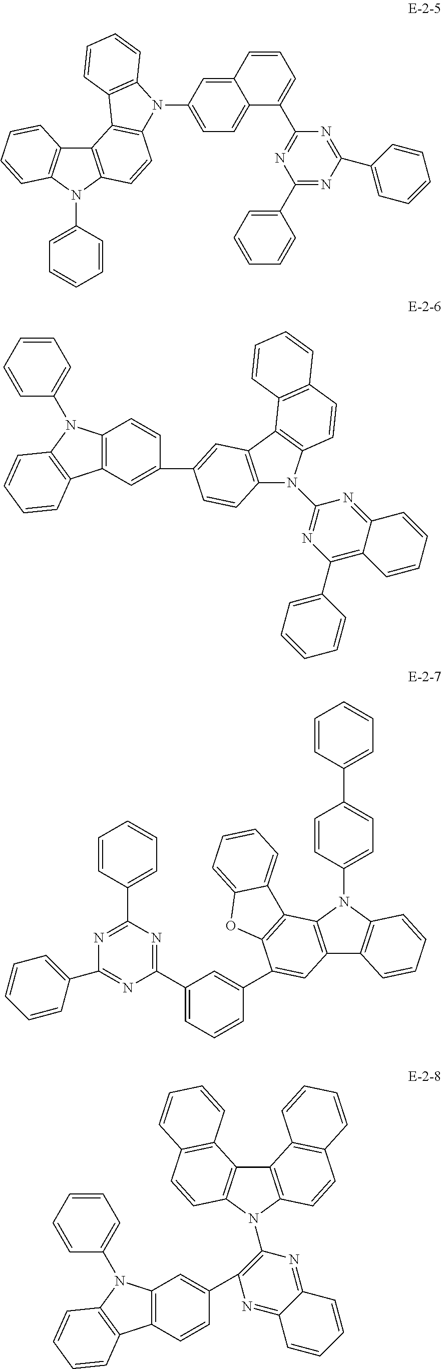 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

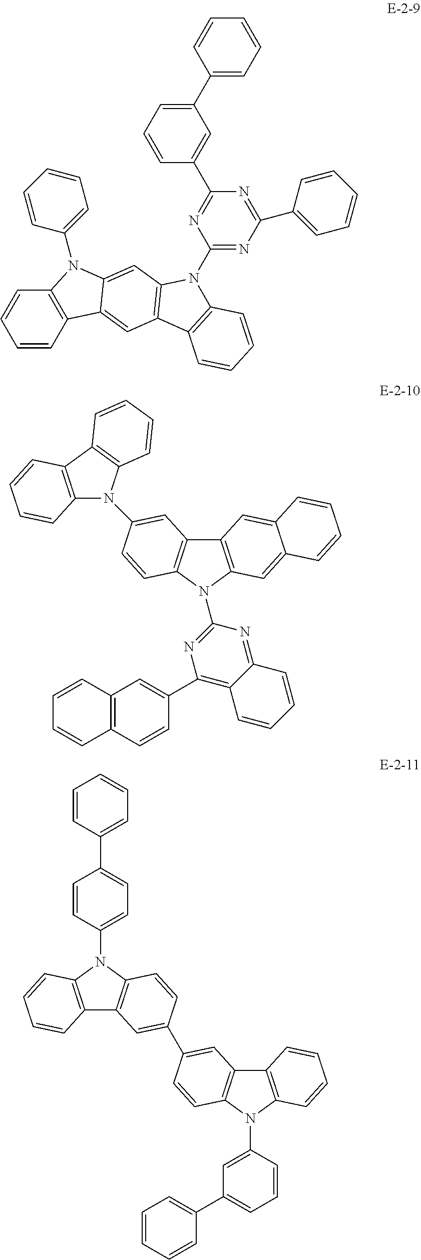

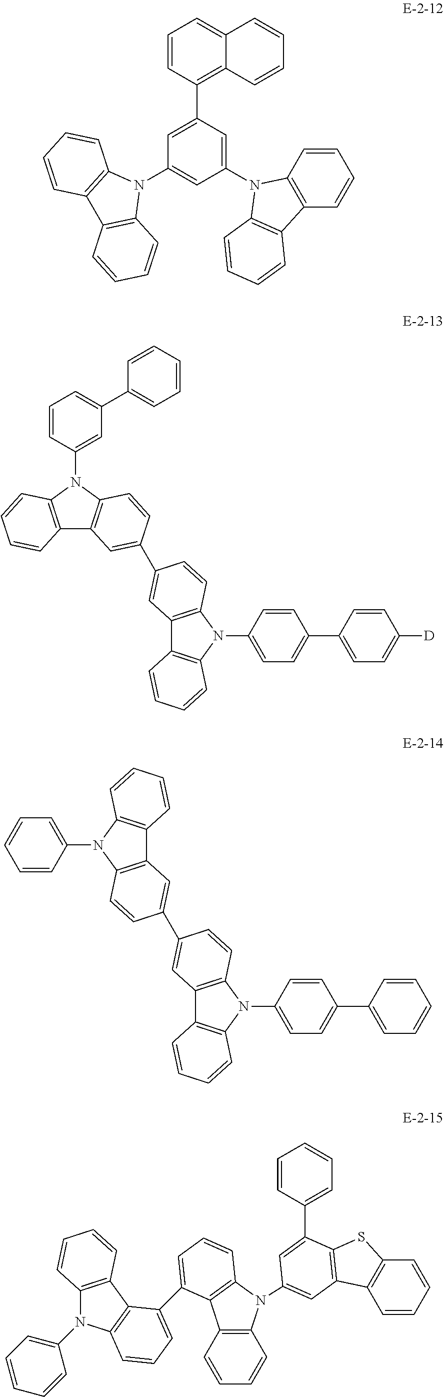 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

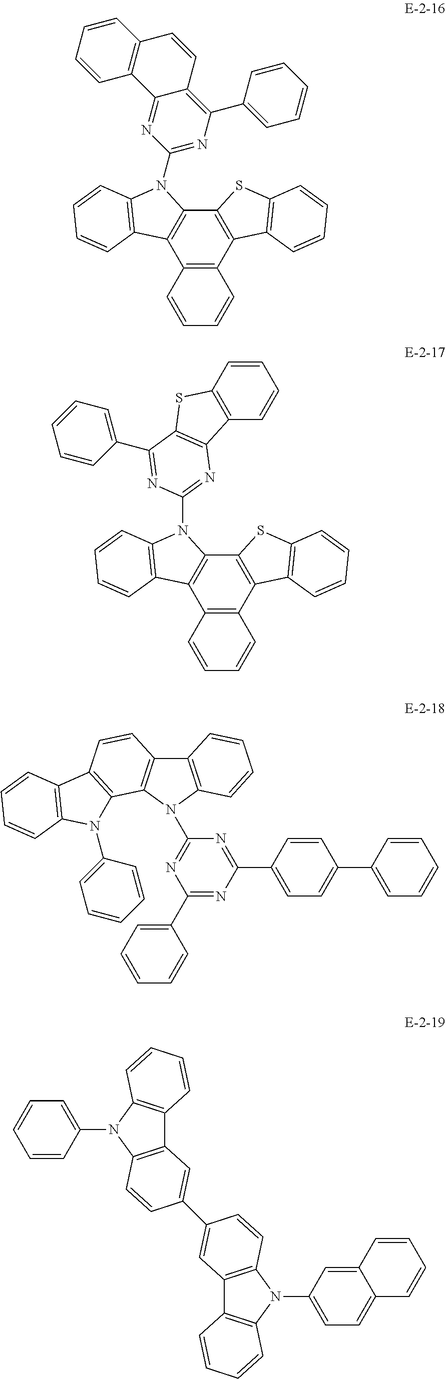

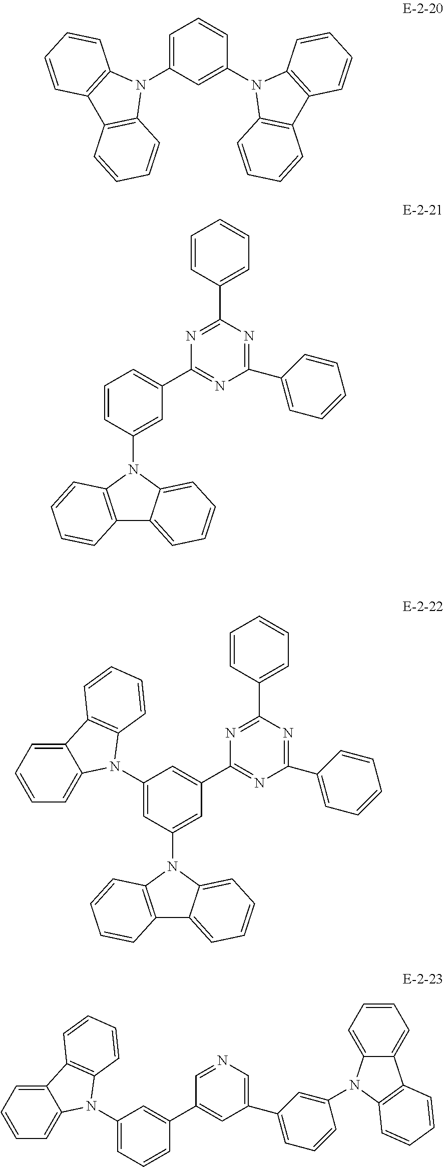 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

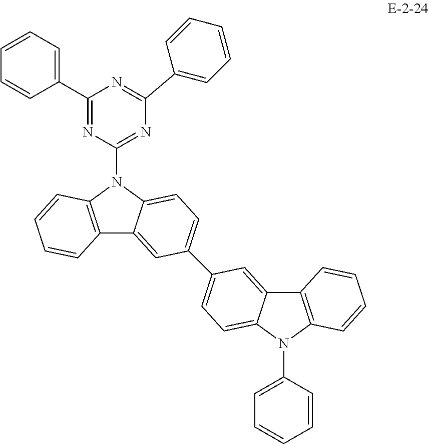 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material as a host. For example, the emission layer EML may include, as a host, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the embodiment of the disclosure is not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetrasiloxane (DPSiO₄), etc. may be used as a host.

The emission layer EML may include a compound represented by Formula M-a or Formula M-b below. The compound represented by Formula M-a or Formula M-b below may be used as a phosphorescent dopant.

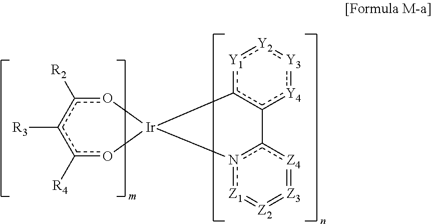

In Formula M-a above, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or one bonded to an adjacent group to form a ring. In Formula M-a, m may be 0 or 1, and n may be 2 or 3. In Formula M-a, in case that m is 0, n may be 3, and in case that m is 1, n may be 2.

The compound represented by Formula M-a may be used as a phosphorescent dopant.

The compound represented by Formula M-a may be represented by one of compounds M-al to M-a25 below. However, the compounds M-al to M-a25 below are presented as an example, and the compound represented by Formula M-a is not limited to those of the compounds M-al to M-a25 below.

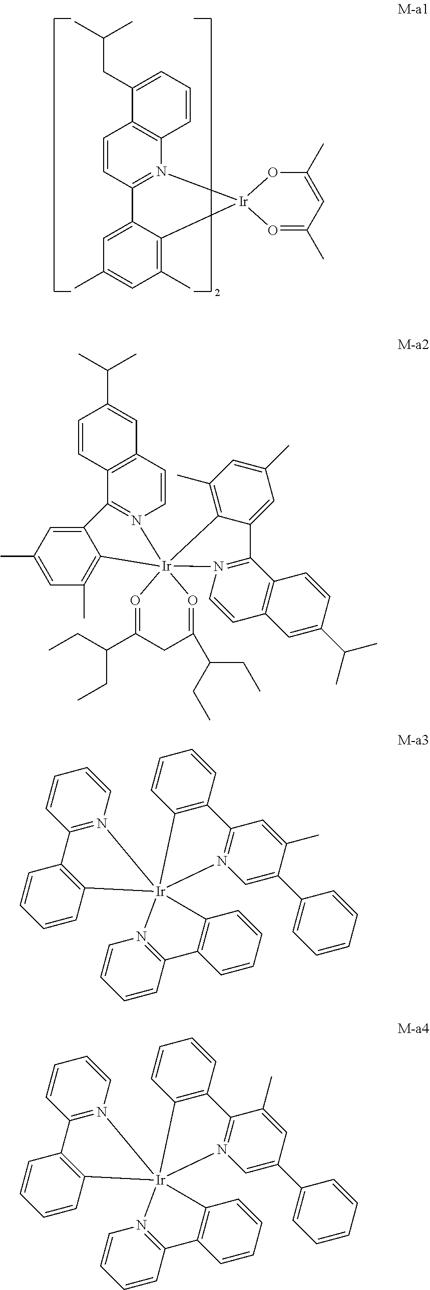

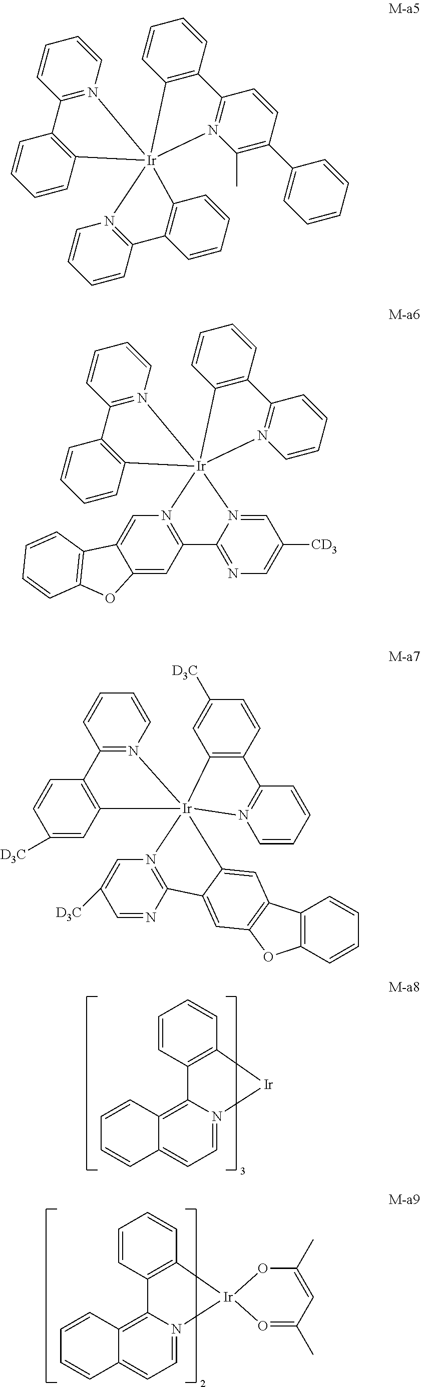

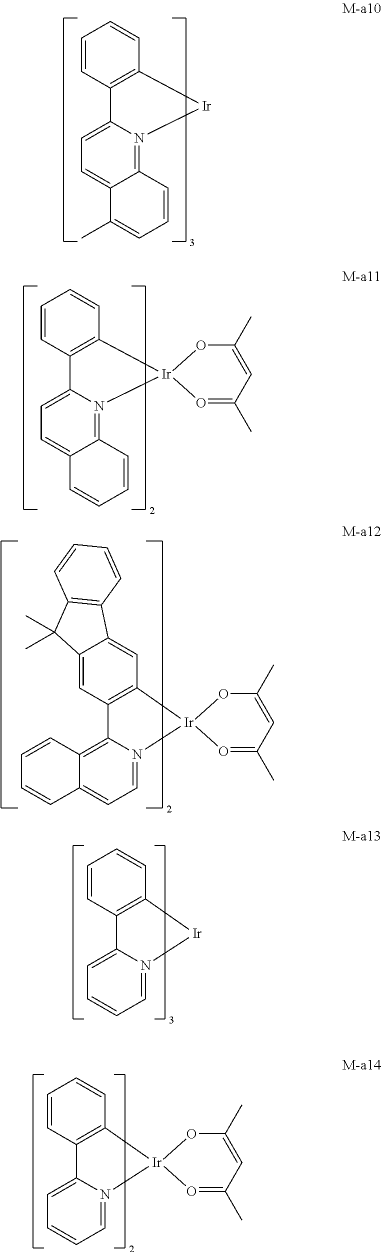

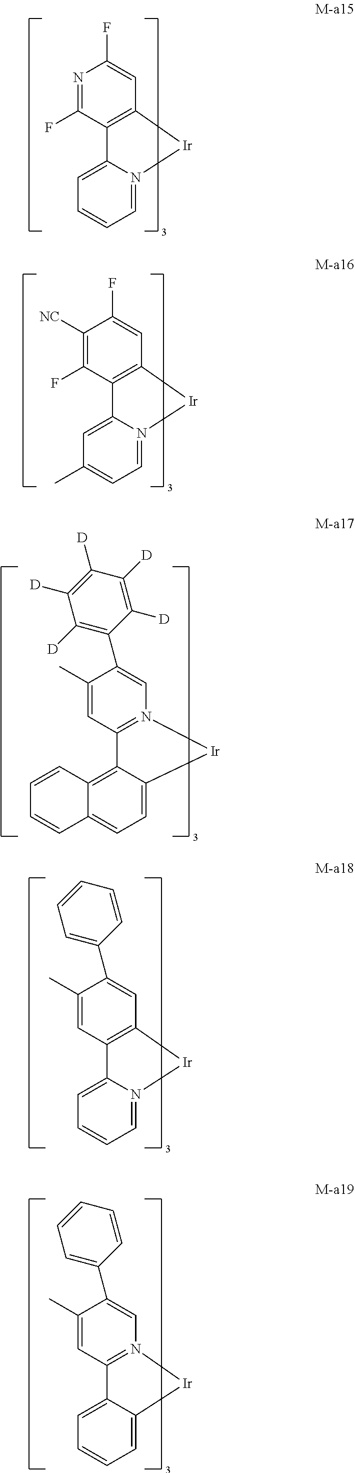

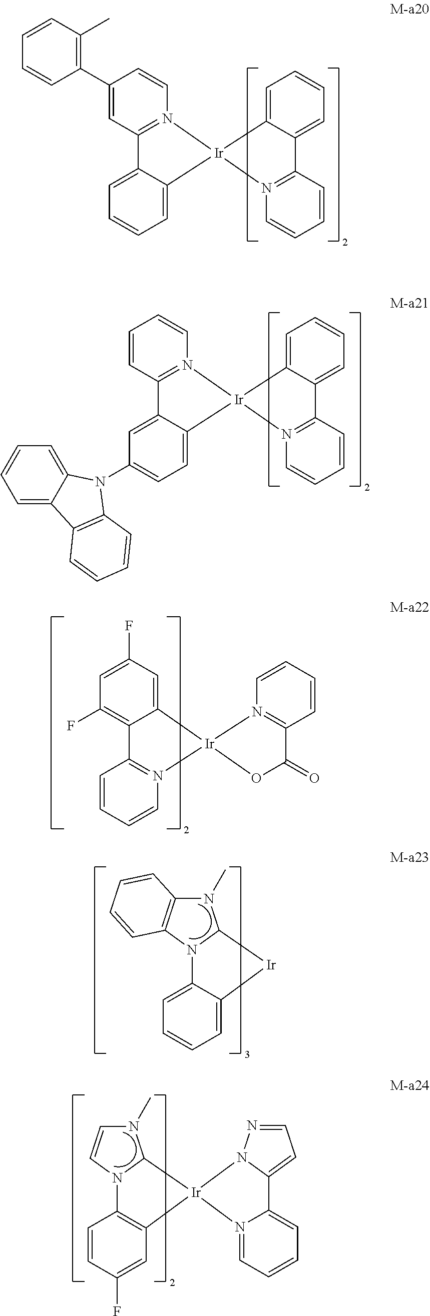

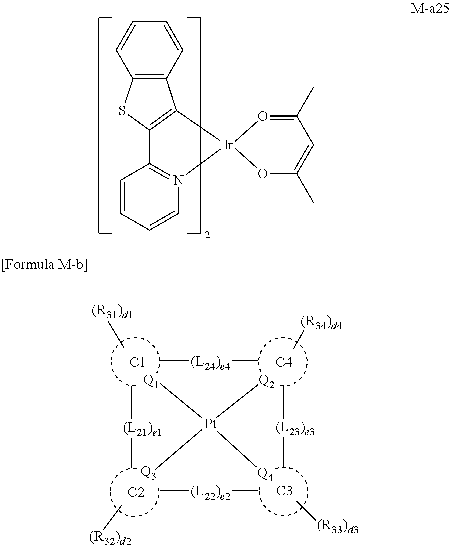

In Formula M-b, Q₁ to Q₄ may each independently be C or N, and C1 to C4 may each independently be a substituted or unsubstituted hydrocarbon ring having 5 to 30 ring-forming carbon atoms or a substituted or unsubstituted heterocycle having 2 to 30 ring-forming carbon

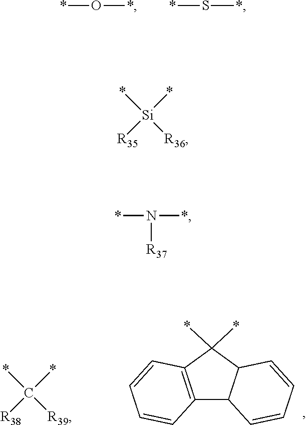

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or one bonded to an adjacent group to form a ring, and d1 to d4 may each independently be an integer of 0 to 4.

The compound represented by Formula M-b may be used as a blue phosphorescent dopant or a green phosphorescent dopant.

The compound represented by Formula M-b may be represented by any one of Compounds M-b-1 to M-b-11 below. However, Compounds M-b-1 to M-b-11 below are presented as examples, and the compound represented by Formula M-b is not limited to Compounds M-b-1 to M-b-11 below.

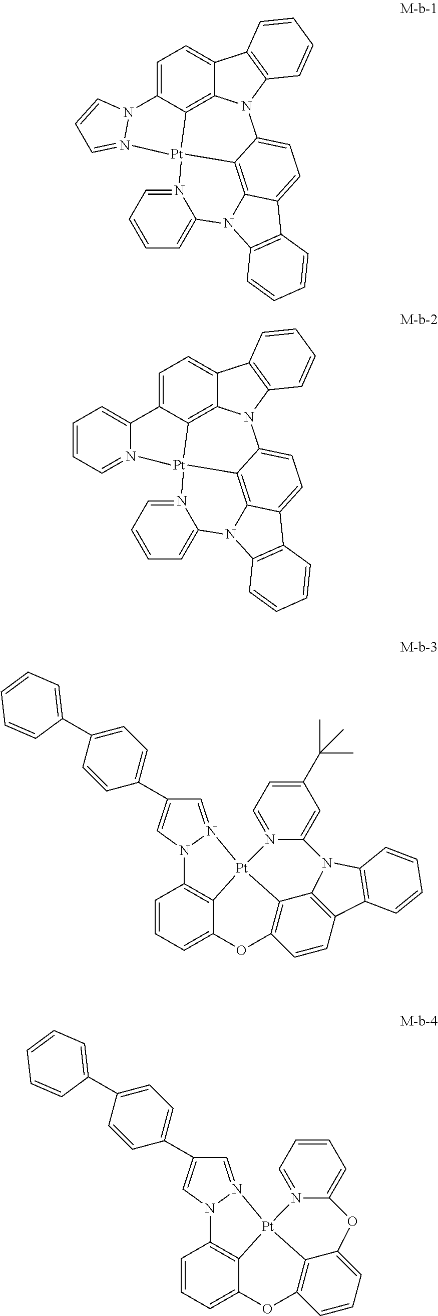

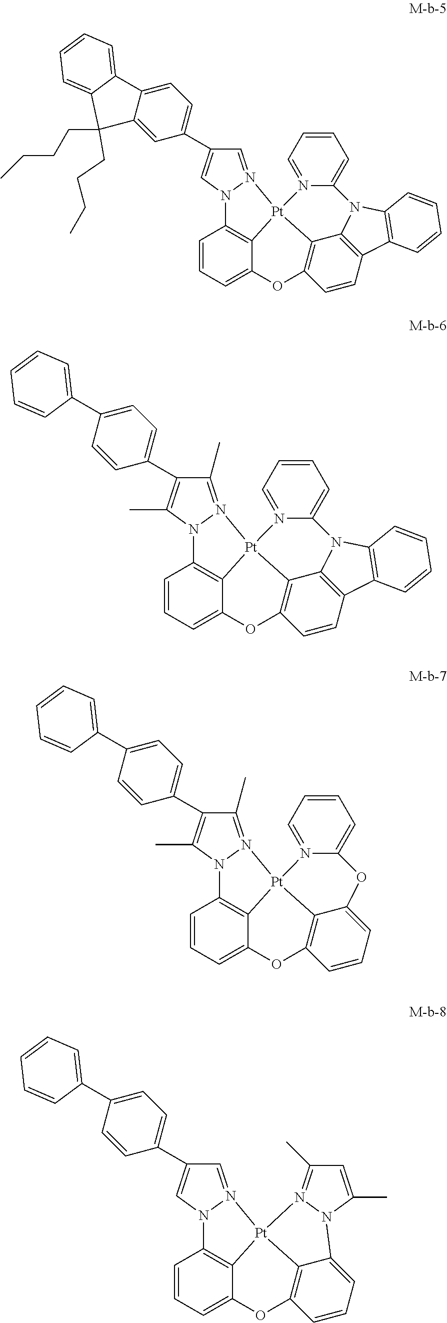

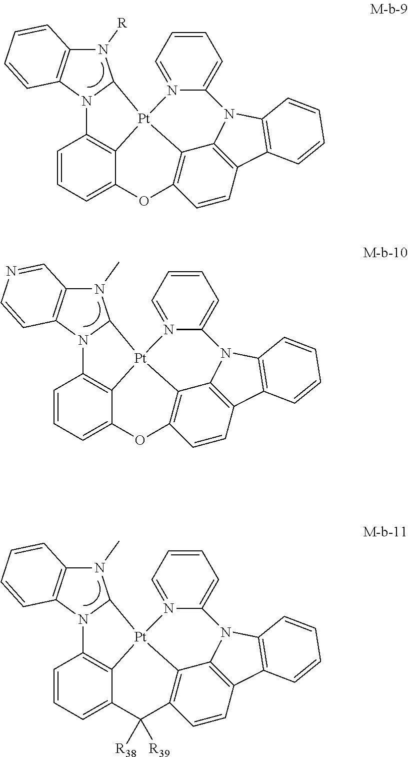

In Compounds M-b-1 to M-b-11 above, R, R₃₈, R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by one of Formulas F-a to F-c below. The compounds represented by Formulas F-a to F-c below may be used as a fluorescent dopant.

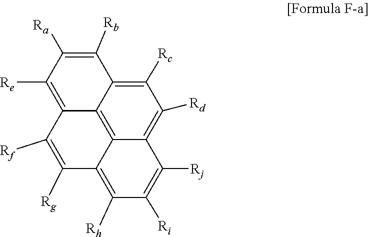

In Formula F-a above, two of Rₐ to Rⱼ may each independently be substituted with ⋅—NAr₁Ar₂. The others of Rₐ to Rⱼ which are not substituted with ⋅—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In ⋅—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of An or Ar₂ may be a heteroaryl group containing O or S as a ring-forming atom.

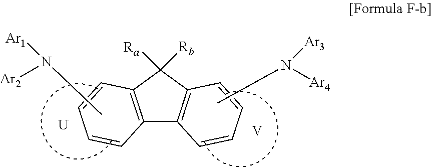

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or one linked to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. For example, In Formula F-b, in case that the number of U or V is 1, one ring may form a fused ring in a portion indicated by U or V, and in case that the number of U or V is 0, no ring indicated by U or V may present. For example, in case that the number of U is 0 and the number of V is 1, or in case that the number of U is 1 and the number of V is 0, a fused ring having a fluorene core of Formula F-b may be a cyclic compound having four rings. In case that both U and V are 0, the fused ring of Formula F-b may be a cyclic compound having three rings. In case that both U and V are 1, the fused ring having a fluorene core of Formula F-b may be a cyclic compound having five rings.

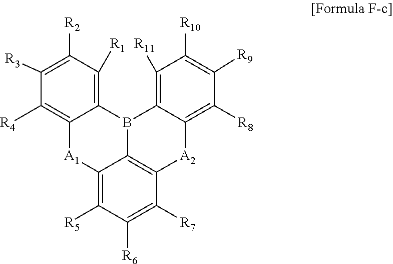

In Formula F-c, A₁ and A₂ may each independently be O, S, Se, or N(Rₘ), and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or one bonded to an adjacent group to form a ring.

In Formula F-c, A₁ and A₂ may each independently be bonded to substituents of neighboring rings to form a fused ring. For example, in case that A₁ and A₂ are each independently NRₘ, Aᵢ may be bonded to R₄ or R₅ to form a ring. A₂ may be bonded to R₇ or R₈ to form a ring.

The emission layer EML may include, as a dopant, styryl derivatives (e.g., 1,4-bis[2-(3-N-ethylcarbazoryl)vinyl]benzene (BCzVB), 4-(di-p-tolylamino)-4″-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

The emission layer EML may include a phosphorescent dopant. For example, as a phosphorescent dopant, a metal complex including iridium (Ir), platinum (Pt), osmium (Os), gold (Au), titanium (Ti), zirconium (Zr), hafnium (Hf), europium (Eu), terbium (Tb), or thulium (Tm) may be used. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), platinum octaethyl porphyrin (PtOEP), etc. may be used as a phosphorescent dopant.

However, the embodiment of the disclosure is not limited thereto.

The emission layer EML may include a quantum dot material. The core of a quantum dot may include a Group II-VI compound, a Group III-VI compound, a Group 1-II-VI compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and In₂Se₃, a ternary compound such as InGaS₃ and InGaSe₃, or any combination thereof.

The Group 1-III-VI compound may include a ternary compound selected from the group consisting of AgInS, AgInS₂, CuInS, CuInS₂, AgGaS₂, CuGaS₂ CuGaO₂, AgGaO₂, AgAlO₂, or any mixture thereof, or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

The binary compound, the ternary compound, or the quaternary compound may be present in particles having a uniform concentration distribution, or may be present in the same particles having a partially different concentration distribution. A core/shell structure in which one quantum dot surrounds another quantum dot may be present. The core/shell structure may have a concentration gradient in which the concentration of an element present in the shell becomes lower towards the core.

In embodiments, a quantum dot may have the core/shell structure including a core having nano-crystals, which are described above, and a shell surrounding the core. The shell of the quantum dot may serve as a protection layer to prevent the chemical deformation of the core so as to keep semiconductor properties, and/or a charging layer to impart electrophoresis properties to the quantum dot. The shell may be a single layer or may include multiple layers.

The shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but the embodiment of the disclosure is not limited thereto.

The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the disclosure is not limited thereto.

The quantum dot may have a full width at half maximum (FWHM) of an emission wavelength spectrum less than or equal to about 45 nm. For example, the quantum dot may have a FWHM of an emission wavelength spectrum less than or equal to about 40 nm. For example, the quantum dot may have a FWHM of an emission wavelength spectrum less than or equal to about 30 nm. Color purity or color reproducibility may be enhanced in the above ranges. Light emitted through such a quantum dot may be emitted in all directions, and thus a wide viewing angle may be achieved.

The form of a quantum dot is not particularly limited as long as it is a form commonly used in the art, for example, a quantum dot in the form of spherical, pyramidal, multi-arm, cubic nanoparticles, nanotubes, nanowires, nanofibers, nanoplatelets, etc. may be used.

The quantum dot may control the color of emitted light according to particle size thereof, and thus the quantum dot may have various colors of emitted light such as blue, red, green, etc.

In the light emitting elements ED and ED-a according to an embodiment shown in FIGS. 3A and 4, an electron transport region ETR may be provided on the emission layer EML. The electron transport region ETR may include at least one of a hole blocking layer, an electron transport layer, and an electron injection layer, but the embodiment of the disclosure is not limited thereto.

The electron transport region ETR may be a layer formed of a single material, a layer formed of different materials, or a structure having multiple layers formed of different materials.

For example, the electron transport region ETR may have a single layer structure of an electron injection layer or an electron transport layer, and may have a single layer structure formed of an electron injection material and an electron transport material. The electron transport region ETR may have a single layer structure formed of different materials, or may have a structure in which an electron transport layer/electron injection layer, or a hole blocking layer/electron transport layer/electron injection layer are stacked in order from the emission layer EML, but is not limited thereto. The electron transport region ETR may have a thickness in a range of, for example, about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-2 below.

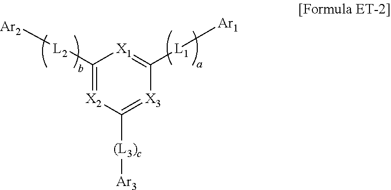

In Formula ET-2, at least one of X₁ to X₃ may each be N and the remainder of X₁ to X₃ may each independently be C(Rₐ). Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. An to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In case that a to c are an integer of 2 or greater, L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, the embodiment of the disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (Balq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one of Compounds ET1 to ET36 below.

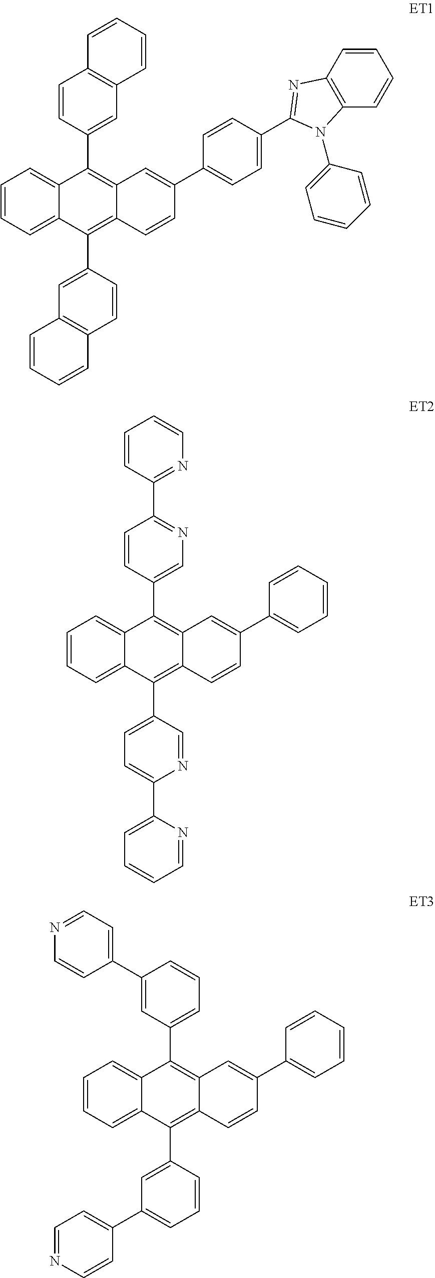 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

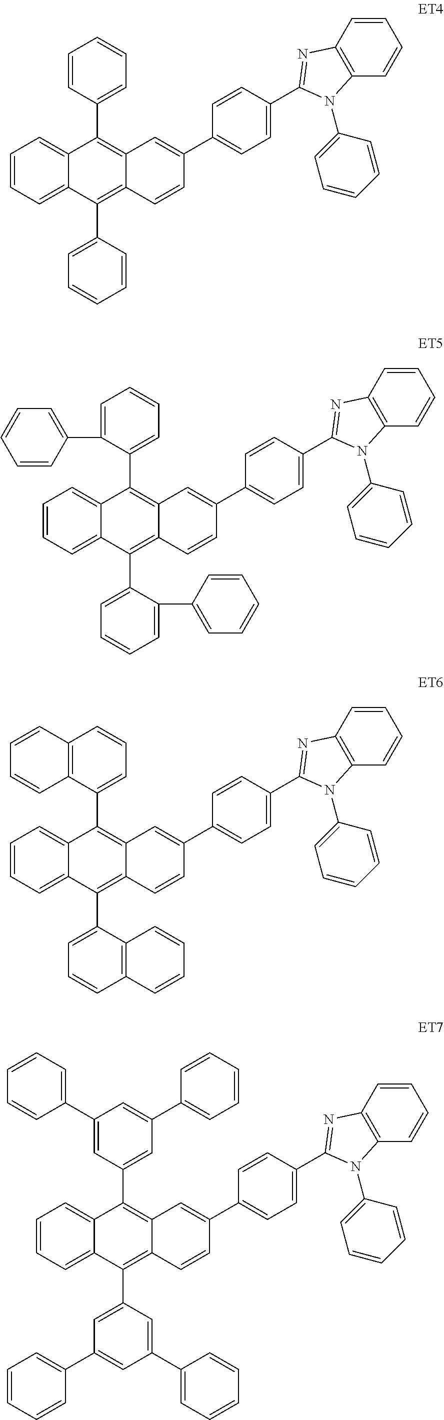 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

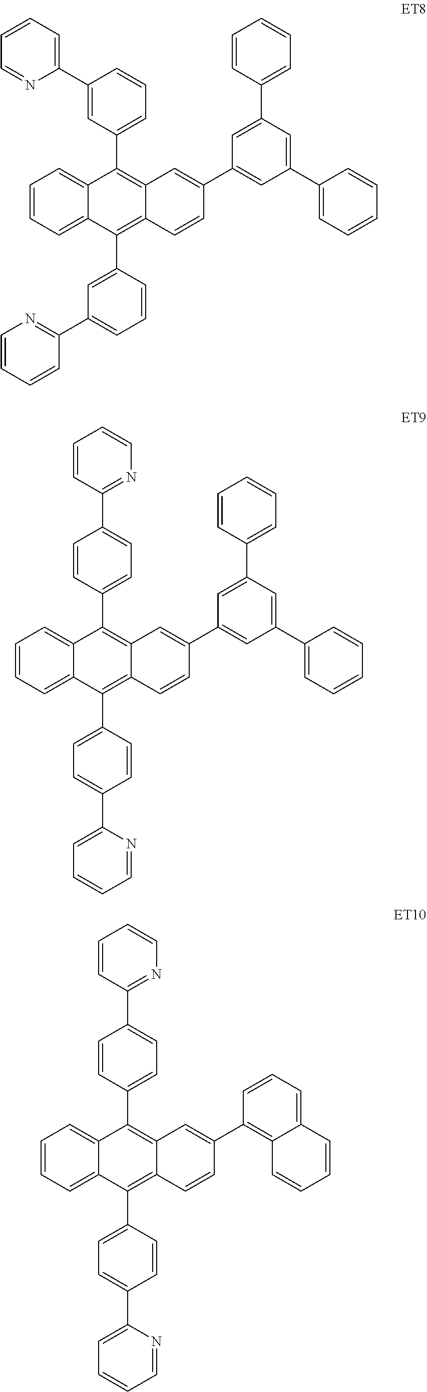

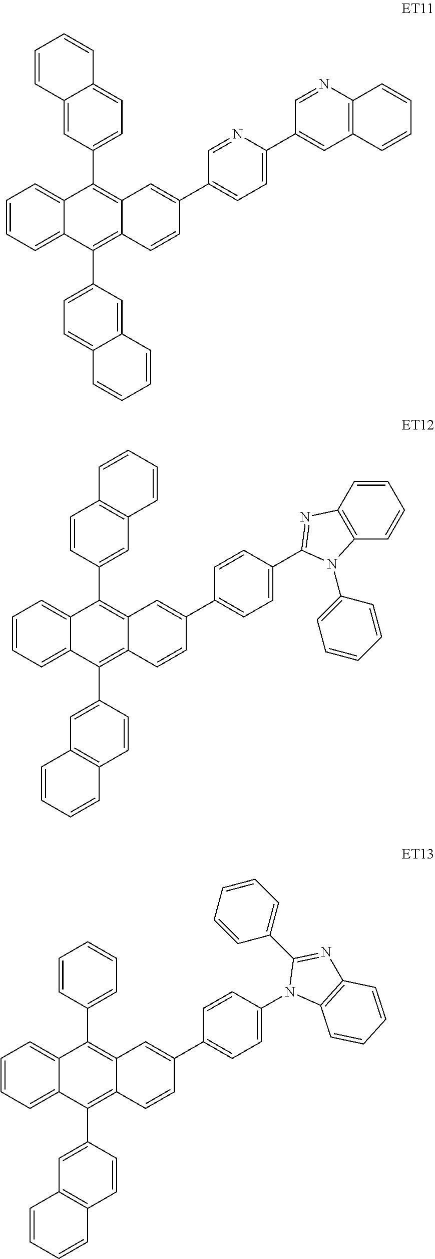 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

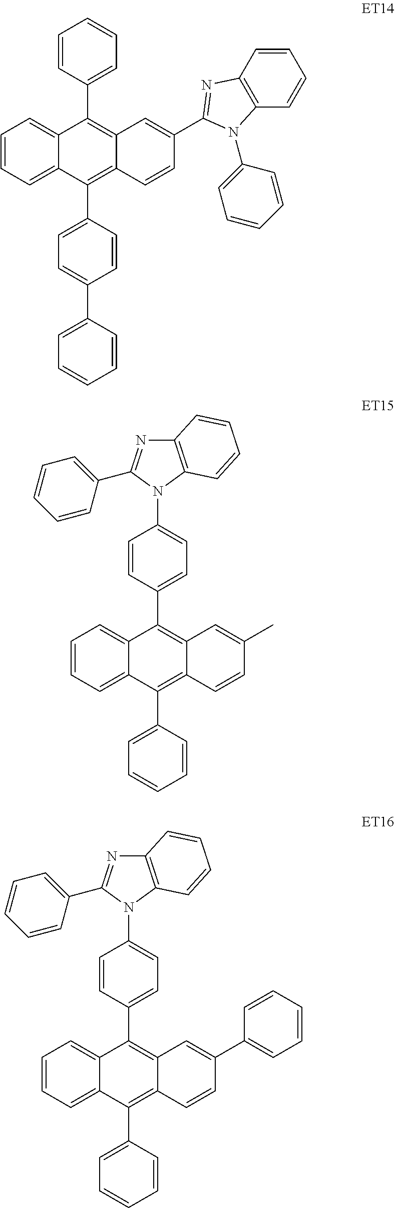

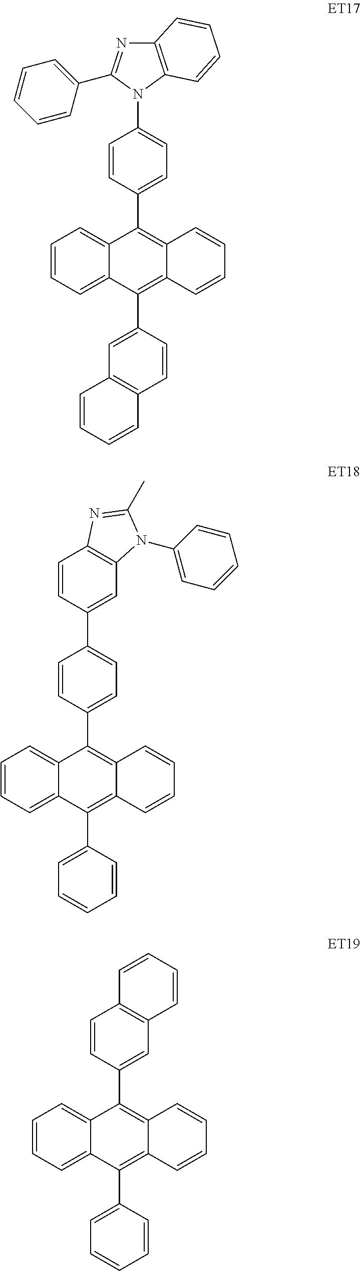

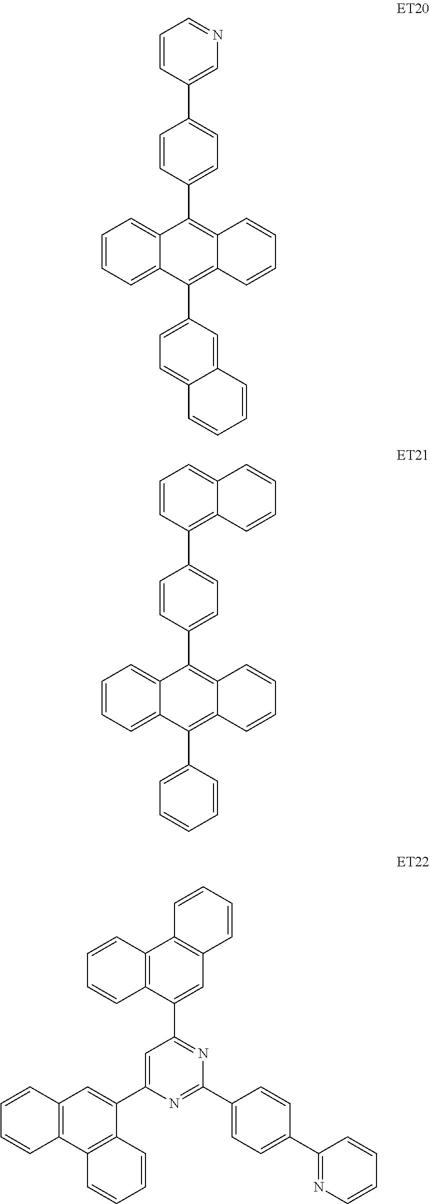

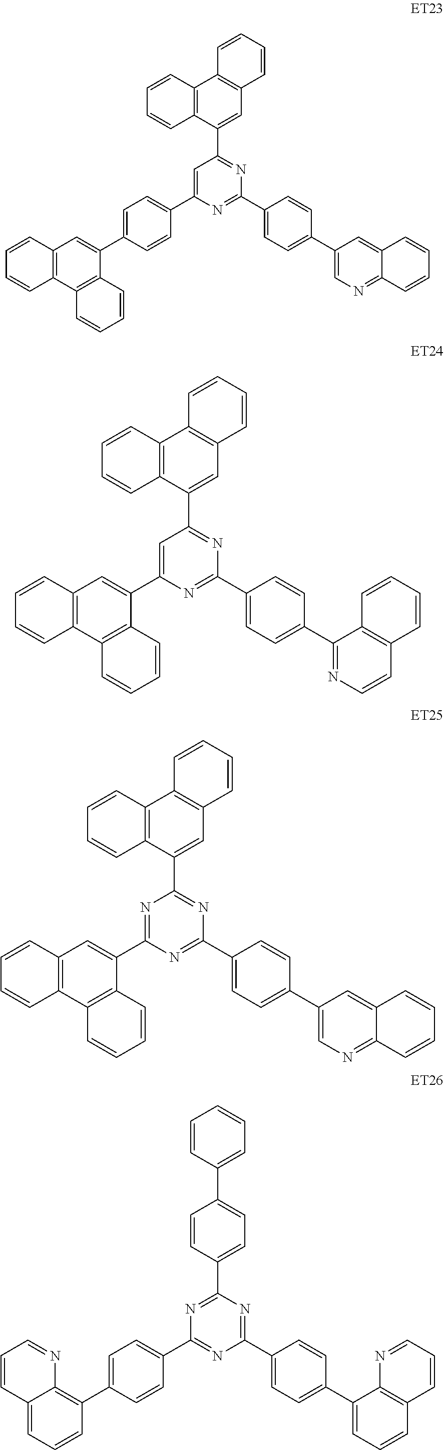 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

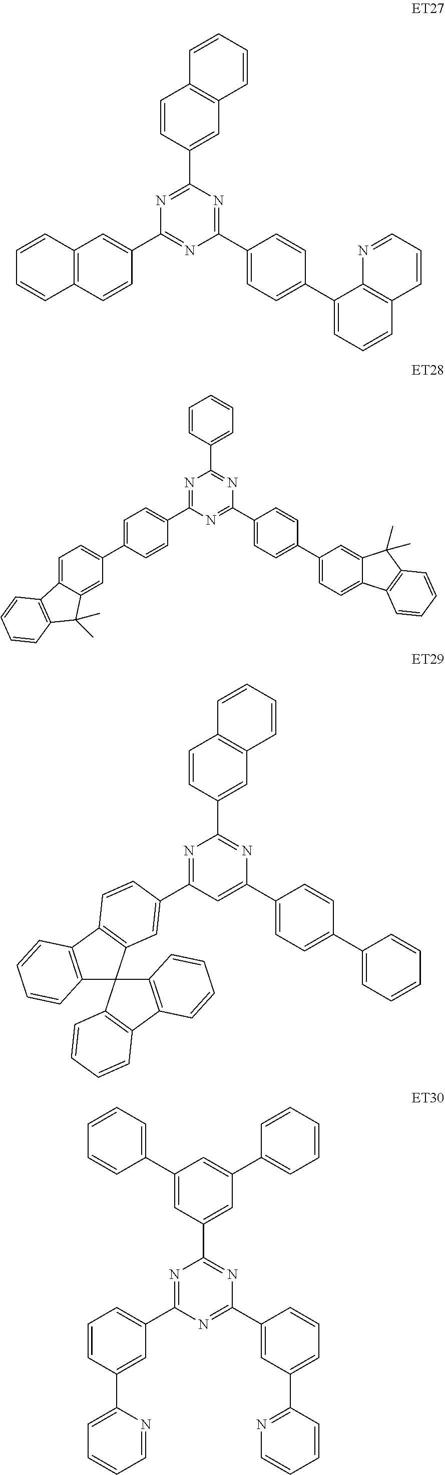

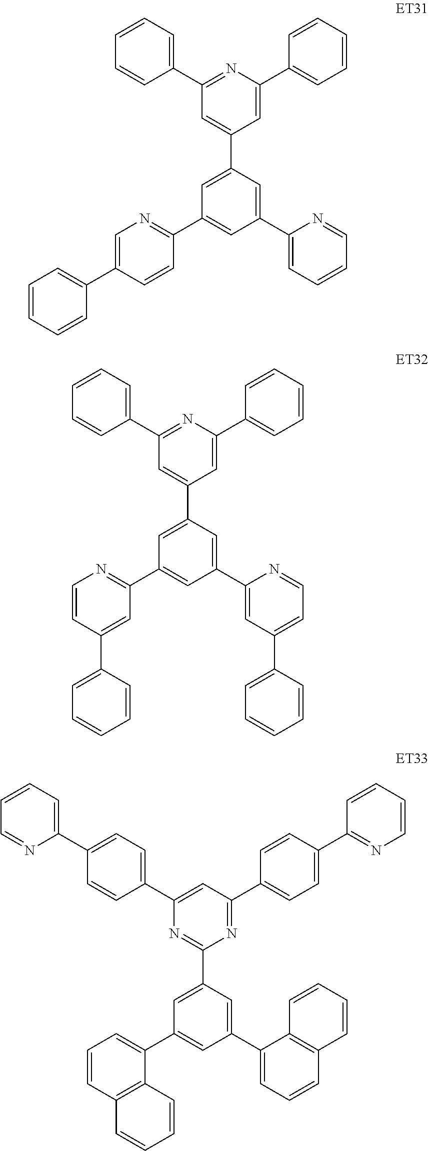 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

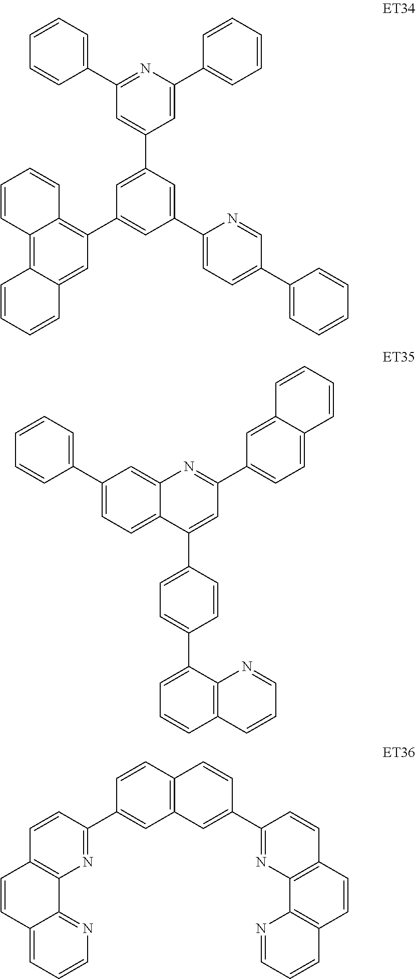

The electron transport region ETR may include halogenated metals such as LiF, NaCl, CsF, RbCl, RbI, CuI, and KI, lanthanide metals such as Yb, or co-deposition materials of a halogenated metal and a lanthanide metal. For example, the electron transport region ETR may include K:Yb, RbI:Yb, LiF:Yb, etc. as a co-deposition material. For the electron transport region ETR, a metal oxide such as Li₂O and BaO, 8-hydroxyl-lithium quinolate (Liq), etc. may be used, but the embodiment of the disclosure is limited thereto. The electron transport region ETR may be formed of a mixture material of an electron transport material and an insulating organo-metal salt. The organo-metal salt may be a material having an energy band gap of greater than or equal to about 4 eV. For example, the organo-metal salt may include, for example, metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but the embodiment of the disclosure is not limited thereto.

At least one of the electron injection layer, the electron transport layer, and the hole blocking layer of the electron transport region ETR may include the compounds that may be included in the electron transport region described above.

In case that the electron transport region ETR includes the electron transport layer, the electron transport layer may have a thickness in a range of about 100 Å to about 1,000 Å. For example, the electron transport layer may have a thickness in a range of about 150 Å to about 500 Å. In case that the thickness of the electron transport layer satisfies the above-described range, satisfactory electron transport properties may be obtained without a substantial increase in driving voltage. In case that the electron transport region ETR includes the electron injection layer, the electron injection layer may have a thickness in a range of about 1 Å to about 100 Å. For example, the electron injection layer may have a thickness in a range of about 3 Å to about 90 Å. In case that the thickness of the electron injection layer satisfies the above-described range, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode but the embodiment of the disclosure is not limited thereto. For example, in case that the first electrode EL1 is an anode, the second electrode EL2 may be a cathode, and in case that the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, and Zn, an oxide thereof, a compound thereof, or a mixture thereof.

The second electrode EL2 may be a transmissive electrode, a transflective electrode, or a reflective electrode. In case that the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

In case that the second electrode EL2 is a transflective electrode or a reflective electrode, the second electrode EL2 may include Ag, Mg, Cu, Al, Pt, Pd, Au, Ni, Nd, Ir, Cr, L₁, Ca, LiF/Ca, LiF/Al, Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or oxides of the above-described metal materials.

Although not shown, the second electrode EL2 may be electrically connected with an auxiliary electrode. In case that the second electrode EL2 is electrically connected with the auxiliary electrode, the resistance of the second electrode EL2 may decrease.

A capping layer (not shown) may be further disposed on the second electrode EL2 of the light emitting elements ED and ED-a according to an embodiment. The capping layer may be a multilayer or a single layer.

In an embodiment, the capping layer may be an organic layer or an inorganic layer. For example, in case that the capping layer includes an inorganic material, the inorganic material may include an alkali metal compound such as LiF, or an alkaline earth metal compound such as MgF₂, SiON, SiNx, SiOy, etc.

For example, in case that the capping layer includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), etc., or may include epoxy resins or acrylates such as methacrylates. However, the embodiment of the disclosure is not limited thereto, and the capping layer may include compounds P1 to P5 below.

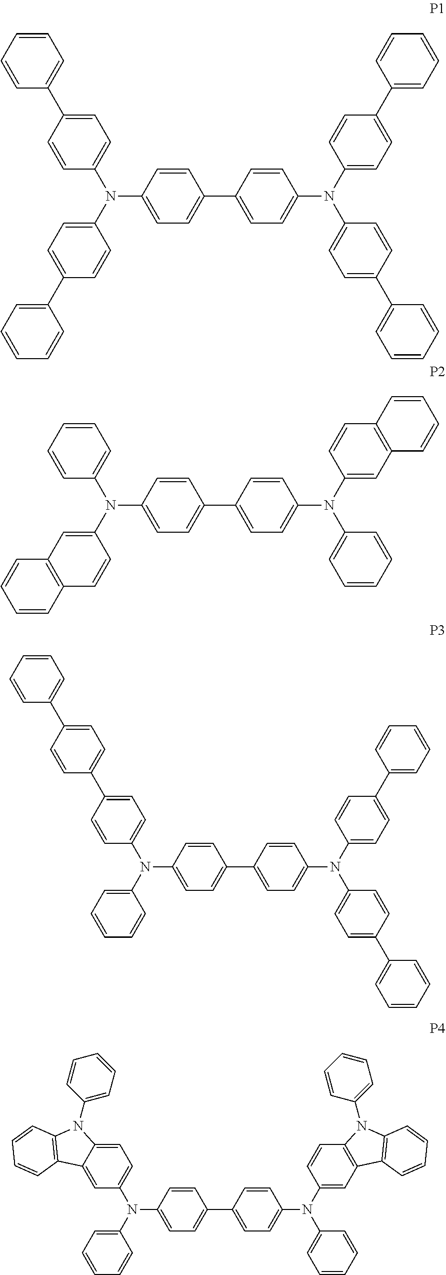 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

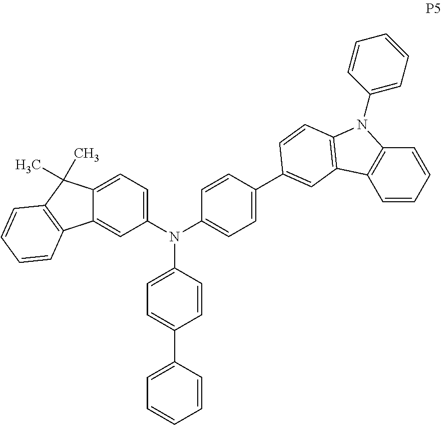 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer may have a refractive index of greater than or equal to about 1.6. For example, the capping layer may have a refractive index of greater than or equal to about 1.6 in a wavelength range of about 550 nm to about 660 nm.

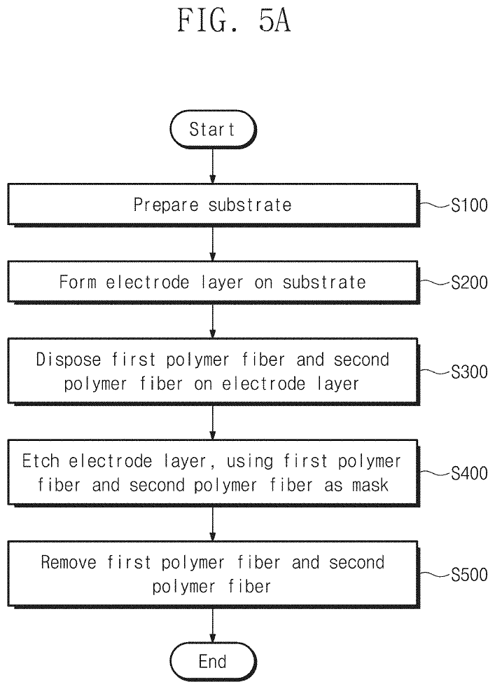

FIG. 5A is a flowchart showing a method for manufacturing a transparent electrode according to an embodiment. FIG. 5B is a flowchart showing a process of disposing a first polymer fiber and a second polymer fiber on an electrode layer in a method for manufacturing a transparent electrode according to an embodiment. Referring to FIG. 5A, a method for manufacturing a transparent electrode may include preparing a substrate (S100), forming an electrode layer on the substrate (S200), disposing a first polymer fiber and a second polymer fiber on the electrode layer (S300), etching the electrode layer, using the first polymer fiber and the second polymer fiber as masks (S400), and removing the first polymer fiber and the second polymer fiber (S500).

Referring to FIG. 5B, the disposing of the first polymer fiber and the second polymer fiber (S300) according to an embodiment may include disposing the first polymer fiber (S301) and disposing the second polymer fiber (S302).

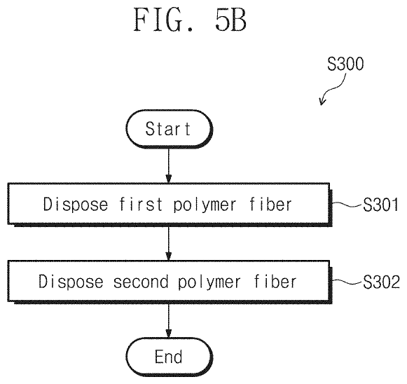

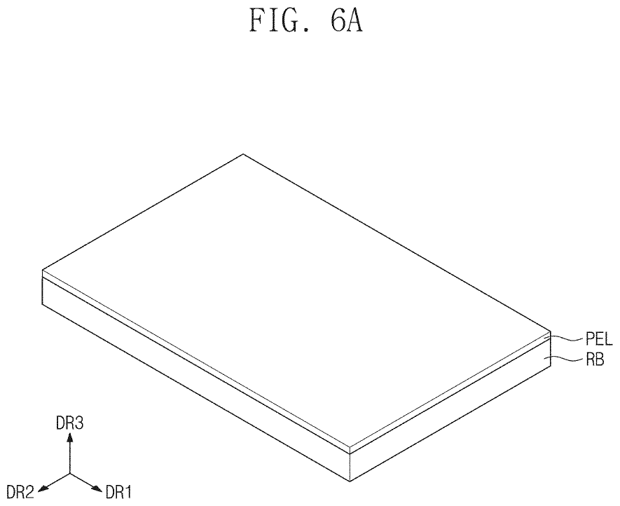

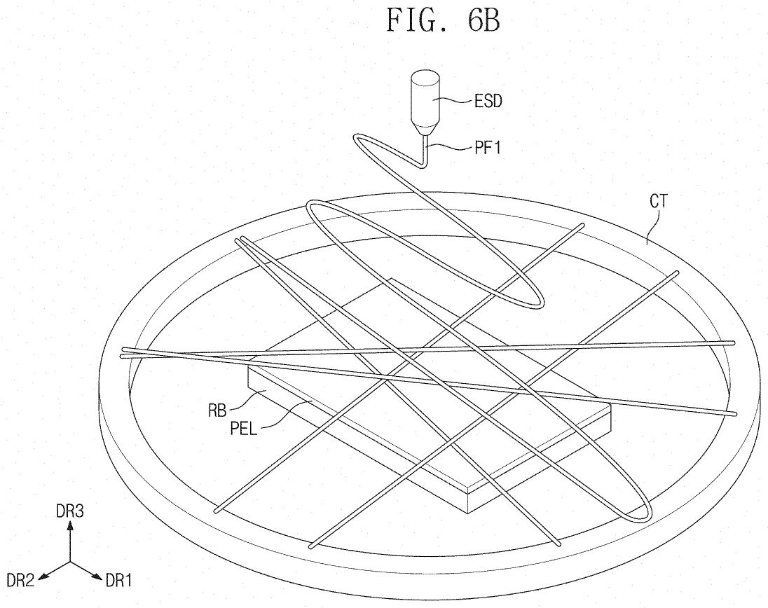

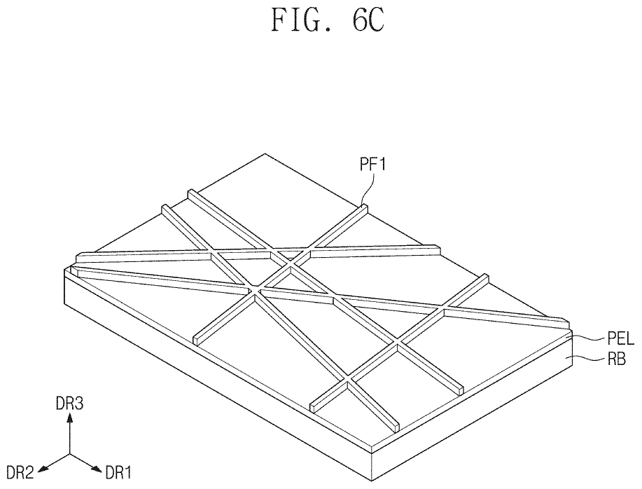

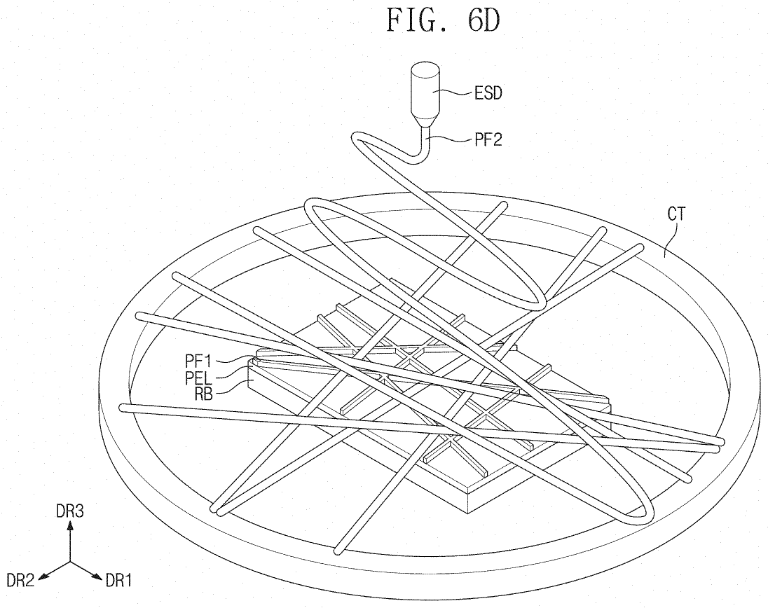

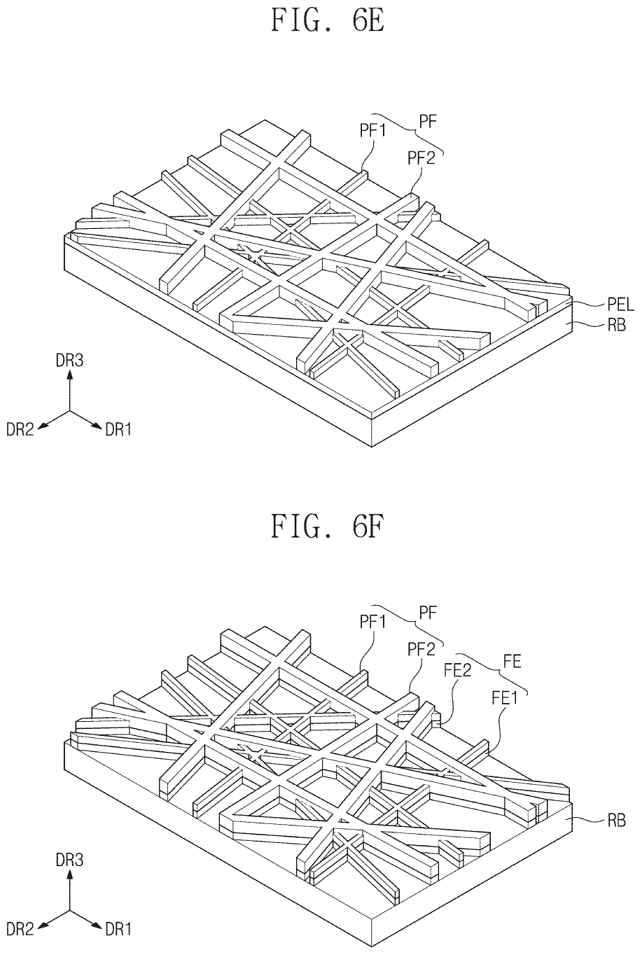

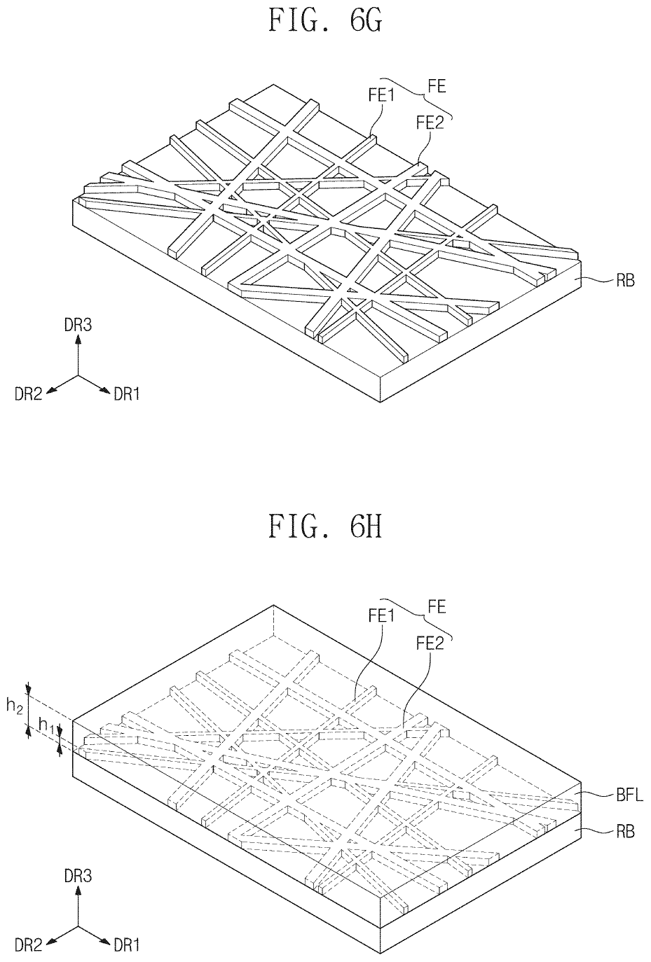

FIGS. 6A to 6H are each a perspective view showing processes in a method for manufacturing a transparent electrode according to an embodiment of the disclosure. FIGS. 6A to 6H sequentially show processes of forming a transparent electrode in an embodiment of the disclosure. Hereinafter, in describing the method for manufacturing a transparent electrode according to an embodiment with reference to FIGS. 6A to 6H, the same reference numerals are given to components that are the same as the components described above, and detailed descriptions thereof will be omitted.

Referring to FIGS. 6A and 6B, the method may include preparing of the substrate RB (S100) and forming of an electrode layer PEL on the substrate RB (S200) in the method for manufacturing a transparent electrode according to an embodiment.

Referring to FIG. 6A, the method for manufacturing a transparent electrode according to an embodiment may include providing a substrate RB on which multiple fibrous electrodes FE may be formed. The substrate RB may provide a reference surface on which the fibrous electrodes FE may be formed. The substrate RB may be an insulating substrate. In another embodiment, the substrate RB may be a display panel substrate in the manufacturing process. For example, the substrate RB may be an unfinished display panel substrate, or an intermediate display panel substrate in which the circuit layer DP-CL (FIG. 2) is formed on the base layer BS (FIG. 2). For example, the substrate RB may indicate the base layer BS or the circuit layer DP-CL shown in FIG. 2, and the fibrous electrodes FE may be formed on the reference surface provided by the base layer BS or the circuit layer DP-CL. However, the embodiment of the disclosure is not limited thereto.

Referring to FIG. 6A, an electrode layer PEL may be formed on the substrate RB. A method of forming the electrode layer PEL is not particularly limited, and methods such as thermal evaporation, vacuum deposition, spin coating, casting, Langmuir-Blodgett (LB), inkjet printing, laser printing, and Laser Induced Thermal Imaging (LITI) may be used.

The electrode layer PEL may include silver (Ag), gold (Au), platinum (Pt), aluminum (Al), copper (Cu), tin (Sn), gallium (Ga), indium (In), nickel (Ni), or any combination thereof. The electrode layer PEL may include a metal material made of silver (Ag), gold (Au), platinum (Pt), aluminum (Al), copper (Cu), tin (Sn), gallium (Ga), indium (In), or nickel (Ni), or the electrode layer PEL may include a metal material made of a combination of two or more of silver (Ag), gold (Au), platinum (Pt), aluminum (Al), copper (Cu), tin (Sn), gallium (Ga), indium (In), and nickel (Ni).

Referring to FIGS. 6B to 6E, the method may include disposing a first polymer fiber PF1 and a second polymer fiber PF2 on an electrode layer PEL in the method for manufacturing a transparent electrode according to an embodiment. The disposing of the first polymer fiber PF1 and the second polymer fiber PF2 on the electrode layer PEL may include disposing a first polymer fiber PF1 on the electrode layer PEL, and disposing a second polymer fiber PF2 on the electrode layer PEL and the first polymer fiber PF1. FIGS. 6B to 6E show an embodiment that the first polymer fiber PF1 is first disposed on the electrode layer PEL, and the second polymer fiber PF2 is disposed on the electrode layer PEL on which the first polymer fiber PF1 is disposed. However, the embodiment of the disclosure is not limited thereto, and the order in which the first polymer fiber PF1 and the second polymer fiber PF2 are disposed may be altered, unlike what is shown in FIGS. 6B to 6E. For example, the second polymer fiber PF2 may be disposed first on the electrode layer PEL, and the first polymer fiber PF1 may be disposed on the electrode layer PEL on which the second polymer fiber PF2 is disposed.

FIGS. 6B to 6E show an embodiment in which the method of electrospinning is used as a method for disposing the first polymer fiber PF1 and the second polymer fiber PF2 on the electrode layer PEL, but the embodiment of the disclosure is not limited thereto. The method of disposing the first polymer fiber PF1 and the second polymer fiber PF2 on the electrode layer PEL is not particularly limited, and may be performed through any one of the processes among electro-spinning, melt-blowing, and flash-spinning.

The electro-spinning device may include a spinning nozzle ESD, a collector CT, and a power supply unit (not shown). The electro-spinning device may further include a storage tank (not shown) for supplying a polymer solution to the spinning nozzle ESD. Components included in the electro-spinning device are not limited to the components described above. At least some of the components described above may be omitted, and other components may be added.

The spinning nozzle ESD may spin a polymer solution supplied from the storage tank (not shown). The spinning nozzle ESD may spin the polymer solution by a voltage applied from the power supply unit (not shown). As used herein, the “polymer solution” may be a polymer material that is dissolved in a solvent. The solvent is not particularly limited as long as the polymer material used may be dissolved therein.

The collector CT may collect the polymer solution spun from the spinning nozzle ESD. The collector CT may have a voltage opposite to that of the spinning nozzle ESD. A predetermined (or selectable) voltage may be applied to the spinning nozzle ESD and the collector CT from the power supply unit (not shown), and a voltage difference between the spinning nozzle ESD and the collector CT may cause the polymer solution to be spun in the form of fibers from the spinning nozzle ESD and thus to be collected in the collector CT. The solvent included in the polymer solution may be vaporized upon the spinning, and the dried polymer fibers may be collected in the collector CT.

The collector CT may be variously shaped and provided. In FIGS. 6B and 6D, the collector CT is shown as having a ring shape with a hollow at a central portion, but the embodiment of the disclosure is not limited thereto. For example, unlike what is shown in FIGS. 6B and 6D, the collector CT may have a plate shape without a hollow portion.

Referring to FIGS. 6B and 6C, disposing the first polymer fiber PF1 on the electrode layer PEL may be performed. The first polymer fiber PF1 may be provided on the electrode layer PEL. The first polymer fiber PF1 may be provided on the electrode layer PEL by an electro-spinning device. As shown in FIG. 6B, the disposing of the first polymer fiber PF1 on the electrode layer PEL may include transferring the first polymer fiber PF1 collected in the collector CT on the electrode layer PEL. For example, the substrate RB on which the electrode layer PEL is laminated may be disposed below the collector CT, and lifted to separate the first polymer fiber PF1 from the collector CT, and the separated first polymer fiber PF1 may thus be disposed on the electrode layer PEL. However, the embodiment of the disclosure is not limited thereto, and the disposing of the first polymer fiber PF1 on the electrode layer PEL may be performed in various ways. For example, the process may be performed in a way that the first polymer fiber PF1 may be separated from the collector CT, and the separated first polymer fiber PF1 may be disposed on the electrode layer PEL.

The first polymer fiber PF1 may be in the form of a nano-scale fiber. The first polymer fiber PF1 may have a first diameter (or a first width). In an embodiment, the first diameter may be in a range of about 300 nm to about 500 nm.

The type of the first polymer fiber PF1 is not particularly limited, and for example, the first polymer fiber PF1 may include at least one selected from the group consisting of polyvinyl acetate, polyurethane, polyurethane copolymer, cellulose derivative, polymethyl methacrylate (PMMA), polymethyl acrylate (PMA), polyacrylic copolymer, polyvinyl acetate copolymer, polyvinyl alcohol (PVA), polyfurfuryl alcohol (PPFA), polystyrene (PS), polystyrene copolymer, polyethylene oxide (PEO), polypropylene oxide (PPO), polyethylene oxide copolymer, polypropylene oxide copolymer, polycarbonate (PC), polyvinyl chloride (PVC), polycaprolactone, polyvinylpyrrolidone (PVP), polyvinylfluoride, polyvinylidenefluoride copolymer, and polyamide. However, the material of the first polymer fiber PF1 is not limited thereto.

The first polymer fibers PF1 may be randomly disposed on the electrode layer PEL. The first polymer fiber PF1 may have an arbitrary pattern that is not repeated on the electrode layer PEL. The first polymer fiber PF1 may extend in an arbitrary direction on the substrate RB. The first polymer fibers PF1 may extend in a random direction on the substrate RB. The distance between the adjacent first polymer fibers PF1 may be different.

At least two or more of the first polymer fibers PF1 may be arranged to intersect each other on the substrate RB. FIG. 6C shows that the first polymer fiber PF1 is in the form of a single body on the electrode layer PEL, but the embodiment of the disclosure is not limited thereto. The first polymer fiber PF1 may be disposed to be in the form of a three-dimensional network on the electrode layer PEL. For example, the first polymer fibers PF1 may rest upon each other on the electrode layer PEL to form a three-dimensional network structure.

Referring to FIGS. 6D and 6E, disposing the second polymer fiber PF2 on the electrode layer PEL may be performed. The second polymer fiber PF2 may be provided on the electrode layer PEL. The second polymer fiber PF2 may be provided on the electrode layer PEL by the electro-spinning device described above. As for the disposing of the second polymer fiber PF2, the method described above in the disposing of the first polymer fiber PF1 may be equally applied.

The second polymer fiber PF2 may be in the form of a micro-scale fiber. The second polymer fiber PF2 may have a second diameter (or a second width). The second diameter of the second polymer fiber PF2 may be different from the first diameter of the first polymer fiber PF1. The second diameter of the second polymer fiber PF2 may be greater than the first diameter of the first polymer fiber PF1. In an embodiment, the second diameter may be in a range of about 2 μm to about 3 μm.

The type of the second polymer fiber PF2 is not particularly limited, and for example, the second polymer fiber PF2 may include at least one selected from the group consisting of polyvinyl acetate, polyurethane, polyurethane copolymer, cellulose derivative, polymethyl methacrylate (PMMA), polymethyl acrylate (PMA), polyacrylic copolymer, polyvinyl acetate copolymer, polyvinyl alcohol (PVA), polyfurfuryl alcohol (PPFA), polystyrene (PS), polystyrene copolymer, polyethylene oxide (PEO), polypropylene oxide (PPO), polyethylene oxide copolymer, polypropylene oxide copolymer, polycarbonate (PC), polyvinyl chloride (PVC), polycaprolactone, polyvinylpyrrolidone (PVP), polyvinylfluoride, polyvinylidenefluoride copolymer, and polyamide. However, the material of the second polymer fiber PF2 is not limited thereto.

The second polymer fiber PF2 and the first polymer fiber PF1 may include a same material. However, the embodiment of the disclosure is not limited thereto, and the first polymer fiber PF1 and the second polymer fiber PF2 may include different materials.

The second polymer fibers PF2 may be randomly disposed on the electrode layer PEL. The second polymer fiber PE2 may have an arbitrary pattern that is not repeated on the electrode layer PEL. The second polymer fiber PF2 may extend in an arbitrary direction on the substrate RB. The second polymer fibers PF2 may extend in a random direction on the substrate RB. The distance between the adjacent second polymer fibers PF2 may be different.

The second polymer fiber PF2 may be disposed on the electrode layer PEL, and arranged to intersect at least one of the adjacent first polymer fiber PF1 or the adjacent second polymer fiber PF2. FIG. 6E shows that the first polymer fiber PF1 and the second polymer fiber PF2 are integral with each other on the electrode layer PEL, but the embodiment of the disclosure is not limited thereto. The first polymer fiber PF1 and the second polymer fiber PF2 may be disposed to be in the form of a three-dimensional network on the electrode layer PEL. For example, the first polymer fiber PF1 and the second polymer fiber PF2 may rest upon each other on the electrode layer PEL to form a three-dimensional network structure.

Although not shown, after the disposing of the first polymer fiber PF1 and the second polymer fiber PF2 on the electrode layer PEL, heat-treating the first polymer fiber PF1 and the second polymer fiber PF2 may be performed. The heat-treating of the first polymer fiber PF1 and the second polymer fiber PF2 may increase adhesion between the electrode layer PEL and the first and second polymer fibers PF1 and PF2. The heat-treating of the first polymer fiber PF1 and the second polymer fiber PF2 may include cross-linking of the first polymer fiber PF1 and the second polymer fiber PF2. Accordingly, the adhesion between the electrode layer PEL and the first and second polymer fibers PF1 and PF2 may be increased.

The heat-treating may include exposing the first polymer fiber PF1 and the second polymer fiber PF2 to a first temperature condition. The first temperature may be above the glass transition temperature and below the melting point of each of the first polymer fiber PF1 and the second polymer fiber PF2. The first temperature is not particularly limited as long as the temperature is less than the melting point of each of the first polymer fiber PF1 and the second polymer fiber PF2, and, for example, the first temperature may be in a range of about 80° C. to about 150° C. The first temperature in the heat-treating may be appropriately set according to the type and capacity of the first polymer fiber PF1 and the second polymer fiber PF2. As used herein, the glass transition temperature and melting point of each of the first polymer fiber PF1 and the second polymer fiber PF2 may indicate one measured through differential scanning calorimetry (DSC).

As shown in FIG. 6F, the first polymer fiber PF1 and the second polymer fiber PF2 may be disposed on the electrode layer PEL, and the first polymer fiber RF1 and the second polymer fiber PF2 may be used as masks to etch the electrode layer PEL.

Referring to FIG. 6F, the first polymer fiber PF1 and the second polymer fiber PF2 may be used as mask patterns for etching the electrode layer PEL. The first polymer fiber PF1 and the second polymer fiber PF2 may partially expose an upper portion of the electrode layer PEL and cover the rest.

The electrode layer PEL may be divided into a first portion overlapping the first polymer fiber PF1 and the second polymer fiber PF2 in the third direction DR3, and a second portion that is not overlapping the first polymer fiber PF1 and the second polymer fiber PF2 in the third direction DR3. The first portion of the electrode layer PEL may not be removed after the etching of the electrode layer PEL and may remain to form multiple fibrous electrodes FE. The second portion of the electrode layer PEL may be a portion that is removed after the etching of the electrode layer PEL.

The etching of the electrode layer PEL may include dry etching and/or wet etching.

In an embodiment, in the etching of the electrode layer PEL, dry etching and wet etching may be sequentially performed.

For the dry etching, at least one of plasma etching, reactive ion etching (RIE), and reactive ion beam etching may be used. In the dry etching, at least one gas selected from the group consisting of SiF₄, CF₄, C₃F₈, C₂F₆, CHF₃, CClF₃, O₂, NF₃, and SF₆ may be used as a process gas. The process gas may further include an inert gas such as Ar or N₂ which is not directly involved in the etching reaction so as to increase etching reactivity or to increase etching uniformity.

The wet etching may include an isotropic etching process. An etchant used for wet etching is not particularly limited, and for example, may include at least one of hydrofluoric acid (HF), hydrochloric acid (HCl), nitric acid (HNO₃), sulfuric acid (H₂SO₄), phosphoric acid (H₃PO₄), oxalic acid, buffered oxide etchant (BOE), sodium hydroxide (NaOH), hydroxide potassium (KOH), hydrogen peroxide (H₂O₂), acetone, tetramethyl ammonium hydroxide (TMAH), ethylenediamine, pyrocatechol, hydrazine chelating amine, 1,2-diaminoethane, N, N-dimethylacetamide, and water, or a mixed solution by a combination thereof.

Referring to FIG. 6F, in the etching of the electrode layer PEL, the second portion in which the first polymer fiber PF1 and the second polymer fiber PF2 are not disposed may be removed from the electrode layer PEL. Accordingly, an upper surface of the substrate RB, which is overlapping the second portion of the electrode layer PEL in the third direction DR3 may be exposed.

Multiple fibrous electrodes FE may be formed after the etching of the electrode layer PEL, using the first polymer fiber PF1 and the second polymer fiber PF2 as masks. A first fibrous electrode FE1 may be formed in the portion in which the first polymer fiber PF1 is disposed in the electrode layer PEL. A second fibrous electrode FE2 may be formed in the portion in which the second polymer fiber PF2 is disposed in the electrode layer PEL. The formed first fibrous electrode FE1 and the second fibrous electrode FE2 may have different widths. The width of each of the first fibrous electrode FE1 and the second fibrous electrode FE2 may be controlled by altering the diameters of the first polymer fiber PF1 and the second polymer fiber PF2, respectively.

Referring to FIGS. 6F and 6G, after the etching of the electrode layer PEL, removing the first polymer fiber PF1 and the second polymer fiber PF2 may be performed. The removing of the first polymer fiber PF1 and the second polymer fiber PF2 may expose upper surfaces of the fibrous electrodes FE. The removing of the first polymer fiber PF1 and the second polymer fiber PF2 may include dissolving the first polymer fiber PF1 and the second polymer fiber PF2, using a first solvent. The first solvent is not particularly limited as long as the first polymer fiber PF1 and the second polymer fiber PF2 may be dissolved therein, and for example, may be made of toluene, benzene, hexane, pentane, chloroform, or a mixture thereof.

Referring to FIG. 6H, forming a buffer layer BFL on the fibrous electrodes FE may be performed. A method of forming the buffer layer BFL is not particularly limited, and methods such as thermal evaporation, vacuum deposition, spin coating, casting, Langmuir-Blodgett (LB), inkjet printing, laser printing, and Laser Induced Thermal Imaging (LITI) may be used for the forming.

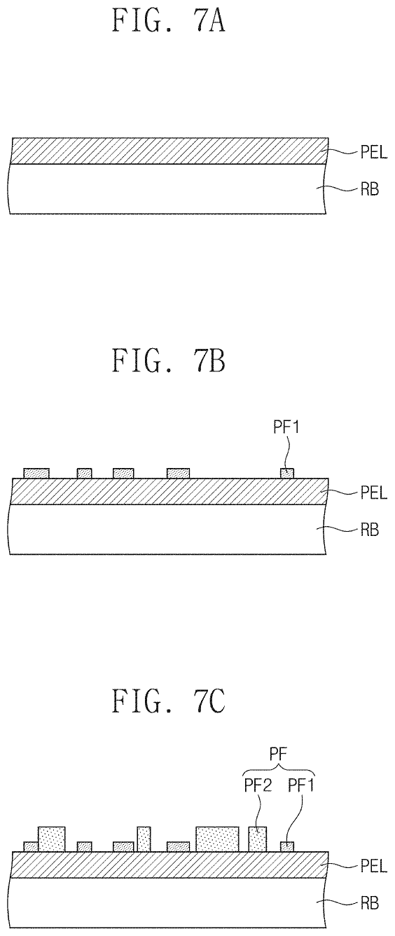

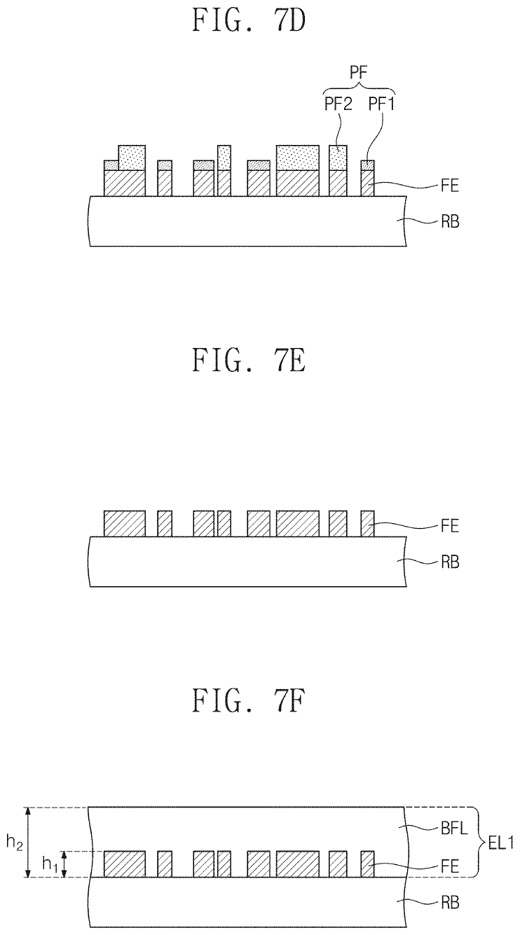

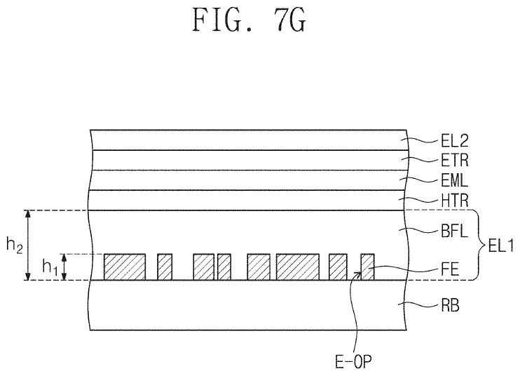

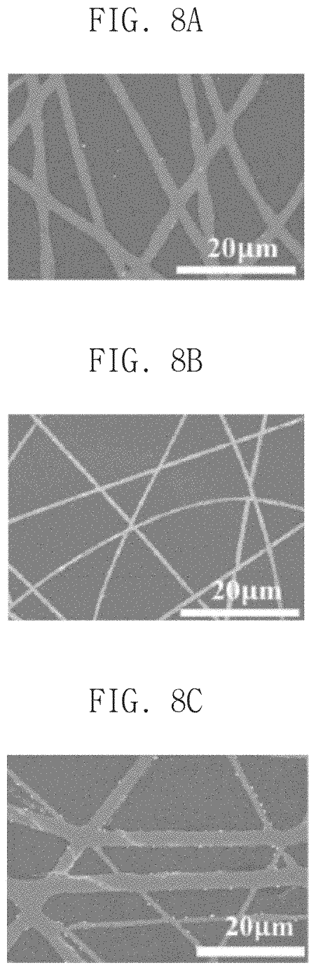

FIGS. 7A to 7G are each a schematic cross-sectional view showing processes of manufacturing a light emitting element according to an embodiment. FIGS. 7A to 7G sequentially show processes of forming a transparent electrode for manufacturing a light emitting element according to an embodiment of the disclosure. In describing the method for manufacturing a light emitting element of an embodiment, the descriptions of the light emitting element of an embodiment above may be applied. Hereinafter, in the describing of the method for manufacturing a light emitting element according to an embodiment with reference to FIGS. 7A to 7G, the same reference numerals are given to components that are the same as the components described above, and detailed descriptions thereof will be omitted.

The method for manufacturing a light emitting element according to an embodiment may indicate manufacturing light emitting elements ED and ED-a of an embodiment described in FIGS. 3A and 4. An embodiment provides a method for manufacturing a light emitting element including multiple fibrous electrodes FE.

Referring to FIGS. 7A to 7G, the method for manufacturing a light emitting element according to an embodiment may include forming a first electrode EL1, forming multiple functional layers on the first electrode EL1, and forming a second electrode EL2 on the functional layers.

FIG. 7A is a schematic cross-sectional view of forming an electrode layer PEL on a substrate RB. Referring to FIG. 7A, the electrode layer PEL may be disposed on the substrate RB. The substrate RB may be the base layer BS or the circuit layer DP-CL of FIG. 2. The electrode layer PEL may form multiple fibrous electrodes FE through an etching process which will be described later.

Referring to FIGS. 7B and 7C, disposing the polymer fiber PF on the electrode layer PEL may be performed after the forming of the electrode layer PEL on the substrate RB. The polymer fiber PF may include a first polymer fiber PF1 having a first diameter and a second polymer fiber PF2 having a second diameter different from the first diameter. The first polymer fiber PF1 and the second polymer fiber PF2 may be randomly disposed on the electrode layer PEL as described in FIGS. 6B to 6E. The first polymer fiber PF1 and the second polymer fiber PF2 may be used as mask patterns for etching the electrode layer PEL in an etching process which will be described later.

Referring to FIGS. 7D and 7E, etching the electrode layer PEL may be performed using the first polymer fiber PF1 and the second polymer fiber PF2 as masks. In the electrode layer PEL, a region other than the region where the first polymer fiber PF1 and the second polymer fiber PF2 are disposed may be removed in the etching process. Accordingly, multiple fibrous electrodes FE having the same shape as the first polymer fiber PF1 and the second polymer fiber PF2 in a plan view may be formed. For example, in the etching of the electrode layer PEL as described in FIG. 6D, a first fibrous electrode FE1 having the same shape as the first polymer fiber PF1 may be formed, and a second fibrous electrode FE2 having the same shape as the second polymer fiber PF2 may be formed. The formed first and second fibrous electrodes FE1 and FE2 may be randomly disposed on the substrate RB as described in FIG. 6E, and may be integral with each other.

Referring to FIG. 7F, a buffer layer BFL covering the fibrous electrodes FE may be formed on the fibrous electrodes FE.

Referring to FIG. 7G, forming multiple functional layers may be performed after the forming of the buffer layer BFL. A hole transport region HTR, an emission layer EML, and an electron transport region ETR may be sequentially laminated on the buffer layer BFL. The second electrode EL2 may be formed after the forming of the functional layers including the hole transport region HTR, the emission layer EML, and the electron transport region ETR.

In the describing of the method for manufacturing a light emitting element according to an embodiment with reference to FIGS. 7A to 7G, an embodiment in which the first electrode EL1 includes the fibrous electrodes FE and the buffer layer BFL is shown. However, the embodiment of the disclosure is not limited thereto, and the second electrode EL2 may include the fibrous electrodes FE and the buffer layer BFL, unlike what is shown in FIGS. 7A to 7G. The second electrode EL2 may be manufactured in the same method as the method for manufacturing the transparent electrode described above.

Hereinafter, a transparent electrode according to an embodiment of the disclosure will be described in detail with reference to evaluation results of transparent electrodes of Example and Comparative Examples. Example shown below are presented only for the understanding of the disclosure, and the scope of the disclosure is not limited thereto.

### Manufacture of Example

A polyethylene naphthalate (PEN) substrate was cut to a size of about 2.5 cm×2.5 cm and subjected to UV—O₃ washing for about 10 minutes. An electrode layer having a thickness of about 40 nm was formed using Ag through thermal evaporation.

400 mg of polystyrene was dissolved in a mixed solution of 2 ml of acetone and 1 ml of dimethylformamide to prepare a polymer solution. Thereafter, the prepared polymer solution was electro-spun using an electro-spinning device to form a first polymer fiber having a diameter of about 300 nm to about 500 nm and a second polymer fiber having a diameter of about 2 μm to about 3 μm on the electrode layer.

The first and second polymer fibers were heat-treated at 130° C. for about 10 minutes. Thereafter, the resulting product was oxygen plasma treated, and immersed using H₂O₂ as an etchant to etch the electrode layer. The first and second polymer fibers were dissolved and removed using chloroform. Thereafter, a buffer layer having a thickness of about 240 nm was formed using IZO.

### Manufacture of Comparative Example 1

In Comparative Example 1, a transparent electrode was manufactured under the same conditions as in Example, except that a second polymer fiber was used alone as compared with Example above.

### Manufacture of Comparative Example 2

In Comparative Example 2, a transparent electrode was manufactured under the same conditions as in Example, except that a first polymer fiber was used alone as compared with Example above.

### Manufacture of Comparative Example 3

In Comparative Example 3, a transparent electrode having a single-layer structure in which only an electrode layer having a thickness of about 40 nm was formed using Ag on a polyethylene naphthalate substrate was manufactured.

### Manufacture of Comparative Example 4

In Comparative Example 4, a transparent electrode was manufactured by applying silver nanowires onto a polyethylene naphthalate substrate.

FIGS. 8A to 8C are each a showing scanning transfer micrographs of transparent electrodes of Example and Comparative Examples. FIGS. 8A to 8C show images of surfaces of transparent electrodes of Example and Comparative Examples, which are taken using a Field Emission Scanning Electron Microscope (FE-SEM).

FIG. 8A is a view showing a scanning electron micrograph of a transparent electrode of Comparative Example 1. FIG. 8A corresponds to a transparent electrode formed using only a micro-scale second polymer fiber. For example, Comparative Example 1 shown in FIG. 8A corresponds to a transparent electrode including only a second fibrous electrode.

FIG. 8B is a view showing a scanning electron micrograph of a transparent electrode of Comparative Example 2. FIG. 8B corresponds to a transparent electrode formed using only a nano-scale first polymer fiber. For example, Comparative Example 2 shown in FIG. 8B corresponds to a transparent electrode including only a first fibrous electrode.

FIG. 8C is a view showing a scanning electron micrograph of a transparent electrode of Example. FIG. 8C corresponds to a transparent electrode formed by using both a nano-scale first polymer fiber and a micro-scale second polymer fiber. For example, Example shown in FIG. 8C corresponds to a transparent electrode including both a first fibrous electrode and a second fibrous electrode.

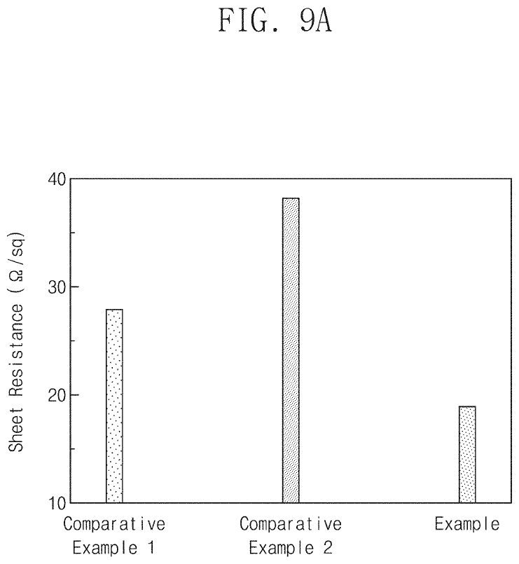

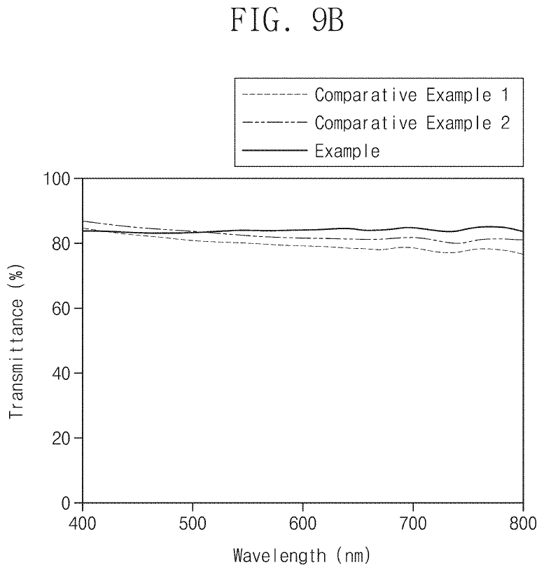

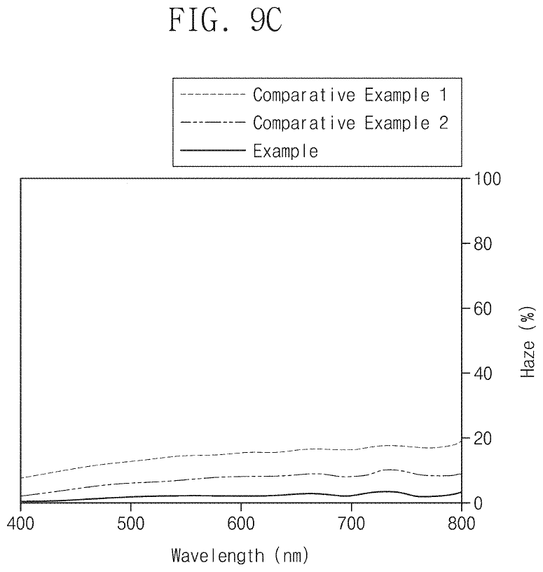

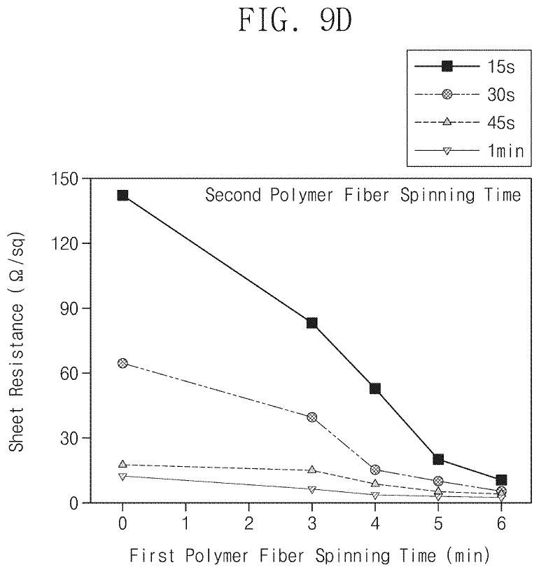

FIG. 9A is a graph showing sheet resistance of transparent electrodes of Example and Comparative Examples. FIG. 9B is a graph showing changes in light transmittance versus wavelengths of Example and Comparative Examples. FIG. 9C is a graph showing haze of Example and Comparative Examples.

In FIG. 9A, sheet resistance was measured and shown in order to evaluate electrical properties of the transparent electrodes of Example and Comparative Examples. In Example and Comparative Examples 1 and 2, the sheet resistance was measured by a 4-point probe method, and a sheet resistance measuring device (FPP-2400: DASOL ENG) was used.

Referring to FIG. 9A, it is seen that the sheet resistance of Example is the smallest as compared to Comparative Examples 1 and 2. For example, it is seen that the transparent electrode of Example, which was formed using the first polymer fiber and the second polymer fiber exhibits low sheet resistance as compared to the transparent electrode of Comparative Example 1, which was formed using only the first polymer fiber and the transparent electrode of Comparative Example 2, which was formed using only the second polymer fiber.

Accordingly, it is believed that light emitting elements ED and ED-a may exhibit excellent electrical properties in case that the transparent electrode of Example is applied.

In FIGS. 9B and 9C, transmittance and haze were measured and shown in order to evaluate optical properties of the transparent electrodes of Example and Comparative Examples. In FIG. 9B, as for the transmittance, light transmittance versus wavelength was measured. The transmittance and haze were measured in a wavelength range of about 400 nm to about 800 nm, using a Cary 5000 UV-VIS-NIR spectrophotometer (Agilent) for Example and Comparative Examples 1 and 2.

Referring to FIGS. 9B and 9C, the transparent electrode of Example has a light transmittance of greater than or equal to about 80% a haze of less than or equal to about 5% in the wavelength range of about 400 nm to about 800 nm, confirming to have excellent optical properties. It is also seen that the transparent electrode of Example exhibits higher light transmittance than those of Comparative Examples 1 and 2 in a wavelength range of about 550 nm, which is a visible light range.

On the other hand, it is seen that the light transmittance of the transparent electrodes of Comparative Examples 1 and 2 in the wavelength range of about 400 nm to about 500 nm is at a level corresponding to the light transmittance of the transparent electrode of Example, but the light transmittance of the transparent electrodes of Comparative Examples 1 and 2 in the wavelength range of about 500 nm to about 800 nm is lower than that of the transparent electrode of Example. It is also seen that Comparative Examples 1 and 2 have increased haze as compared with Example.

FIG. 9D is a graph showing changes in sheet resistance of transparent electrodes versus spinning time of the first polymer fiber and the second polymer fiber.

Surface coverage of the polymer fiber may increase with longer spinning time. As used herein, the “surface coverage” may be the area ratio of a polymer fiber with respect to the entire area of an electrode layer after electro-spinning. In case that the surface coverage of the polymer fiber increases, the area ratio of a fibrous electrode formed may increase.

Referring to FIG. 9D, in the second polymer fiber, it is seen that a difference in sheet resistance value versus the spinning time is large. In the micro-scale second polymer fiber, the area ratio of an electrode formed according to the spinning time may be significantly different from that of the nano-scale first polymer fiber. It may be possible to increase the spinning time of the second polymer fiber to reduce the sheet resistance, but as the spinning time of the second polymer fiber having a relatively large diameter increases, a space through which light may pass may decrease to cause a reduction in light transmittance.

According to the method for manufacturing a transparent electrode according to an embodiment of the disclosure, a transparent electrode that satisfies both low electrical resistance and high light transmittance may be obtainable by using the nano-scale first polymer fiber and the micro-scale second polymer fiber together and controlling the spinning time of the first polymer fiber and the second polymer fiber. Referring back to FIG. 9D, in case that the spinning time of the second polymer fiber is as short as 15 seconds and 30 seconds, it is seen that the sheet resistance significantly increases. On the other hand, even in case that the spinning time of the second polymer fiber is as short as 15 seconds and 30 seconds, it is seen that the sheet resistance decreases in case that the spinning time of the first polymer fiber is long. For example, it is seen that even in case that the spinning time of the second polymer fiber having a relatively large diameter is shortened, both the low sheet resistance and high light transmittance may be achieved by controlling the spinning time of the first polymer fiber.

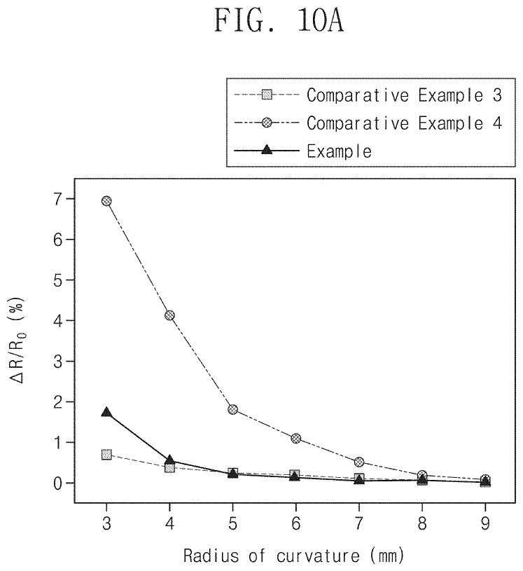

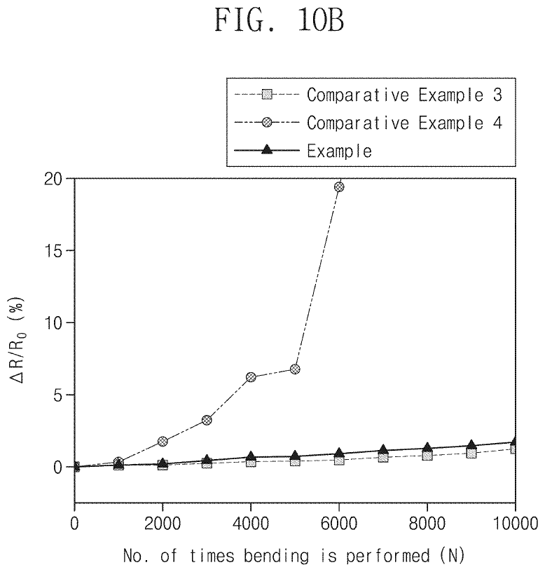

FIG. 10A is a graph showing changes in electrical resistance value versus a radius of transparent electrodes of Example and Comparative Examples. FIG. 10B is a graph showing changes in electrical resistance value from a test of repeated bending of transparent electrodes of Example and Comparative Examples.

In FIG. 10A, changes in electrical resistance value were measured for the transparent electrodes of Example and Comparative Examples 3 and 4 with a radius of 3 mm, 4 mm, 5 mm, 6 mm, 7 mm, 8 mm, and 9 mm. Referring to FIG. 10A, it is seen that the transparent electrode of Comparative Example 4 has a rapid increase in the electrical resistance value at a radius of 5 mm or less. On the other hand, it is seen that the transparent electrode of Example and Comparative Example 3 have no rapid increase in the electric resistance value even with a radius of curvature reduced to 3 mm. Accordingly, it is seen that the transparent electrode of Example has durability and folding reliability similar to those of the transparent electrode of Comparative Example 3, which includes a single structure electrode layer, and has greater mechanical durability and folding reliability than the transparent electrode of Comparative Example 4, which includes silver nanowires. For example, it is seen that high folding reliability without an increase in internal resistance of an element up to 3 mm radius of curvature is shown in case that a transparent electrode using the first polymer fiber and the second polymer fiber as in the disclosure is implemented.

FIG. 10B shows the results of performing a repeated bending test to measure changes in electrical resistance versus the extent of repeated bending of the transparent electrodes with a radius of 5 mm of Example and Comparative Examples 3 and 4. Referring to FIG. 10B, in Comparative Example 4, it is seen that the electrical resistance value starts to increase after about 2000 times of repeated bending, and the electrical resistance value sharply increases after about 5000 times of repeated bending. On the other hand, in Example with a small radius with 5 mm, it is seen that the change in electrical resistance value is small even after 10000 times of repeated bending to show excellent reliability. Accordingly, it is seen that high flexibility properties in which internal resistance does not increase even in case that external stress is repeatedly applied by about 10000 times with a radius of 5 mm is shown in case that a light emitting element is implemented using the first polymer fiber and the second polymer fiber as in the disclosure.

According to a method for manufacturing a transparent electrode according to an embodiment of the disclosure, a transparent electrode having excellent electrical, optical, and mechanical properties may be manufactured.

A light emitting element according to an embodiment of the disclosure may include a transparent electrode having a first fibrous electrode and a second fibrous electrode, which have different widths in a plan view, and thus may have excellent electrical, optical, and mechanical properties.

According to a method for manufacturing a light emitting element according to an embodiment of the disclosure, a light emitting element having excellent electrical, optical, and mechanical properties may be manufactured.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode facing the first electrode; and
a plurality of functional layers disposed between the first electrode and the second electrode, wherein
at least one of the first electrode and the second electrode includes a plurality of fibrous electrodes, which are randomly disposed, and
the plurality of fibrous electrodes includes:
a first fibrous electrode having a first width in a plan view; and
a second fibrous electrode having a second width different from the first width in a plan view.

2. The light emitting element of claim 1, wherein the first fibrous electrode and the second fibrous electrode are integral with each other.

3. The light emitting element of claim 1, wherein
the first width of the first fibrous electrode is in a range of about 300 nm to about 500 nm, and
the second width of the second fibrous electrode is in a range of about 2 μm to about 3 μm.

4. The light emitting element of claim 1, wherein
each of the first fibrous electrode and the second fibrous electrode has a thickness in a thickness direction of the first electrode or the second electrode, and
the thickness of the first fibrous electrode is substantially equal to the thickness of the second fibrous electrode in the thickness direction.

5. The light emitting element of claim 1, wherein the first fibrous electrode and the second fibrous electrode each independently comprises silver (Ag), gold (Au), platinum (Pt), aluminum (Al), copper (Cu), tin (Sn), gallium (Ga), indium (In), nickel (Ni), or a combination thereof.

6. The light emitting element of claim 1, wherein at least one of the first electrode and the second electrode further comprises:
a buffer layer disposed on the plurality of fibrous electrodes and including a transparent conductive oxide.

7. The light emitting element of claim 6, wherein the buffer layer covers the plurality of fibrous electrodes.

8. The light emitting element of claim 6, wherein the buffer layer has an upper surface parallel to an upper surface of the first electrode or the second electrode.

9. The light emitting element of claim 6, wherein the buffer layer comprises indium zinc oxide.

10. The light emitting element of claim 6, wherein the buffer layer comprises:
a first buffer layer disposed on the plurality of fibrous electrodes and including the transparent conductive oxide; and
a second buffer layer disposed on the first buffer layer and including a conductive polymer.

11. The light emitting element of claim 1, wherein the plurality of functional layers comprises:
a hole transport region disposed on the first electrode;
an emission layer disposed on the hole transport region; and
an electron transport region disposed on the emission layer.

12. A method for manufacturing a transparent electrode, the method comprising:
forming an electrode layer on a substrate;
disposing a first polymer fiber having a first diameter and a second polymer fiber having a second diameter different from the first diameter on the electrode layer;
etching the electrode layer, using the first polymer fiber and the second polymer fiber as masks; and
removing the first polymer fiber and the second polymer fiber.

13. The method of claim 12, wherein the first polymer fiber and the second polymer fiber are randomly disposed on the electrode layer.

14. The method of claim 12, wherein:
the first diameter is in a range of about 300 nm to about 500 nm; and
the second diameter is in a range of about 2 μm to about 3 km.

15. The method of claim 12, wherein the disposing of the first polymer fiber and the second polymer fiber comprises:
disposing the first polymer fiber on the electrode layer; and
disposing the second polymer fiber on the electrode layer and the first polymer fiber.

16. The method of claim 12, further comprising:
forming a buffer layer including a transparent conductive oxide on the substrate, after the removing of the first polymer fiber and the second polymer fiber.

17. The method of claim 16, wherein the forming of the buffer layer comprises:
forming a first buffer layer including the transparent conductive oxide on the substrate; and
forming a second buffer layer including a conductive polymer on the first buffer layer.

18. The method of claim 12, further comprising:
heat-treating the first polymer fiber and the second polymer fiber, after the disposing of the first polymer fiber and the second polymer fiber.

19. The method of claim 12, wherein the disposing of the first polymer fiber and the second polymer fiber is performed by at least one of electro-spinning, melt-blowing, and flash-spinning.

20. A method for manufacturing a light emitting element, the method comprising:
forming a first electrode;
forming a plurality of functional layers on the first electrode; and
forming a second electrode on the plurality of functional layers, wherein the forming of the first electrode includes:
forming an electrode layer on a substrate;
disposing a first polymer fiber having a first diameter and a second polymer fiber having a second diameter different from the first diameter on the electrode layer;
etching the electrode layer, using the first polymer fiber and the second polymer fiber as masks; and
removing the first polymer fiber and the second polymer fiber.
